(19) United States
(12) Patent Application Publication
(10) Pub. No.: US 2023/0262998 A1
(43) Pub. Date: Aug. 17, 2023

(54) PHOTOELECTRIC CONVERSION ELEMENT AND SOLID-STATE IMAGING DEVICE

(71) Applicant: Sony Group Corporation, Tokyo (JP)

(72) Inventors: Yuta HASEGAWA, Kanagawa (JP); Masashi BANDO, Kanagawa (JP); Shintarou HIRATA, Tokyo (JP); Hideaki MOGI, Kanagawa (JP); Iwao YAGI, Kanagawa (JP); Yasuharu UJIIE, Kanagawa (JP); Yuki NEGISHI, Kanagawa (JP)

(73) Assignee: Sony Group Corporation, Tokyo (JP)

(21) Appl. No.: 18/106,885

(22) Filed: Feb. 7, 2023

Related U.S. Application Data
(63) Continuation of application No. 16/462,790, filed on May 21, 2019, now abandoned.

(30) Foreign Application Priority Data
Nov. 30, 2016 (JP) 2016-232961
Nov. 14, 2017 (JP) 2017-219374

(51) Int. Cl. H10K 39/32; H04N 25/63; H10K 85/20; H10K 85/60

(52) U.S. Cl. CPC H10K 39/32; H04N 25/63; H10K 85/211; H10K 85/649

(57) ABSTRACT

There is provided an imaging device and an electronic apparatus including an imaging device, where the imaging device includes: a first electrode; a second electrode; a photoelectric conversion layer disposed between the first electrode and the second electrode and including a first organic semiconductor material, a second organic semiconductor material, and a third organic semiconductor material, where the second organic semiconductor material comprises a subphthalocyanine material, and where the second organic semiconductor material has a highest occupied molecular orbital level ranging from −6 eV to −6.7 eV.

### CROSS REFERENCE TO RELATED APPLICATIONS

This application claims the benefit of Japanese Priority Patent Application JP 2016-232961 filed Nov. 30, 2016, and Japanese Priority Patent Application JP 2017-219374 filed Nov. 14, 2017, the entire contents of which are incorporated herein by reference.

### TECHNICAL FIELD

The present disclosure relates to a photoelectric conversion element using an organic semiconductor, and a solid-state imaging device including the same.

### BACKGROUND ART

In recent years, in solid-state imaging devices such as CCDs (Charge Coupled Devices) and CMOS (Complementary Metal Oxide Semiconductor) image sensors, reduction in pixel size has accelerated. The reduction in pixel size reduces the number of photons entering a unit pixel, which results in reduction in sensitivity and reduction in S/N ratio. Moreover, in a case where a color filter including a two-dimensional array of primary-color filters of red, green, and blue is used for colorization, in a red pixel, green light and blue light are absorbed by the color filter, which causes reduction in sensitivity. Further, in order to generate each color signal, interpolation of pixels is performed, which causes false color.

Accordingly, for example, PTL 1 discloses an image sensor using an organic photoelectric conversion film having a multilayer configuration in which an organic photoelectric conversion film having sensitivity to blue light (B), an organic photoelectric conversion film having sensitivity to green light (G), and an organic photoelectric conversion film having sensitivity to red light (R) are stacked in order. In the image sensor, signals of B, G, and R are separately extracted from one pixel to achieve an improvement in sensitivity. PTL 2 discloses an imaging element in which an organic photoelectric conversion film configured of a single layer is provided, and a signal of one color is extracted from the organic photoelectric conversion film and signals of two colors are extracted by silicon (Si) bulk spectroscopy.

### CITATION LIST

### Patent Literature

PTL 1: Japanese Unexamined Patent Application Publication No. 2003-234460

PTL 2: Japanese Unexamined Patent Application Publication No. 2005-303266

### SUMMARY

### Technical Problem

Incidentally, a photoelectric conversion element used as an imaging element may be desirable to suppress generation of a dark current.

It may therefore be desirable to provide a photoelectric conversion element and a solid-state imaging device that each make it possible to improve dark-current characteristics.

### Solution to Problem

Various embodiments are directed towards an imaging device, including: a first electrode; a second electrode; a photoelectric conversion layer disposed between the first electrode and the second electrode and comprising a first organic semiconductor material, a second organic semiconductor material, and a third organic semiconductor material, where the second organic semiconductor material comprises a subphthalocyanine material, and where the second organic semiconductor material has a highest occupied molecular orbital level ranging from −6 eV to −6.7 eV.

Additional embodiments are directed towards an electronic apparatus, including: a lens; signal processing circuitry; and an imaging device, including: a first electrode; a second electrode; a photoelectric conversion layer disposed between the first electrode and the second electrode and including a first organic semiconductor material, a second organic semiconductor material, and a third organic semiconductor material, where the second organic semiconductor material comprises a subphthalocyanine material, and wherein the second organic semiconductor material has a highest occupied molecular orbital level ranging from −6 eV to −6.7 eV.

It is to be noted that an effect described above is illustrative and not necessarily limited. An effect to be achieved by an embodiment of the disclosure may be any of the effects described in the present disclosure.

It is to be understood that both the foregoing general description and the following detailed description are exemplary, and are provided for further explanation of the technology as claimed.

### BRIEF DESCRIPTION OF DRAWINGS

The accompanying drawings are included to provide a further understanding of the technology, and are incorporated in and constitute a part of this specification. The drawings show illustrative embodiments and, together with the specification, serve to explain various principles of the technology.

FIG. 1 is a cross-sectional view of an illustrative schematic configuration of a photoelectric conversion element according to an embodiment of the present disclosure.

FIG. 2A is a diagram illustratively showing an example of energy levels of three kinds of materials configuring an organic photoelectric conversion layer.

FIG. 2B is a diagram showing another illustrative example of energy levels of three kinds of materials configuring the organic photoelectric conversion layer.

FIG. 2C is a diagram illustratively showing a specific example of energy levels of three kinds of materials configuring the organic photoelectric conversion layer.

FIG. 2D is a diagram illustratively showing another specific example of energy levels of three kinds of materials configuring the organic photoelectric conversion layer.

FIG. 3 is a plan view of an illustrative relationship among forming positions of the organic photoelectric conversion layer, a protective film (an upper electrode), and a contact hole.

FIG. 4A is a cross-sectional view of an illustrative configuration example of an inorganic photoelectric converter.

FIG. 4B is another cross-sectional view of the illustrative inorganic photoelectric converter illustrated in FIG. 4A.

FIG. 5 is a cross-sectional view of an illustrative configuration (lower-side electron extraction) of an electric charge (electron) storage layer of the organic photoelectric converter.

FIG. 6A is a cross-sectional view of an illustrative description of a method of manufacturing the photoelectric conversion element illustrated in FIG. 1.

FIG. 6B is a cross-sectional view of an illustrative process following FIG. 6A.

FIG. 7A is a cross-sectional view of an illustrative process following FIG. 6B.

FIG. 7B is a cross-sectional view of an illustrative process following FIG. 7A.

FIG. 8A is a cross-sectional view of an illustrative process following FIG. 7B.

FIG. 8B is a cross-sectional view of an illustrative process following FIG. 8A.

FIG. 8C is a cross-sectional view of an illustrative process following FIG. 8B.

FIG. 9 is a main-part cross-sectional view that describes illustrative workings of the photoelectric conversion element illustrated in FIG. 1.

FIG. 10 is a schematic view of an illustrative description of workings of the photoelectric conversion element illustrated in FIG. 1.

FIG. 11 is a functional block diagram of an illustrative solid-state imaging device using the photoelectric conversion element illustrated in FIG. 1 as a pixel.

FIG. 12 is a block diagram showing an illustrative a schematic configuration of an electronic apparatus using the solid-state imaging device illustrated in FIG. 11.

FIG. 13 is a block diagram depicting an illustrative example of a schematic configuration of an in-vivo information acquisition system.

FIG. 14 is a block diagram depicting an illustrative example of schematic configuration of a vehicle control system.

FIG. 15 is a diagram to explain an illustrative example of installation positions of an outside-vehicle information detecting section and an imaging section.

FIG. 16 is a characteristic diagram showing an illustrative relationship between a dark current and both a difference in LUMO level between the second organic semiconductor material and the first organic semiconductor material and a LUMO level of the second organic semiconductor material.

FIG. 17 is a characteristic diagram showing an illustrative relationship between a dark current and both a difference in HOMO level between the third organic semiconductor material and the first organic semiconductor material and a HOMO level of the third organic semiconductor material.

FIG. 18 is a result of X-ray diffraction measurement of an organic photoelectric conversion layer in an experimental example 23.

FIG. 19 is a result of X-ray diffraction measurement of an organic photoelectric conversion layer in an experimental example 24.

FIG. 20 is a result of X-ray diffraction measurement of an organic photoelectric conversion layer in an experimental example 25.

FIG. 21 is a result of X-ray diffraction measurement of an organic photoelectric conversion layer in an experimental example 26.

FIG. 22 is a result of X-ray diffraction measurement of an organic photoelectric conversion layer in an experimental example 27.

FIG. 23 is a result of X-ray diffraction measurement of an organic photoelectric conversion layer in an experimental example 28.

FIG. 24 is a result of X-ray diffraction measurement of an organic photoelectric conversion layer in an experimental example 29.

### DESCRIPTION OF EMBODIMENTS

Some embodiments of the present disclosure are described in detail below with reference to the drawings. It is to be noted that description is given in the following order.

1. Embodiment (An example in which an organic photoelectric conversion layer is made of three kinds of materials)

1-1. Configuration of a Photoelectric Conversion Element

1-2. Method of Manufacturing a Photoelectric Conversion Element

1-3. Workings and Effects

2. Application Examples

3. Examples

### 1. Embodiment

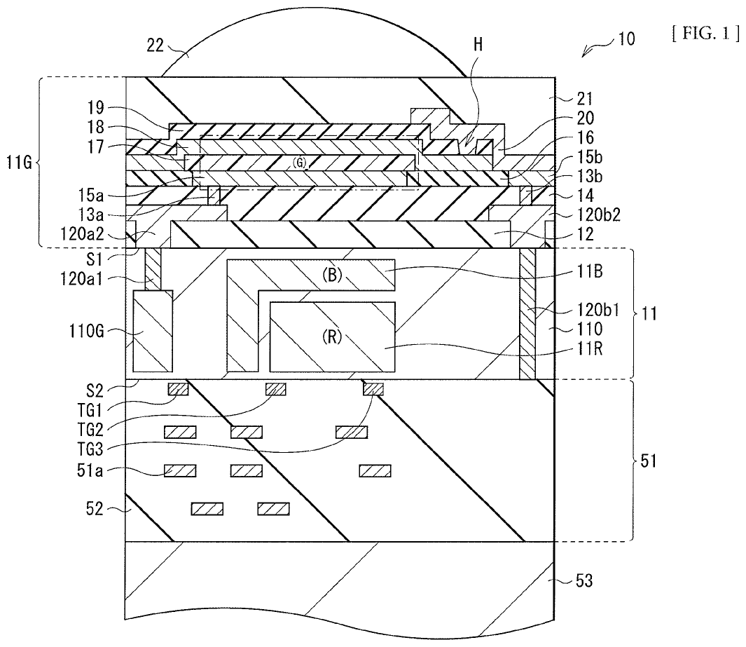

FIG. 1 illustrates a cross-sectional configuration of a photoelectric conversion element (a photoelectric conversion element 10) according to an embodiment of the present disclosure. The photoelectric conversion element 10 may configure, for example, one pixel (a unit pixel P in FIG. 11) of a solid-state imaging device (a solid-state imaging device 1 in FIG. 11) such as a CCD image sensor and a CMOS image sensor. In the photoelectric conversion element 10, a pixel transistor (including transfer transistors Tr1 to Tr3 to be described later) and a multilayer wiring layer (a multilayer wiring layer 51) may be provided on front surface (a surface S2 opposite to a light-reception surface (a surface S1)) side of a semiconductor substrate 11.

The photoelectric conversion element 10 according to the present embodiment may have a configuration in which one organic photoelectric converter 11G and two inorganic photoelectric converters 11B and 11R are stacked along a vertical direction. Each of the organic photoelectric converter 11G and the inorganic photoelectric converters 11B and 11R may selectively detect light in a relevant one of wavelength regions different from one another, and perform photoelectric conversion on the thusdetected light. The organic photoelectric converter 11G includes three kinds of organic semiconductor materials.

(1-1. Configuration of a Photoelectric Conversion Element)

The photoelectric conversion element 10 may have a stacked configuration of one organic photoelectric converter 11G and two inorganic photoelectric converters 11B and 11R. The configuration makes it possible for one element to obtain color signals of red (R), green (G), and blue (B). The organic photoelectric converter 11G may be provided on a back surface (the surface S1) of the semiconductor substrate 11, and the inorganic photoelectric converters 11B and 11R may be provided as embedded in the semiconductor substrate 11. Hereinafter, description is given of configurations of respective components.

(Organic Photoelectric Converter 11G)

The organic photoelectric converter 11G may be an organic photoelectric conversion element that absorbs light in a selective wavelength region (green light herein) with use of an organic semiconductor to generate electron-hole pairs. The organic photoelectric converter 11G has a configuration in which an organic photoelectric conversion layer 17 is sandwiched between a pair of electrodes (a lower electrode 15a and an upper electrode 18) for extraction of signal electric charges. The lower electrode 15a and the upper electrode 18 may be electrically coupled to conductive plugs 120a1 and 120b1 embedded in the semiconductor substrate 11 through wiring layers 13a, 13b, and 15b and a contact metal layer 20, as described later.

More specifically, in the organic photoelectric converter 11G, interlayer insulating films 12 and 14 may be provided on the surface S1 of the semiconductor substrate 11, and the interlayer insulating film 12 may be provided with through holes in regions facing the respective conductive plugs 120a1 and 120b1 to be described later. Each of the through holes may be filled with a relevant one of conductive plugs 120a2 and 120b2. In the interlayer insulating film 14, wiring layers 13a and 13b may be respectively embedded in regions facing the conductive plugs 120a2 and 120b2. The lower electrode 15a and the wiring layer 15b may be provided on the interlayer insulating film 14. The wiring layer 15b may be electrically isolated by the lower electrode 15a and an insulating film 16. The organic photoelectric conversion layer 17 may be provided on the lower electrode 15a out of the lower electrode 15a and the wiring layer 15b, and the upper electrode 18 may be provided to cover the organic photoelectric conversion layer 17. As described in detail later, a protective layer 19 may be provided on the upper electrode 18 to cover a surface of the upper electrode 18. The protective layer 19 may be provided with a contact hole H in a predetermined region, and a contact metal layer 20 may be provided on the protective layer 19 so as to be contained in the contact hole H and to extend to a top surface of the wiring layer 15b.

The conductive plug 120a2 may serve as a connector together with the conductive plug 120a1. Moreover, the conductive plug 120a2 may form, together with the conductive plug 120a1 and the wiring layer 13a, a transmission path of electric charges (electrons) from the lower electrode 15a to a green electric storage layer 110G to be described later. The conductive plug 120b2 may serve as a connector together with the conductive plug 120b1. Moreover, the conductive plug 120b2 may form, together with the conductive plug 120b1, the wiring layer 13b, the wiring layer 15b, and the contact metal layer 20, a discharge path of electric charges (holes) from the upper electrode 18. In order to allow each of the conductive plugs 120a2 and 120b2 to also serve as a light-blocking film, each of the conductive plugs 120a2 and 120b2 may be configured of, for example, a laminated film of metal materials such as titanium (Ti), titanium nitride (TiN), and tungsten. Moreover, such a laminated film may be used, which makes it possible to secure contact with silicon even in a case where each of the conductive plugs 120a1 and 120b1 is formed as an n-type or p-type semiconductor layer.

The interlayer insulating film 12 may be configured of an insulating film having a small interface state in order to reduce an interface state with the semiconductor substrate 11 (a silicon layer 110) and to suppress generation of a dark current from an interface with the silicon layer 110. As such, an insulating film, for example, a laminated film of a hafnium oxide (HfO₂) film and a silicon oxide (SiO₂) film may be used. The interlayer insulating film 14 may be configured of a single-layer film made of one material of materials such as silicon oxide, silicon nitride, and silicon oxynitride (SiON), or may be configured of a laminated film made of two or more of these materials.

The insulating film 16 may be configured of, for example, a single-layer film made of one material of materials such as silicon oxide, silicon nitride, and silicon oxynitride (SiON) or a laminated film made of two or more of these materials. The insulating film 16 may have, for example, a planarized surface, thereby having a shape and a pattern that each have almost no difference in level between the insulating film 16 and the lower electrode 15a. In a case where the photoelectric conversion element 10 is used as each of unit pixels P of the solid-state imaging device 1, the insulating film 16 may have a function of electrically isolating the lower electrodes 15a of respective pixels from one another.

The lower electrode 15a may be provided in a region that faces light-reception surfaces of the inorganic photoelectric converters 11B and 11R provided in the semiconductor substrate 11 and covers these light-reception surfaces. The lower electrode 15a may be configured of a conductive film having light transparency, and may be made of, for example, ITO (indium tin oxide). Alternatively, as a constituent material of the lower electrode 15a, other than ITO, a tin oxide (SnO₂)-based material doped with a dopant or a zinc oxide-based material prepared by doping aluminum zinc oxide with a dopant may be used. Non-limiting examples of the zinc oxide-based material may include aluminum zinc oxide (AZO) doped with aluminum (Al), gallium zinc oxide (GZO) doped with gallium (Ga), and indium zinc oxide (IZO) doped with indium (In). Moreover, other than these materials, for example, CuI, InSbO₄, ZnMgO, CuInO₂, MgIN₂O₄, CdO, or ZnSnO₃ may be used. It is to be noted that in various embodiments, signal electric charges (electrons) are extracted from the lower electrode 15a; therefore, in the solid-state imaging device 1 to be described later that uses the photoelectric conversion element 10 as each of the unit pixels P, the lower electrode 15a may be provided separately for each of the pixels.

The organic photoelectric conversion layer 17 includes three kinds of organic semiconductor materials, e.g., a first organic semiconductor material, a second organic semiconductor material, and a third organic semiconductor material. The organic photoelectric conversion layer 17 may include one or both of a p-type semiconductor and an n-type semiconductor, and one of the three kinds of organic semiconductor materials mentioned above may be the p-type semiconductor or the n-type semiconductor. The organic photoelectric conversion layer 17 may perform photoelectric conversion on light in a selective wavelength region, and may allow light in other wavelength regions to pass through. In the present embodiment, the organic photoelectric conversion layer 17 may have a maximal absorption wavelength in a range from 450 nm to 650 nm both inclusive.

As the first organic semiconductor material, a material having a high electron transporting property may be used, and non-limiting examples of such a material may include C60 fullerene and a derivative thereof represented by the following formula (1), and C70 fullerene and a derivative thereof represented by the following formula (2). It is to be noted that in various embodiments, fullerenes are treated as organic semiconductor materials.

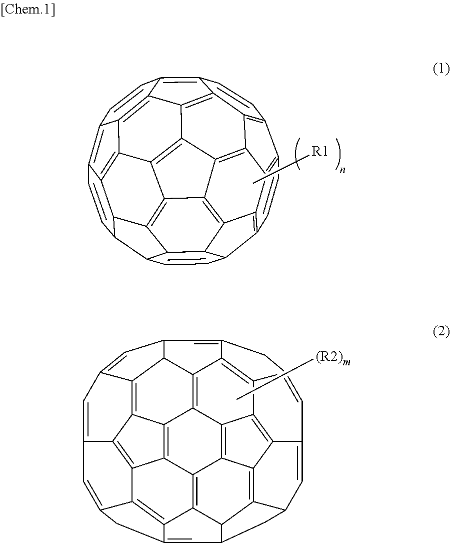

where each of R1 and R2 is independently one of a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfanyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, and derivatives thereof, and each of “n” and “m” is 0 or an integer of 1 or more.

Specific but non-limiting examples of the first organic semiconductor material may include not only C60 fullerene represented by a formula (1-1), C70 fullerene represented by a formula (2-1) but also compounds represented by the following formulas (1-2), (1-3), and (2-2) as derivatives of C60 fullerene and C70 fullerene.

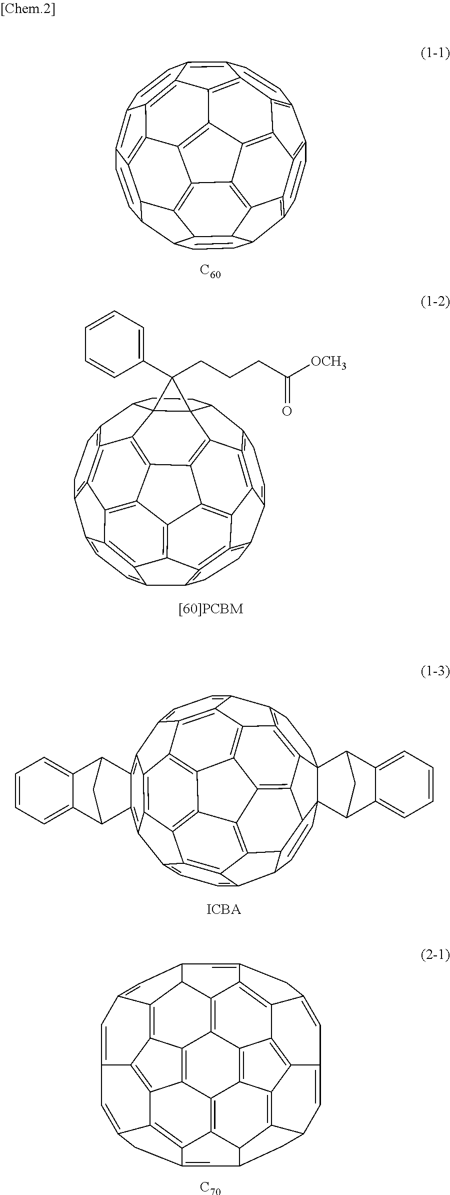

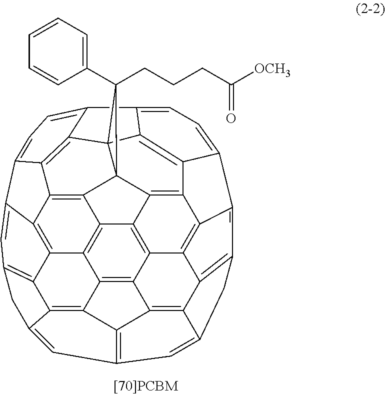 [SMILES: COC(=O)CCCC1(c2ccccc2)C23c4c5ccc6c7cc8c9c%10c(cc%11cc%12c%13c%14c(cc%15c%16ccc-5c2c%16c2c5c%16c%17c(c(c46)c7c9c%17c4c%10c%11c%13c4c%16c%14c%152)C513)C%12)C8]

Table 1 provides a summary of electron mobility of C60 fullerene (the formula (1-1)), C70 fullerene (the formula (2-1)), and the fullerene derivatives represented by the foregoing formulas (1-2), (1-3), and (2-2). Using an organic semiconductor material having high electron mobility, which may be 10⁻⁷ cm²/Vs or more, or may be 10⁻⁴ cm²/Vs or more, may improve electron mobility resulting from separation of excitons into electric charges, and may improve responsivity of the organic photoelectric converter 11G.

TABLE 1

| | Electron Mobility (cm²/Vs) |
|---|---|
| C60 Fullerene | 2 × 10⁻² |
| C70 Fullerene | 3 × 10⁻³ |
| [60]PCBM | 5 × 10⁻² |
| [70]PCBM | 3 × 10⁻⁴ |
| ICBA | 2 × 10⁻³ |

As the second organic semiconductor material, an organic semiconductor material having a shallower lowest unoccupied molecular orbital (LUMO) level than a LUMO level of the first organic semiconductor material may be used. Moreover, the second organic semiconductor material may be a material having a shallower LUMO level by 0.2 eV or more than the LUMO level of the first organic semiconductor material, which suppresses generation of a dark current between the second organic semiconductor material and the third organic semiconductor material in the organic photoelectric conversion layer 17. As a specific but non-limiting example, the LUMO level of the second organic semiconductor material may be shallower than −4.5 eV, and may be −4.3 eV or more. The organic semiconductor material makes it possible to suppress generation of a dark current, as described in detail later.

Moreover, as the second organic semiconductor material, an organic semiconductor material in a form of a single-layer film may have a higher linear absorption coefficient of a maximal absorption wavelength in a visible light region than a single-layer film of the first organic semiconductor material and a single-layer film of the third organic semiconductor material to be described later. In various embodiments, the first, second, and third organic semiconductor materials may have such properties in comparison to each other as single-layer films when they are used in the devices described herein. For example, the first, second, and third organic semiconductor materials may have such properties in comparison to each other as single-layer films although they can used in the devices described herein as other than single-layer films. Said another way, although the first, second, and third organic semiconductor materials may have such properties when measured in states of being single-layer films, these first, second, and third organic semiconductor materials having such measured properties may be used in the devices herein as non-single layer films. This makes it possible to enhance absorption capacity of light in a visible light region of the organic photoelectric conversion layer 17 and to sharpen a spectroscopic shape. For example, in various embodiments in which the organic photoelectric converter 11G absorbs green light, the second organic semiconductor material may have a maximal absorption wavelength in a wavelength region from 500 nm to 600 nm both inclusive. It is to be noted that the visible light region here is in a range from 450 nm to 800 nm both inclusive. The single-layer film here is referred to as a single-layer film made of one kind of organic semiconductor material. This similarly applies to the following single-layer film in each of the second organic semiconductor material and the third organic semiconductor material.

It is to be noted that in various embodiments in which the organic photoelectric converter 11G absorbs green light, the second organic semiconductor material may have, for example, a maximal absorption wavelength in a wavelength region from 530 nm to 580 nm both inclusive.

Specific but non-limiting examples of the second organic semiconductor material may include subphthalocyanine represented by the following formula (3) and a derivative thereof.

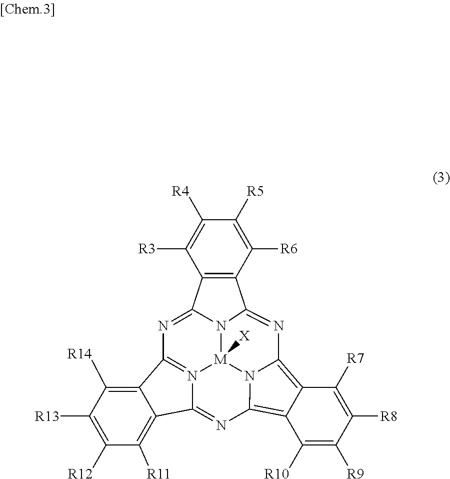

In formula (3), each of R3 to R14 is independently selected from a group configured of a hydrogen atom, a halogen atom, a straight-chain, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, a phenyl group, a carboxy group, a carboxyamide group, a carboalkoxy group, an acyl group, a sulfonyl group, a cyano group, and a nitro group, any adjacent ones of R3 to R14 are optionally part of a condensed aliphatic ring or a condensed aromatic ring, the condensed aliphatic ring or the condensed aromatic ring optionally includes one or more atoms other than carbon, M is one of boron and a divalent or trivalent metal, and X is an anionic group.

Specific but non-limiting examples of the subphthalocyanine derivative represented by the formula (3) may include compounds represented by the following formulas (3-1) to (3-23). For example, F₆ subphthalocyanine (F₆SubPc) derivatives, in which R4, R5, R8, R9, R12, and R13 are substituted by fluorines (F), represented by the formulas (3-1) to (3-18) selected from the formula (3-1) to (3-23) may be used. Moreover, the F₆ SubPc derivatives, in which —OPh group is axially bound to boron (B), represented by the formulas (3-2) to (3-5), (3-8), (3-9), and (3-11) to (3-15) may be used, or F₆SubPc derivatives, in which hydrogen (H) of a —OPh group axially bound to B is substituted by 1 to 4 fluorines (F), represented by the formulas (3-2), (3-3), (3-5), (3-8), (3-9), (3-11) to (3-13), and (3-15) may be used.

In a case where M of the subphthalocyanine derivative represented by the formula (3) is boron (B), if an atom in X bound to the B is a halogen atom such as chlorine (Cl) and bromine (Br), bonding force of the halogen atom with respect to B is relatively weak, which may cause X to be separated from a subphthalocyanine skeleton by a load such as heat or light. Non-limiting examples of an atom having high bonding force with respect to B may include nitrogen (N) and carbon (C) in addition to oxygen (O) of the foregoing —OPh group.

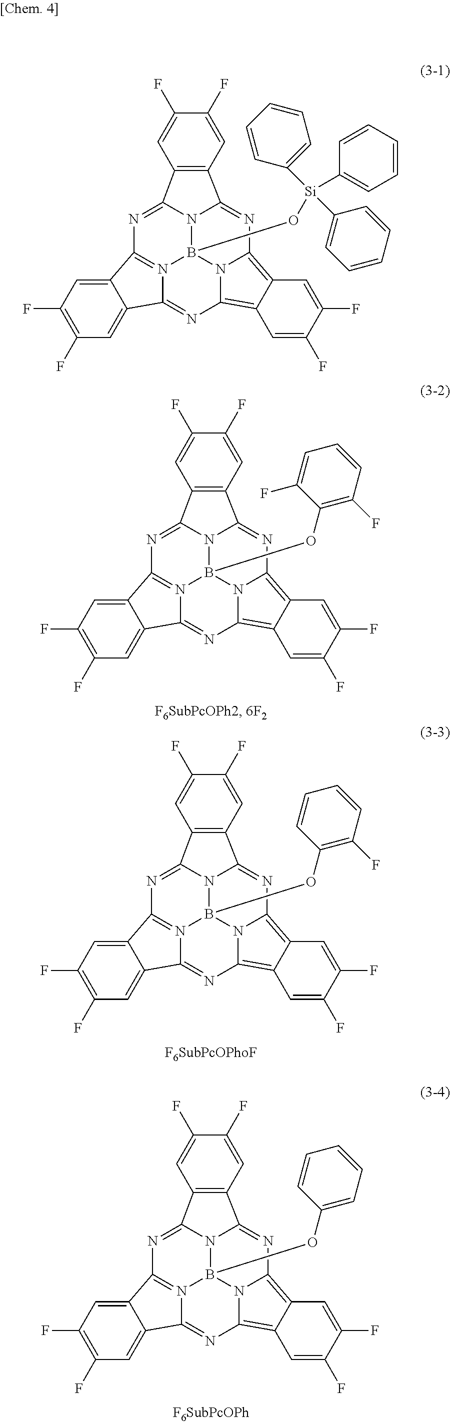

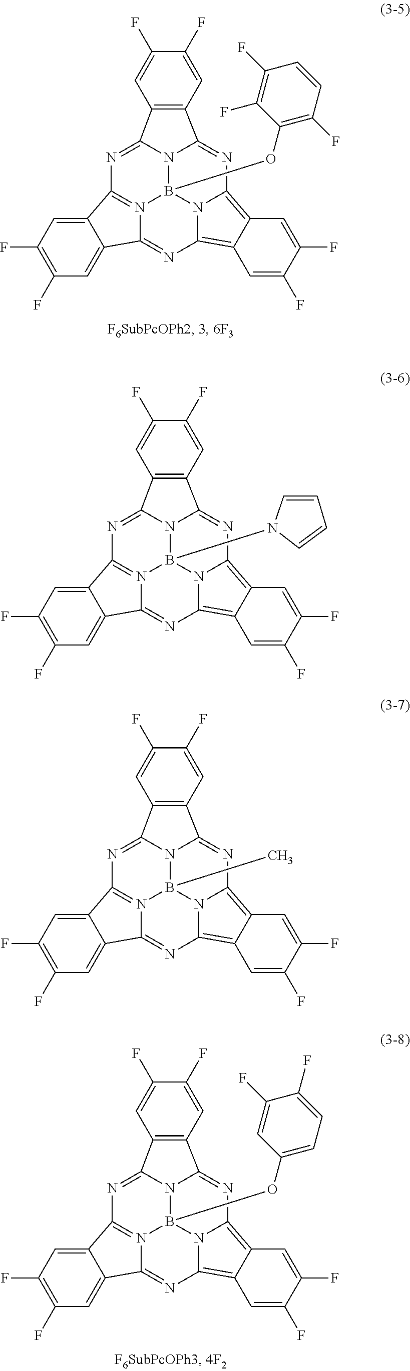

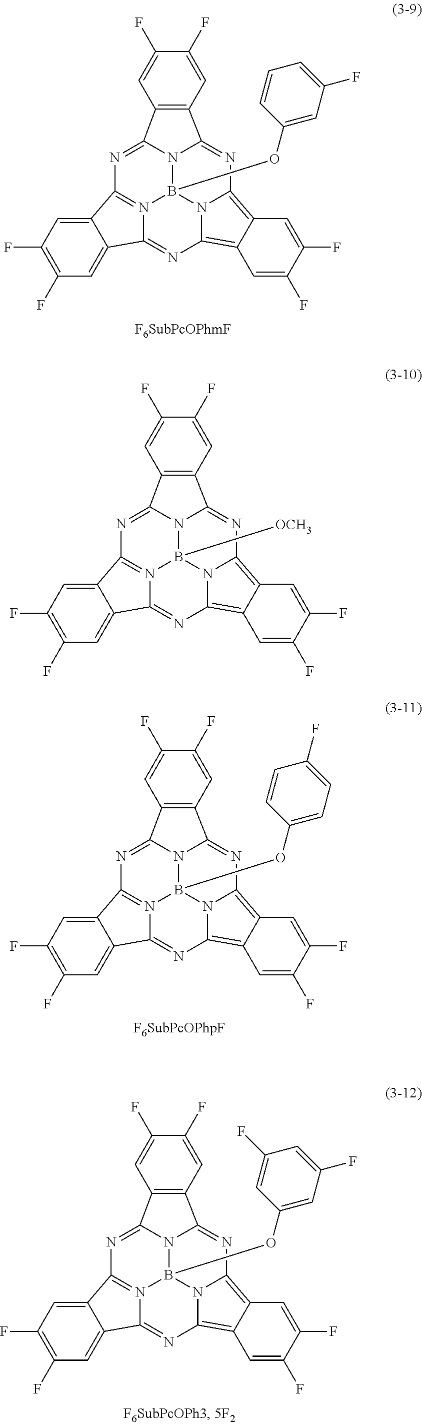

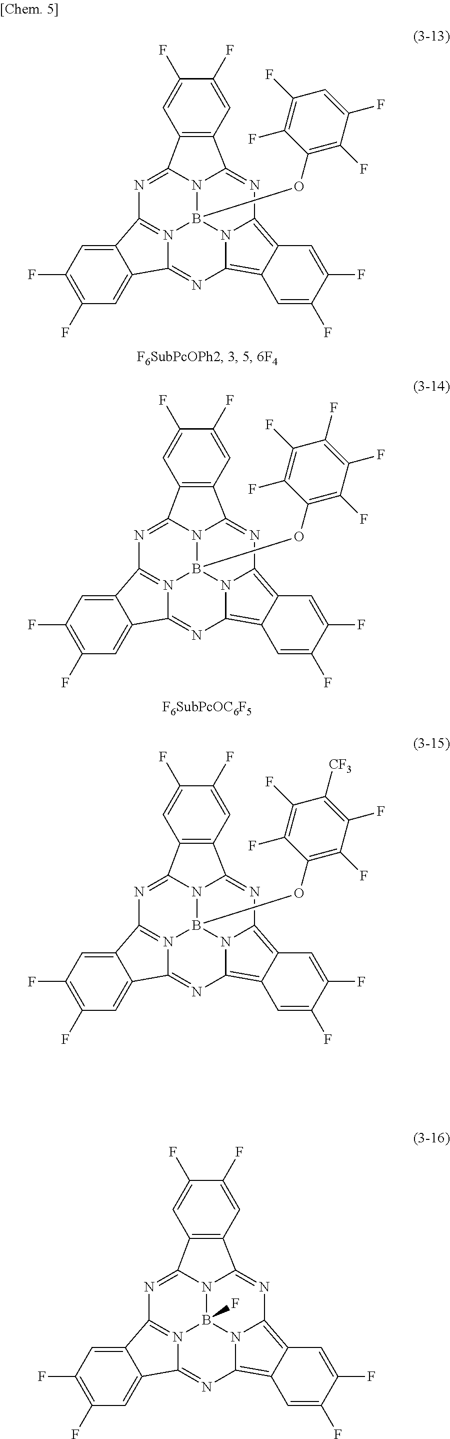

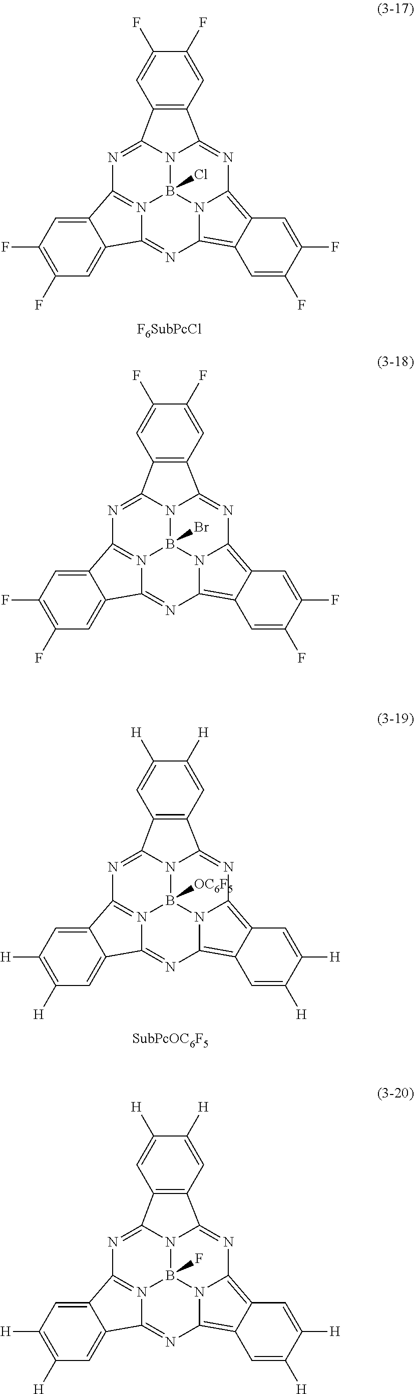

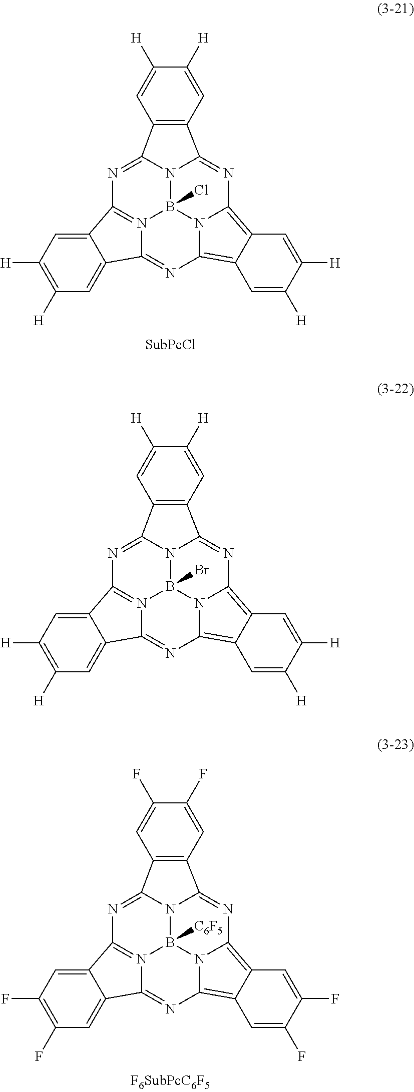

The third organic semiconductor material may have a high hole transporting property. More specifically, an organic semiconductor material in a form of a single-layer film having higher hole mobility than hole mobility of the single-layer film of the second organic semiconductor material may be used. In various embodiments, the second and third organic semiconductor materials may have such properties in comparison to each other as single-layer films when they are used in the devices described herein. For example, the second and third organic semiconductor materials may have such properties in comparison to each other as single-layer films although they can be used in the devices described herein as other than single-layer films. Said another way, although the second and third organic semiconductor materials may have such properties when measured in states of being single-layer films, these second and third organic semiconductor materials having such measured properties may be used in the devices herein as non-single layer films. Moreover, the third organic semiconductor material may have a shallower highest occupied molecular orbital (HOMO) level than a HOMO level of the first organic semiconductor material and a HOMO level of the second organic semiconductor material. For example, the third organic semiconductor material may have a HOMO level that allows a difference in HOMO level between the third organic semiconductor material and the first organic semiconductor material to be less than 0.9 eV, which suppresses generation of a dark current between the first organic semiconductor material and the third organic semiconductor material in the organic photoelectric conversion layer 17.

Moreover, the difference in HOMO level between the third organic semiconductor material and the first organic semiconductor material may be less than 0.7 eV, which stably suppresses generation of a dark current between the first organic semiconductor material and the third organic semiconductor material in the organic photoelectric conversion layer 17. Further, the difference in HOMO level between the third organic semiconductor material and the first organic semiconductor material may be 0.5 eV or more and less than 0.7 eV, which makes it possible to improve photoelectric conversion efficiency in addition to suppression of generation of a dark current.

Specific but non-limiting examples of the HOMO level of the third organic semiconductor material may be deeper than −5.4 eV, or may be deeper than −5.6 eV.

The third organic semiconductor material may have a shallower LUMO level than the LUMO level of the second organic semiconductor material. Moreover, the third organic semiconductor material may have a shallower LUMO level than the LUMO level of the first organic semiconductor material. In other words, the third organic semiconductor material may have the shallowest LUMO level among the first organic semiconductor material, the second organic semiconductor material, and the third organic semiconductor material.

Moreover, the third organic semiconductor material may be a material exhibiting crystallinity in the organic photoelectric conversion layer 17, and a particle diameter of a crystal component of the material may be, for example, in a range from 6 nm to 12 nm both inclusive. For example, the third organic semiconductor material may be a material having a herringbone crystal structure in the organic photoelectric conversion layer 17, which reduces a contact area between the first organic semiconductor material and the third organic semiconductor material and suppresses generation of a dark current between the first organic semiconductor material and the third organic semiconductor material in the organic photoelectric conversion layer 17. Moreover, this reduces a contact area between the second organic semiconductor material and the third organic semiconductor material and suppresses generation of a dark current between the second organic semiconductor material and the third organic semiconductor material in the organic photoelectric conversion layer 17. Further, having crystallinity improves a hole transporting property of the third organic semiconductor material and improves responsivity of the photoelectric conversion element 10.

Further, in various embodiments in which the organic photoelectric converter 11G absorbs green light, the third organic semiconductor material may have absorption only in a wavelength region of 500 nm or less without having absorption in a wavelength region longer than 500 nm. Alternatively, the third organic semiconductor material may have absorption only in a wavelength region of 450 nm or less without having absorption in a wavelength region longer than 450 nm.

Specific but non-limiting examples of the third organic semiconductor material may include compounds represented by the following formula (4) and the following formula (5).

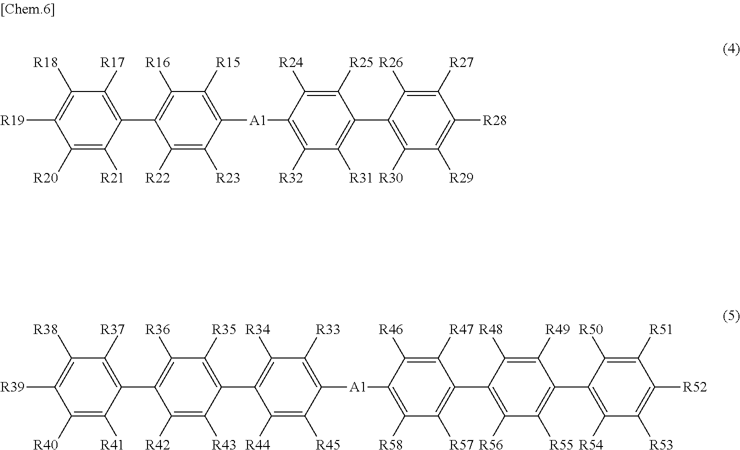

In the formula (4), each of A1 and A2 is one of a conjugated aromatic ring, a condensed aromatic ring, a condensed aromatic ring including a hetero element, oligothiophene, and thiophene, each of which is optionally substituted by one of a halogen atom, a straight-chain, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, a carboxy group, a carboxyamide group, a carboalkoxy group, an acyl group, a sulfonyl group, a cyano group, and a nitro group, each of R15 to R58 is independently selected from a group configured of a hydrogen atom, a halogen atom, a straight-chain, branched, or cyclic alkyl group, a thioalkyl group, an aryl group, a thioaryl group, an arylsulfonyl group, an alkylsulfonyl group, an amino group, an alkylamino group, an arylamino group, a hydroxy group, an alkoxy group, an acylamino group, an acyloxy group, a phenyl group, a carboxy group, a carboxyamide group, a carboalkoxy group, an acyl group, a sulfonyl group, a cyano group, and a nitro group, and any adjacent ones of R15 to R23, any adjacent ones of R24 to R32, any adjacent ones of R33 to R45, and any adjacent ones of R46 to R58 are optionally bound to one another to form a condensed aromatic ring.

In the compounds represented by the formula (4) and the formula (5), each of A1 and A2 may not include a substituent. Each of R15 to R58 may be a hydrogen atom. The compound represented by the formula (4) and the compound represented by the formula (5) may have a symmetric structure with respect to A1 and A2, respectively. Two biphenyls bound to A1 of the compound represented by the formula (4) may have a same chemical structure, and two terphenyls bound to A2 of the compound represented by the formula (5) may have a same chemical structure.

Specific but non-limiting examples of the compound represented by the formula (4) may include compounds represented by the following formulas (4-1) to (4-11).

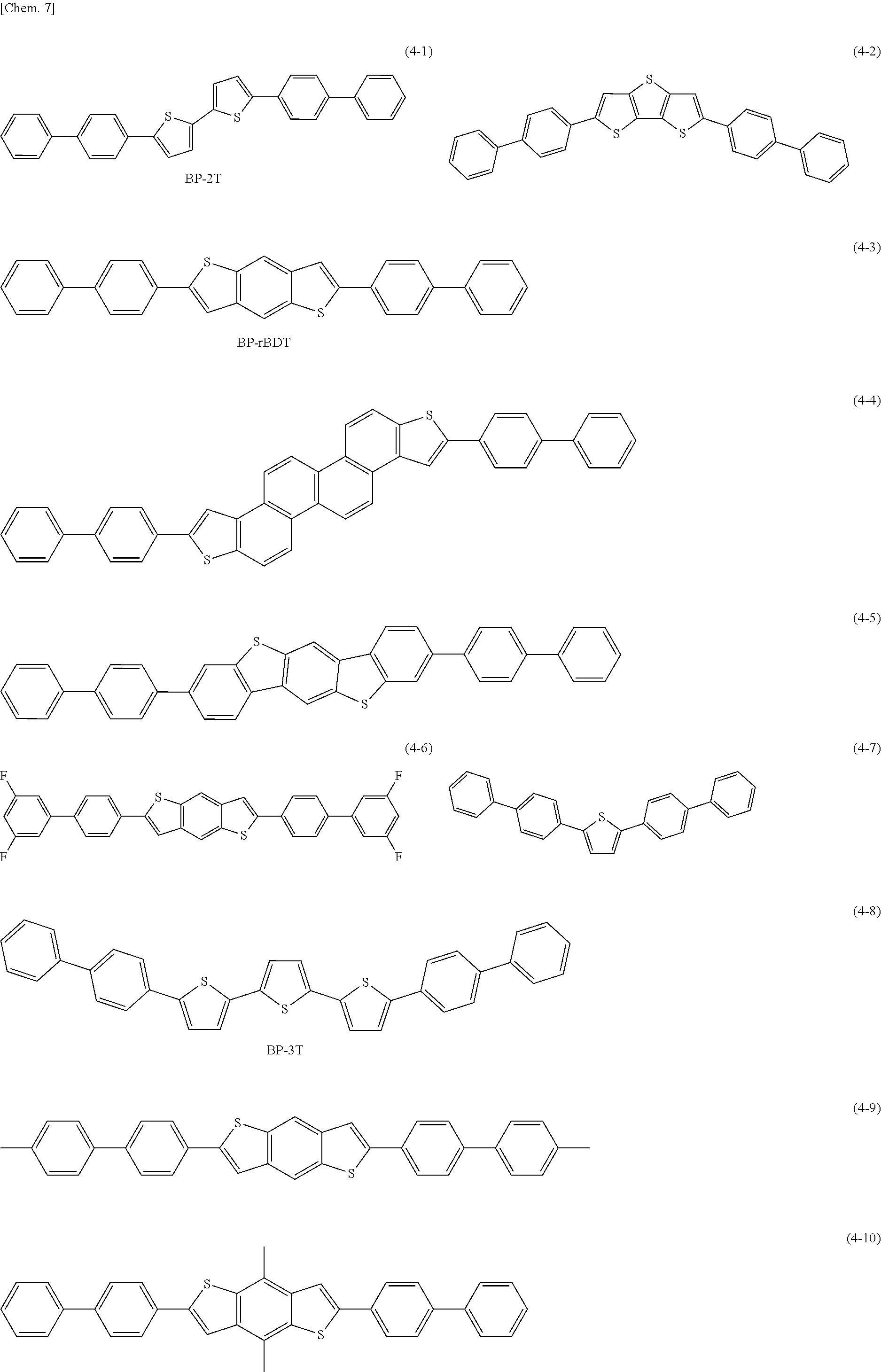

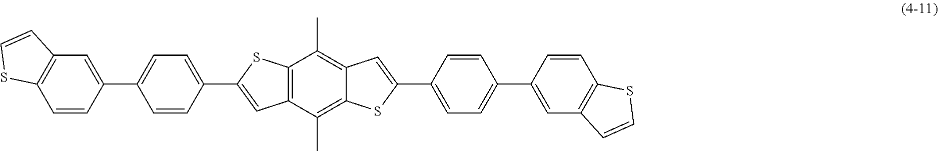 [SMILES: Cc1c2cc(-c3ccc(-c4ccc5sccc5c4)cc3)sc2c(C)c2cc(-c3ccc(-c4ccc5sccc5c4)cc3)sc12]

Specific but non-limiting examples of the compound represented by the formula (5) may include compounds represented by the following formulas (5-1) to (5-6).

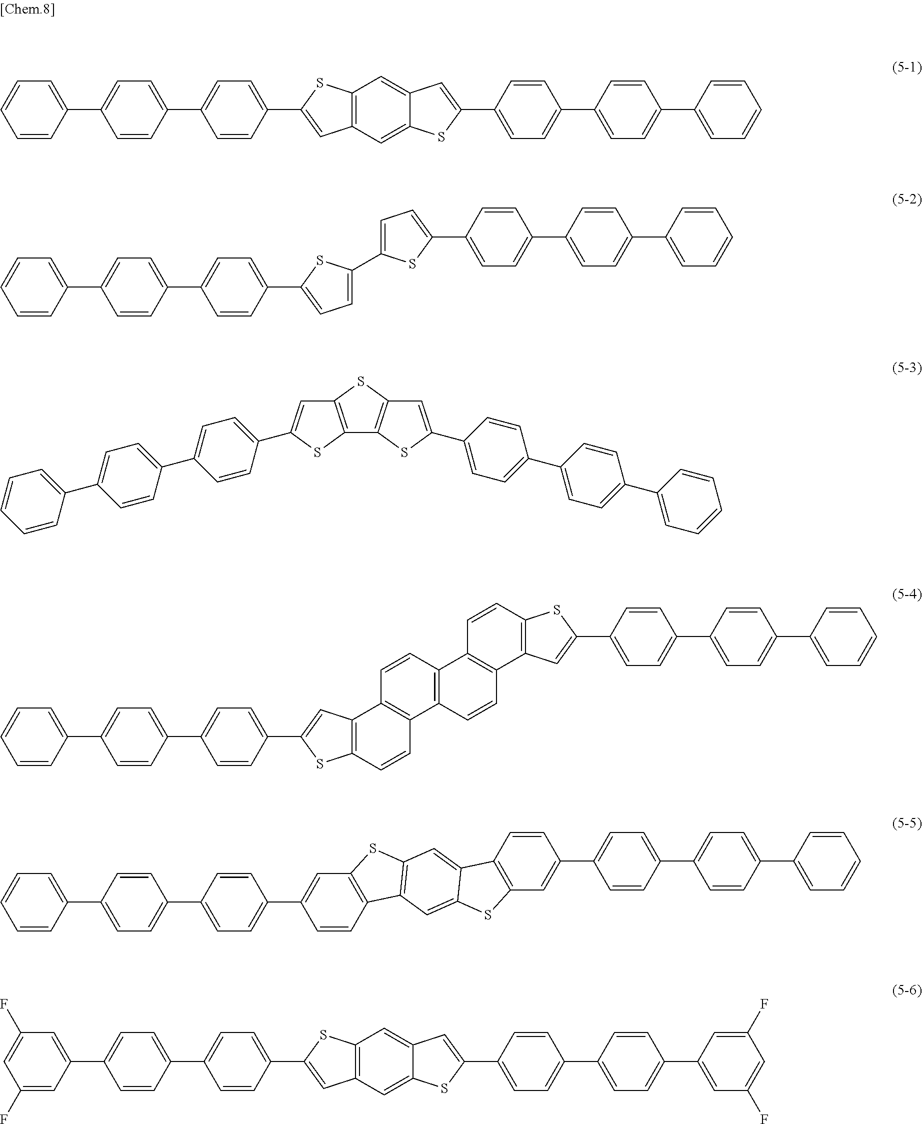

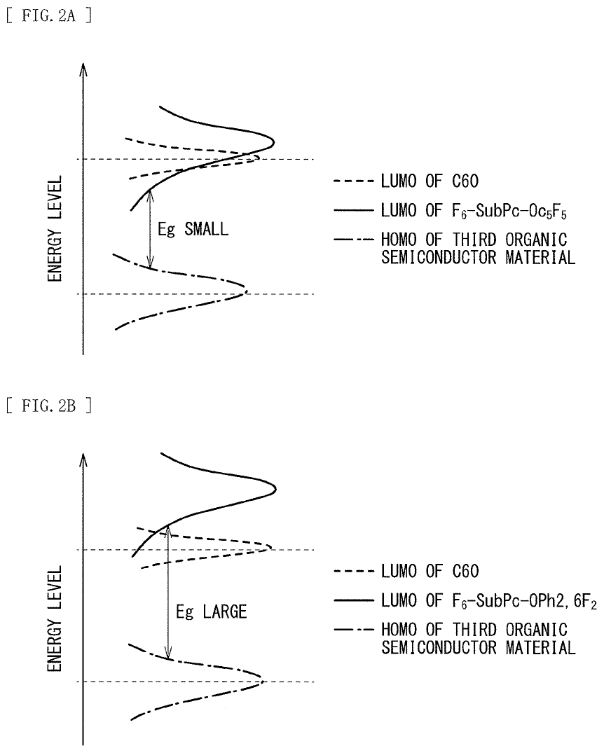

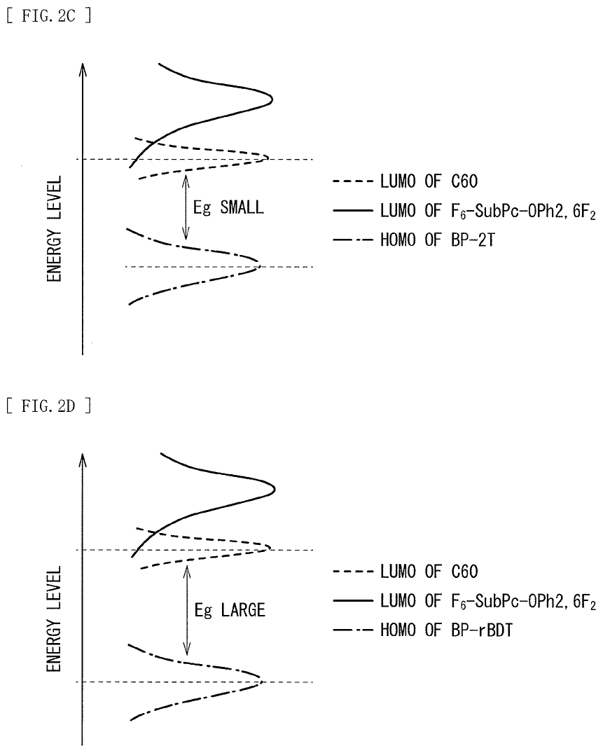

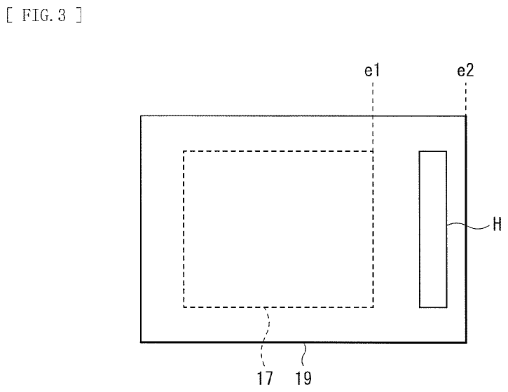

The second organic semiconductor material may have a shallower LUMO level than the LUMO level of the first organic semiconductor material, as described above, which causes a large difference in energy level between the HOMO level of the third organic semiconductor material and the LUMO level of the second organic semiconductor material. FIG. 2A illustrates energy levels of C60, F₆-SubPc-OC₆F₅, and the third organic semiconductor material. FIG. 2B illustrates energy levels of C60, F₆-SubPc-OPh2,6F₂, and the third organic semiconductor material. FIG. 2C illustrates energy levels of C60, F₆-SubPc-OPh2,6F₂, and the third organic semiconductor material in a case where BP-2T represented by the formula (4-1) is used as the third organic semiconductor material. FIG. 2D illustrates energy levels of C60, F₆-SubPc-OPh2,6F₂, and the third organic semiconductor material in a case where BP-rBDT represented by the formula (4-3) is used as the third organic semiconductor material.

As can be seen from FIG. 2B, using, as the second organic semiconductor material, a subphthalocyanine derivative (F₆-SubPc-OPh2,6F₂) having a shallower LUMO level than the LUMO level of the first organic semiconductor material (C60) causes a lower end of energy of the second organic semiconductor material to be located higher than a lower end of energy of the first organic semiconductor material. In other words, a difference in energy level between a HOMO of the third organic semiconductor material and a LUMO of the second organic semiconductor material is increased. Increasing the difference in energy level between the HOMO of the third organic semiconductor material having a high hole transporting property and the LUMO of the second organic semiconductor material in such a manner suppresses generation of a dark current from the HOMO of the third organic semiconductor material to the LUMO of the second organic semiconductor material.

It is to be noted that any organic semiconductor material satisfying the conditions mentioned above other than the compounds represented by the foregoing formulas (4) and (5) may be used as the third organic semiconductor material. Specific but non-limiting examples of the third organic semiconductor material other than the foregoing compounds may include quinacridone and a derivative thereof represented by the following formula (6), triallylamine represented by the following formula (7) and a derivative thereof, and benzothienobenzothiophene represented by a formula (8) and a derivative thereof.

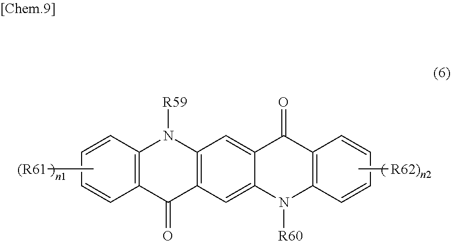

In the formula (6), each of R59 and R60 is independently one of a hydrogen atom, an alkyl group, an aryl group, and a heterocyclic group, each of R61 and R62 is any group and is not specifically limited, but, for example, each of R61 and R62 is independently one of an alkyl chain, an alkenyl group, an alkynyl group, an aryl group, a cyano group, a nitro group, and a silyl group, and two or more of R61 or two or more of R62 optionally form a ring together, and each of n1 and n2 is independently 0 or an integer of 1 or more.

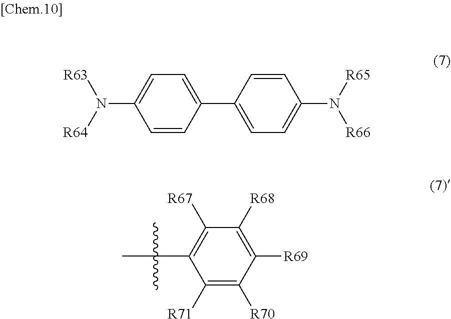

In the formula (7), each of R63 to R66 is independently a substituent represented by a formula (7)′, each of R67 to R71 is independently one of a hydrogen atom, a halogen atom, an aryl group, an aromatic hydrocarbon ring group, an aromatic hydrocarbon ring group having an alkyl chain or a substituent, an aromatic heterocyclic group, and an aromatic heterocyclic group having an alkyl chain or a substituent, adjacent ones of R67 to R71 are optionally saturated or unsaturated divalent groups that are bound to one another to form a ring.

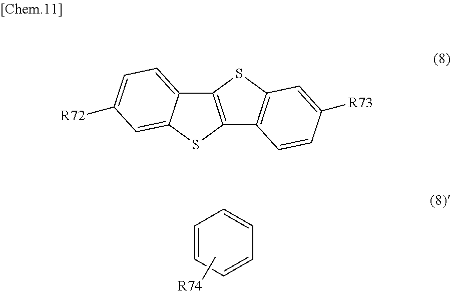

In the formula (8), each of R72 and R73 is independently one of a hydrogen atom and a substituent represented by a formula (8)′, and R74 is one of an aromatic ring group and an aromatic ring group having a substituent.

Specific but non-limiting examples of the quinacridone derivative represented by the formula (6) may include compounds represented by the following formulas (6-1) to (6-3).

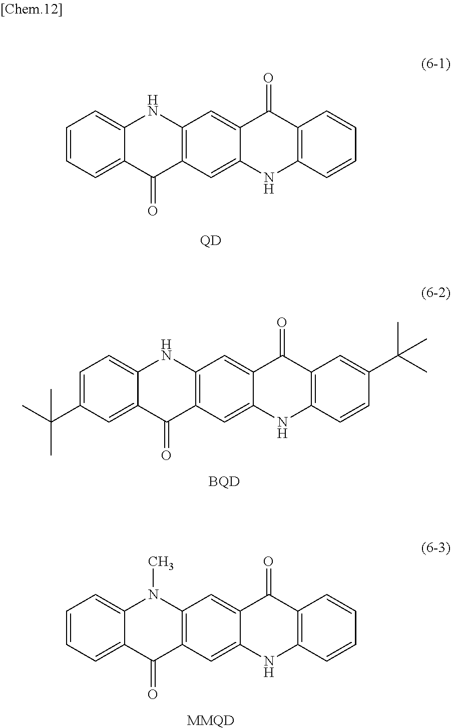

Specific but non-limiting examples of the triallylamine derivative represented by the formula (7) may include compounds represented by the following formulas (7-1) to (7-13).

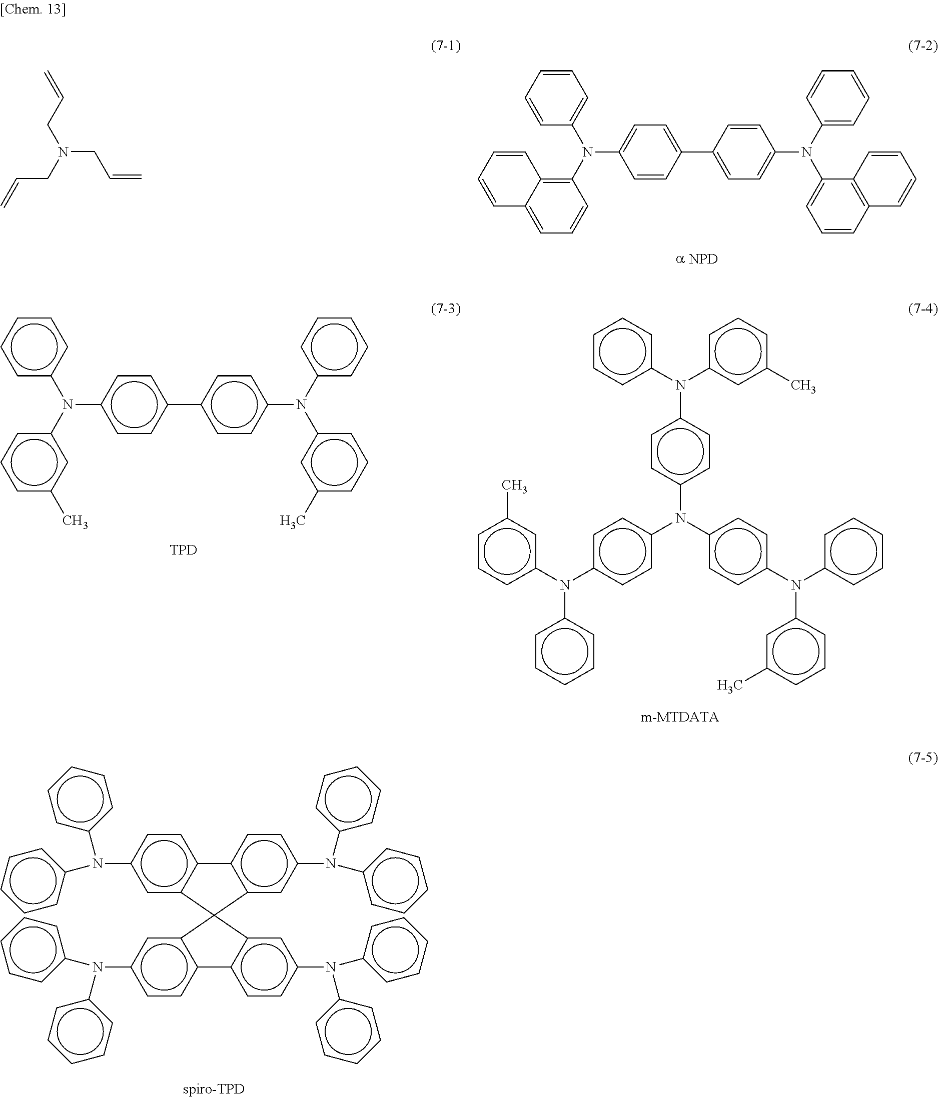

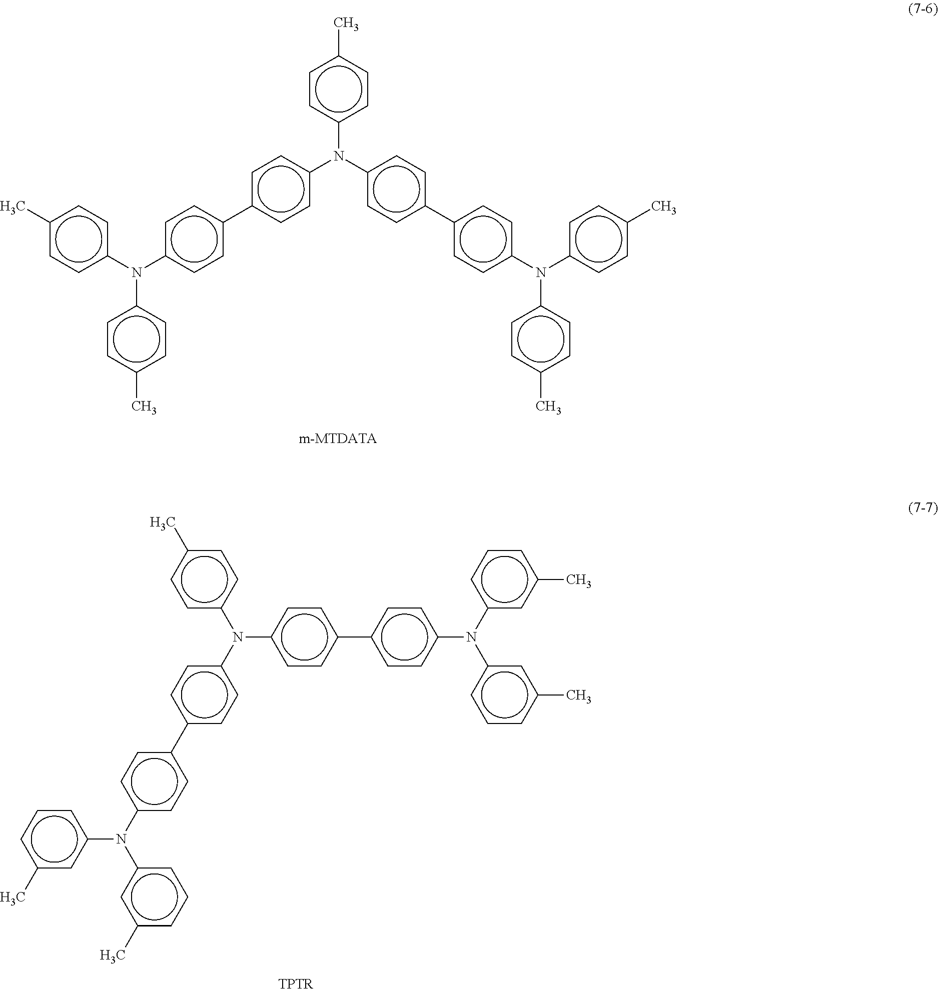

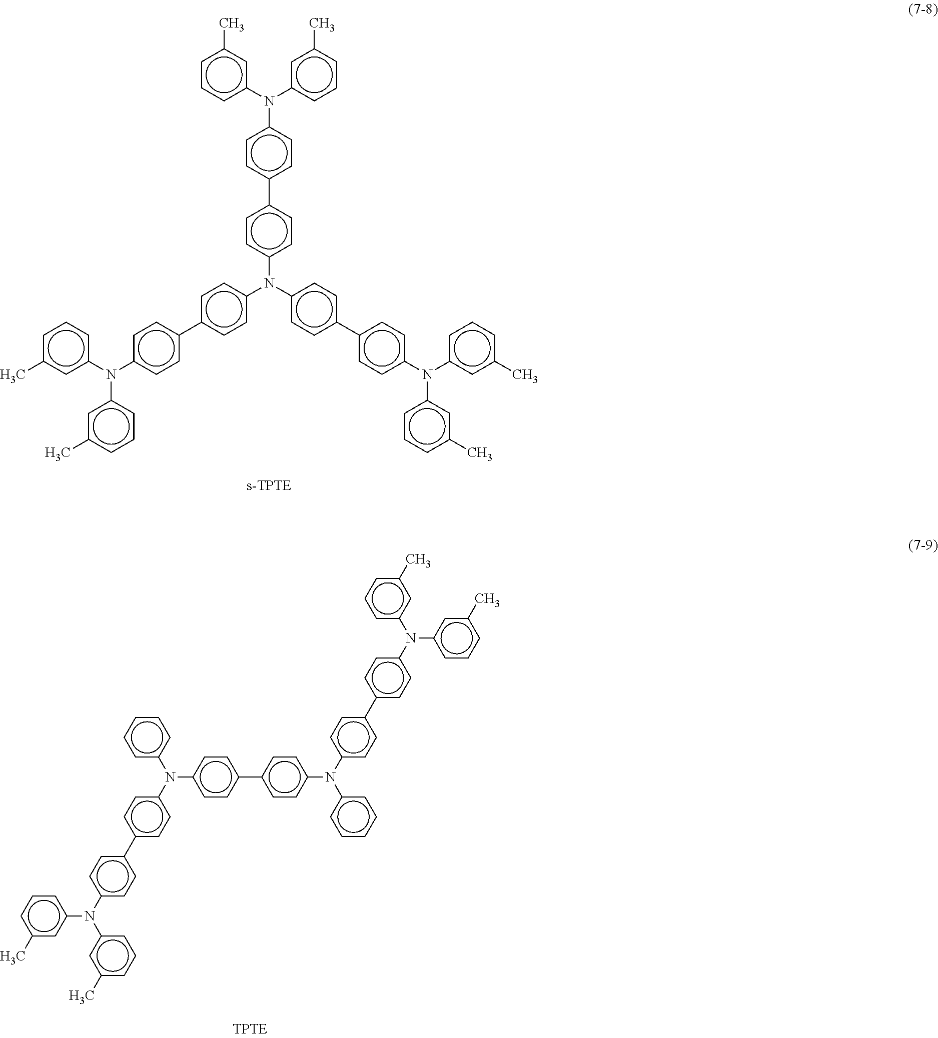

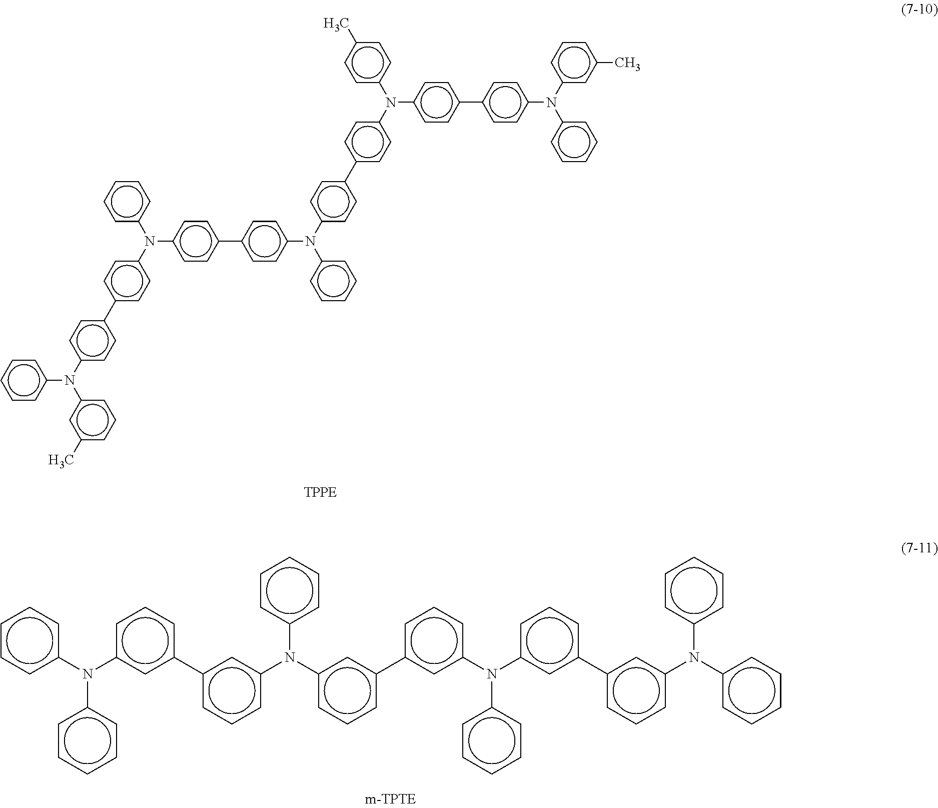

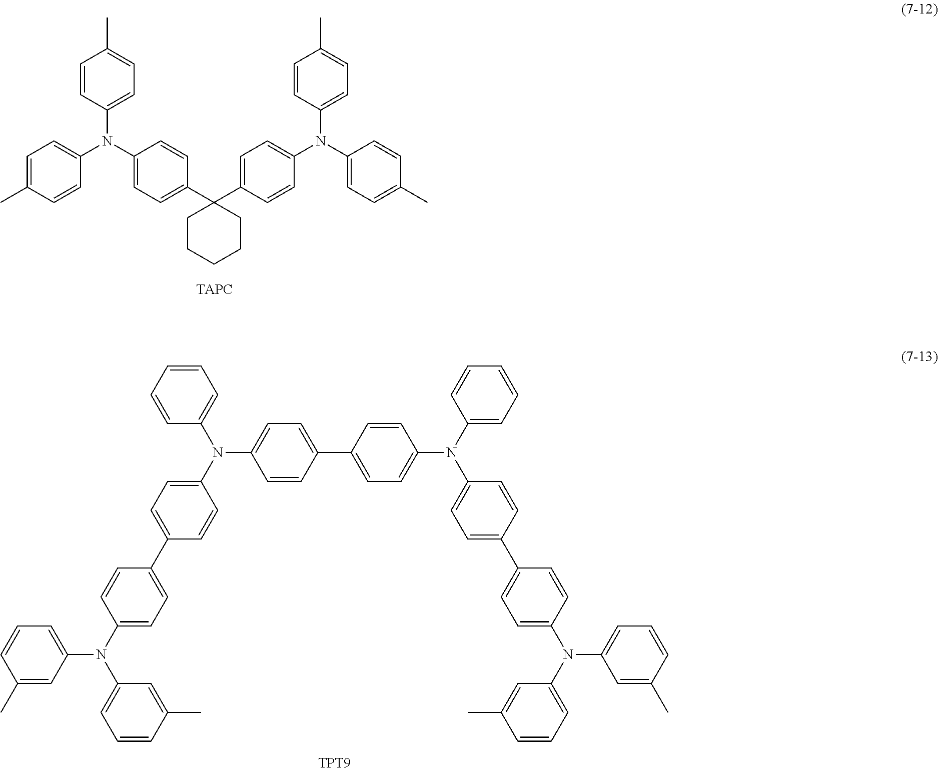

It is to be noted that in a case where the triallylamine derivative is used as the third organic semiconductor material, the triallylamine derivative is not limited to the compounds represented by the foregoing formulas (7-1) to (7-13), and may be any triallylamine derivative having a HOMO level equal to or more than the HOMO level of the second organic semiconductor material. Moreover, the triallylamine derivative may be any triallylamine derivative that has higher hole mobility in a form of a single-layer film (e.g., as a single-layer film) than hole mobility of the second organic semiconductor material as a single-layer film.

Specific but non-limiting examples of the benzothienobenzothiophene derivative represented by the formula (8) may include compounds represented by the following formulas (8-1) to (8-6).

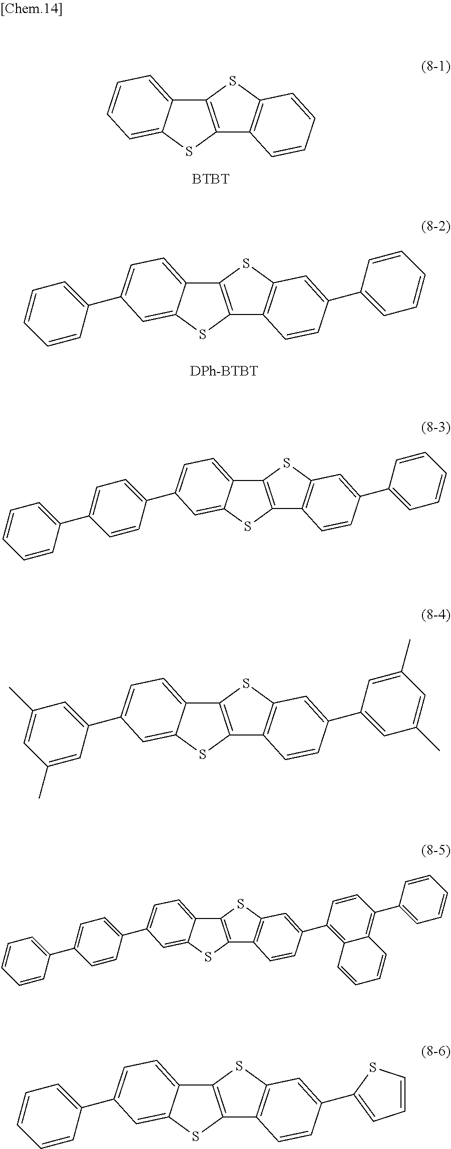

Non-limiting examples of the third organic semiconductor material may include rubrene represented by the following formula (9) and N,N′-di(1-naphthyl-N,N′-diphenylbenzidine (αNPD) represented by the foregoing formula (7-2) and a derivative thereof, in addition to quinacridone and the derivative thereof, triallylamine and the derivative thereof, and benzothienobenzothiophene and the derivative thereof mentioned above. Note that the third organic semiconductor material may include a hetero atom other than carbon (C) and hydrogen (H) in a molecule of the third organic semiconductor material. Non-limiting examples of the hetero atom may include nitrogen (N), phosphorus (P), and chalcogen elements such as oxygen (O), sulfur (S), and selenium (Se).

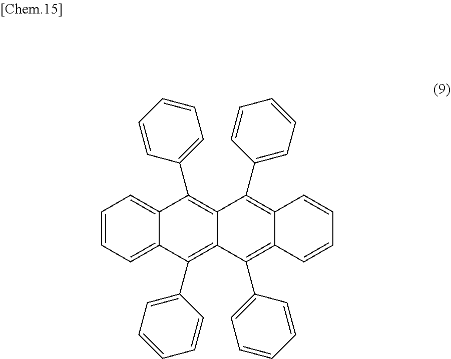 [SMILES: c1ccc(-c2c3ccccc3c(-c3ccccc3)c3c(-c4ccccc4)c4ccccc4c(-c4ccccc4)c23)cc1]

Table 2 and Table 3 provide summaries of HOMO levels (Table 2) and hole mobility (Table 3) of SubPcOC₆F₅ represented by the formula (3-19) and F₆SubPcCl represented by the formula (3-17) as examples of a material applicable as the second organic semiconductor material, quinacridone (QD) represented by the formula (6-1), butylquinacridone (BQD) represented by the formula (6-2), αNPD represented by the formula (7-2), [1]Benzothieno[3,2-b][1]benzothiophene (BTBT) represented by the formula (8-1), and rubrene represented by the formula (9) as examples of a material applicable as the third organic semiconductor material, and Du-H as a reference. The third organic semiconductor material may have a HOMO level equal to or more than the HOMO level of the second organic semiconductor material. Moreover, a single-layer film of the third organic semiconductor material may have higher hole mobility than hole mobility of a single-layer film of the second organic semiconductor material. For example, the second and third organic semiconductor materials may have such properties when measured in states of being single-layer films, although these second and third organic semiconductor materials having such measured properties may be used in the devices herein as non-single layer films. The HOMO level of the third organic semiconductor material may be, for example, 10⁻⁷ cm²/Vs or more, or 104 cm²Vs or more. Using such organic semiconductor materials improves hole mobility resulting from separation of excitons into electric charges. This achieves balance with a high electron transporting property supported by the first organic semiconductor material, thereby improving responsivity of the organic photoelectric converter 11G. It is to be noted that −5.5 eV that is the HOMO level of QD is higher and shallower than −6.3 eV that is the HOMO level of F₆SubPcOCl.

It is to be noted that the HOMO levels illustrated in Table 2 and the hole mobility illustrated in Table 3 were obtained by the following calculation methods. The HOMO levels were obtained as follows. A single-layer film (having a film thickness of 20 nm) of each of the organic semiconductor materials illustrated in Table 2 was formed, and ultraviolet light of 21.23 eV was applied to the single-layer film to obtain a kinetic energy distribution of electrons emitted from a sample surface, and an energy width of a spectrum of the kinetic energy distribution was subtracted from an energy value of the applied ultraviolet light to obtain the HOMO level. The hole mobility was obtained as follows. A photoelectric conversion element including a single-layer film of each of the organic semiconductor materials was fabricated, and the hole mobility of each of the organic semiconductor materials was calculated with use of a semiconductor parameter analyzer. More specifically, a bias voltage to be applied between electrodes was swept from 0 V to −5 V to obtain a current-voltage curve, and thereafter, the curve was fit with a space charge limited current model to determine a relational expression between mobility and voltage, thereby obtaining the hole mobility. It is to be noted that the hole mobility illustrated in Table 3 is hole mobility at −1 V.

TABLE 2

| | HOMO (eV) |
|---|---|
| QD | −5.5 |
| αNPD | −5.5 |
| BTBT | −5.6 |
| SubPcOC₆F₅ | −5.9 |
| Du-H | −6.1 |
| F₆SubPcCl | −6.3 |
| BQD | −5.6 |
| rubrene | −5.5 |

TABLE 3

| | Hole Mobility (cm²/Vs) |
|---|---|
| QD | 2 × 10⁻⁵ |
| αNPD | >10⁻⁴ |
| BTBT | >10⁻³ |
| SubPcOC₆F₅ | 1 × 10⁻⁸ |
| Du-H | 1 × 10⁻¹⁰ |
| F₆SubPcCl | <10⁻¹⁰ |
| BQD | 1 × 10⁻⁶ |
| rubrene | 3 × 10⁻⁶ |

Moreover, in the subphthalocyanine derivative applicable as the second organic semiconductor material, changing X represented by the formula (6) makes it possible to change the HOMO level (refer to Table 5). Table 5 to be described later provides a summary of HOMO levels, LUMO levels, maximal absorption wavelengths, and maximal linear absorption coefficients of the compounds represented by the foregoing formulas (3-1) to (3-15). As can be seen from Table 5, a HOMO level of a compound in which —OPh group configuring X was substituted by F or a substituent including F was a value ranging from −6 eV to −6.7 eV. Moreover, even a compound including N or C as an atom directly bound to M had a similar value. The second organic semiconductor material may have a HOMO level of −6.5 eV or more within the foregoing range, and may have a HOMO level of −6.3 eV or more within the foregoing range. Using the second organic semiconductor material having a HOMO level of −6.5 eV or more makes it possible to suppress generation of a dark current. In various embodiments, the second organic semiconductor material may have a HOMO level of −6.5 eV or more, which suppresses generation of a dark current between the second organic semiconductor material and the third organic semiconductor material.

It is to be noted that the organic photoelectric conversion layer 17 in various embodiments uses, as the second organic semiconductor material, one or both of the organic semiconductor material having a shallower LUMO level than the LUMO level of the first organic semiconductor material and the organic semiconductor material having a HOMO level of −6.58 eV or more, which makes it possible to suppress generation of a dark current. Moreover, the second organic semiconductor material may have the foregoing two characteristics (having a shallower LUMO level than the LUMO level of the first organic semiconductor material and having a HOMO level of −6.5 eV or more).

Contents of the first organic semiconductor material, the second organic semiconductor material, and the third organic semiconductor material configuring the organic photoelectric conversion layer 17 may be in the following ranges. The content of the first organic semiconductor material may be, for example, in a range from 10 vol % to 35 vol % both inclusive, the content of the second organic semiconductor material may be, for example, in a range from 30 vol % to 80 vol % both inclusive, and the content of the third organic semiconductor material may be, for example, in a range from 10 vol % to 60 vol % both inclusive. Moreover, in various embodiments, substantially equal amounts of the first organic semiconductor material, the second organic semiconductor material, and the third organic semiconductor material may be included. In a case where the amount of the first organic semiconductor material is too small, electron transporting performance of the organic photoelectric conversion layer 17 declines, which causes a deterioration in responsivity. In a case where the amount of the first organic semiconductor material is too large, the spectroscopic shape may be deteriorated. In a case where the amount of the second organic semiconductor material is too small, light-absorption capacity in the visible light region and the spectroscopic shape may be deteriorated. In a case where the amount of the second organic semiconductor material is too large, electron transporting performance and hole transporting performance decline. In a case where the amount of the third organic semiconductor material is too small, hole transporting property declines, thereby deteriorating responsivity. In a case where the amount of the third organic semiconductor material is too large, light-absorption capacity in the visible light region and the spectroscopic shape may be deteriorated.

Any other unillustrated layer may be provided between the organic photoelectric conversion layer 17 and the lower electrodes 15a and between the organic photoelectric conversion layer 17 and the upper electrode 18. For example, an undercoat film, a hole transport layer, an electron blocking film, the organic photoelectric conversion layer 17, a hole blocking film, a buffer film, an electron transport layer, and a work function adjustment film may be stacked in order from the lower electrode 15a.

The upper electrode 18 may be configured of a conductive film having light transparency as with the lower electrode 15a. In the solid-state imaging device using the photoelectric conversion element 10 as each of the pixels, the upper electrode 18 may be separately provided for each of the pixels, or may be provided as a common electrode for the respective pixels. The upper electrode 18 may have, for example, a thickness of 10 nm to 200 nm both inclusive.

The protective layer 19 may be made of a material having light transparency, and may be, for example, a single-layer film made of one material of materials such as silicon oxide, silicon nitride, and silicon oxynitride or a laminated film made of two or more of these materials. The protective layer 19 may have, for example, a thickness of 100 nm to 30000 nm both inclusive.

The contact metal layer 20 may be made of, for example, one of materials such as titanium (Ti), tungsten (W), titanium nitride (TiN), and aluminum (Al), or may be configured of a laminated film made of two or more of these materials.

The upper electrode 18 and the protective layer 19 may be provided to cover the organic photoelectric conversion layer 17, for example. FIG. 3 illustrates planar configurations of the organic photoelectric conversion layer 17, the protective layer 19 (the upper electrode 18), and the contact hole H.

More specifically, an edge e2 of the protective layer 19 (and the upper electrode 18) may be located outside of an edge e1 of the organic photoelectric conversion layer 17, and the protective layer 19 and the upper electrode 18 may be provided to protrude toward outside of the organic photoelectric conversion layer 17. More specifically, the upper electrode 18 may be provided to cover a top surface and a side surface of the organic photoelectric conversion layer 17, and to extend onto the insulating film 16. The protective layer 19 may be provided to cover a top surface of the upper electrode 18, and may be provided in a similar planar shape to that of the upper electrode 18. The contact hole H may be provided in a region not facing the organic photoelectric conversion layer 17 (a region outside of the edge e1) of the protective layer 19, and may allow part of a surface of the upper electrode 18 to be exposed from the contact hole H. A distance between the edges e1 and e2 is not particularly limited, but may be, for example, in a range from 1 μm to 500 μm both inclusive. It is to be noted that in FIG. 3, one rectangular contact hole H along an end side of the organic photoelectric conversion layer 17 is provided; however, a shape of the contact hole H and the number of the contact holes H are not limited thereto, and the contact hole H may be any other shape (for example, a circular shape or a square shape), and a plurality of contact holes H may be provided.

The planarization layer 21 may be provided on the protective layer 19 and the contact metal layer 20 so as to cover entire surfaces of the protective layer 19 and the contact metal layer 20. An on-chip lens 22 (a microlens) may be provided on the planarization layer 21. The on-chip lens 22 may concentrate light incoming from a top of the on-chip lens 22 onto each of light-reception surfaces of the organic photoelectric converter 11G and the inorganic photoelectric converters 11B and 11R. In various embodiments, the multilayer wiring layer 51 may be provided on the surface S2 of the semiconductor substrate 11, which makes it possible to dispose the respective light-reception surfaces of the organic photoelectric converter 11G and the inorganic photoelectric converters 11B and 11R close to one another. This makes it possible to reduce variation in sensitivity between respective colors caused depending on an F value of the on-chip lens 22.

It is to be noted that in the photoelectric conversion element 10 in various embodiments, signal electric charges (electrons) are extracted from the lower electrode 15a; therefore, in the solid-state imaging device using the photoelectric conversion element 10 as each of the pixels, the upper electrode 18 may be a common electrode. In this case, a transmission path configured of the contact hole H, the contact metal layer 20, the wiring layers 15b and 13b, the conductive plugs 120b1 and 120b2 mentioned above may be provided at least at one position for all pixels.

In the semiconductor substrate 11, for example, the inorganic photoelectric converters 11B and 11R and the green electric storage layer 110G may be embedded in a predetermined region of the n-type silicon (Si) layer 110. Moreover, the conductive plugs 120a1 and 120b1 configuring a transmission path of electric charges (electrons or holes) from the organic photoelectric converter 11G may be embedded in the semiconductor substrate 11. In various embodiments, a back surface (the surface S1) of the semiconductor substrate 11 may serve as a light-reception surface. A plurality of pixel transistors (including transfer transistors Tr1 to Tr3) corresponding to the organic photoelectric converter 11G and the inorganic photoelectric converters 11B and 11R may be provided on the surface (the surface S2) side of the semiconductor substrate 11, and a peripheral circuit including a logic circuit, etc. may be provided on the surface (the surface S2) side of the semiconductor substrate 11.

Non-limiting examples of the pixel transistor may include a transfer transistor, a reset transistor, an amplification transistor, and a selection transistor. Each of these pixel transistors may be configured of, for example, a MOS transistor, and may be provided in a p-type semiconductor well region on the surface S2 side. A circuit including such pixel transistors may be provided for each of photoelectric converters of red, green, and blue. Each of the circuits may have, for example, a three-transistor configuration including three transistors in total, e.g., the transfer transistor, the reset transistor, and the amplification transistor out of these pixel transistors, or may have, for example, a four-transistor configuration further including the selection transistor in addition to the three transistors mentioned above. Only the transfer transistors Tr1 to Tr3 of these pixel transistors are illustrated and described hereinbelow. Moreover, it may be possible to share the pixel transistors other than the transfer transistor among the photoelectric converters or among the pixels. Further, a pixel sharing configuration in which a floating diffusion is shared may be applicable.

The transfer transistors Tr1 to Tr3 may include gate electrodes (gate electrodes TG1 to TG3) and floating diffusions (FD 113, 114, and 116). The transfer transistor Tr1 may transfer, to a vertical signal line Lsig to be described later, signal electric charges (electrons in various embodiments) corresponding to green that are generated in the organic photoelectric converter 11G and stored in the green electric storage layer 110G. The transfer transistor Tr2 may transfer, to the vertical signal line Lsig to be described later, signal electric charges (electrons in various embodiments) corresponding to blue that are generated and stored in the inorganic photoelectric converter 11B. Likewise, the transfer transistor Tr3 may transfer, to the vertical signal line Lsig to be described later, signal electric charges (electrons in various embodiments) corresponding to red that are generated and stored in the inorganic photoelectric converter 11R.

The inorganic photoelectric converters 11B and 11R may be photodiodes having a p-n junction, and may be provided in an optical path in the semiconductor substrate 11 in this order from the surface S1. The inorganic photoelectric converter 11B of the inorganic photoelectric converters 11B and 11R may selectively detect blue light and store signal electric charges corresponding to blue, and may be provided so as to extend, for example, from a selective region along the surface S1 of the semiconductor substrate 11 to a region in proximity to an interface with the multilayer wiring layer 51. The inorganic photoelectric converter 11R may selectively detect red light and store signal electric charges corresponding to red, and may be provided, for example, in a region below the inorganic photoelectric converter 11B (closer to the surface S2). It is to be noted that blue (B) and red (R) may be, for example, a color corresponding to a wavelength region from 450 nm to 495 nm both inclusive and a color corresponding to a wavelength region from 620 nm to 750 nm both inclusive, respectively, and each of the inorganic photoelectric converters 11B and 11R may detect light of part or the entirety of the relevant wavelength region.

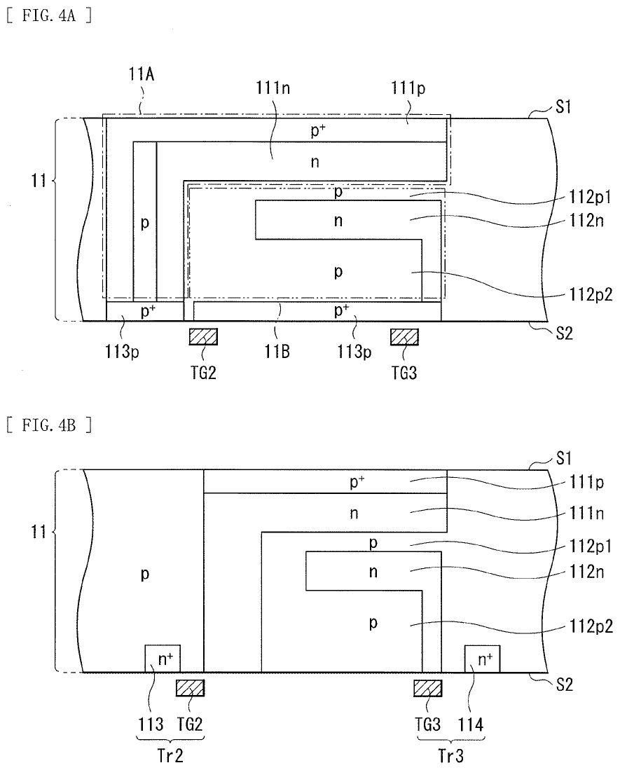

FIG. 4A illustrates specific configuration examples of the inorganic photoelectric converters 11B and 11R. FIG. 4B corresponds to a configuration in other cross-section of FIG. 4A. It is to be noted that in various embodiments, description is given of a case where electrons of electron-hole pairs generated by photoelectric conversion are read as signal electric charges (in a case where an n-type semiconductor region serves as a photoelectric conversion layer). Moreover, in the drawings, a superscript “+(plus)” placed at “p” or “n” indicates that p-type or n-type impurity concentration is high. Further, gate electrodes TG2 and TG3 of the transfer transistors Tr2 and Tr3 out of the pixel transistors are also illustrated.

The inorganic photoelectric converter 11B may include, for example, a p-type semiconductor region (hereinafter simply referred to as p-type region, an n-type semiconductor region is referred in a similar manner) 111p serving as a hole storage layer and an n-type photoelectric conversion layer (an n-type region) 111n serving as an electron storage layer. The p-type region 111p and the n-type photoelectric conversion layer 111n may be provided in respective selective regions in proximity to the surface S1, and may be bent and extend to allow a portion thereof to reach an interface with the surface S2. The p-type region 111p may be coupled to an unillustrated p-type semiconductor well region on the surface S1 side. The n-type photoelectric conversion layer 111n may be coupled to the FD 113 (an n-type region) of the transfer transistor Tr2 for blue. It is to be noted that a p-type region 113p (a hole storage layer) may be provided in proximity to an interface between each of ends on the surface S2 side of the p-type region 111p and the n-type photoelectric conversion layer 111n and the surface S2.

The inorganic photoelectric converter 11R may be configured of, for example, p-type regions 112p1 and 112p2 (hole storage layers), and an n-type photoelectric conversion layer 112n (an electron storage layer) sandwiched between the p-type regions 112p1 and 112p2 (that is, may have a p-n-p laminated structure). The n-type photoelectric conversion layer 112n may be bent and extend to allow a portion thereof to reach an interface with the surface S2. The n-type photoelectric conversion layer 112n may be coupled to the FD 114 (an n-type region) of the transfer transistor Tr3 for red. It is to be noted that a p-type region 113p (a hole storage layer) may be provided at least in proximity to an interface between the end on the surface S2 side of the n-type photoelectric conversion layer 111n and the surface S2.

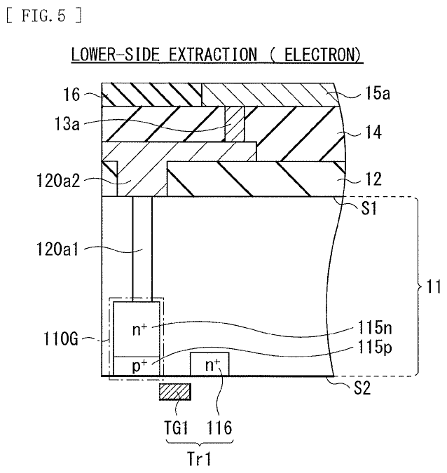

FIG. 5 illustrates a specific configuration example of the green storage layer 110G. It is to be noted that hereinafter, description is given of a case where electrons of electrons-hole pairs generated by the organic photoelectric converter 11G are read as signal electric charges from the lower electrode 15a. Moreover, the gate electrode TG1 of the transfer transistor Tr1 out of the pixel transistors is also illustrated in FIG. 5.

The green storage layer 110G may include an n-type region 115n serving as an electron storage layer. A portion of the n-type region 115n may be coupled to the conductive plug 120a1, and may store electrons transmitted from the lower electrode 15a through the conductive plug 120a1. The n-type region 115n may be also coupled to the FD 116 (an n-type region) of the transfer transistor Tr1 for green. It is to be noted that a p-type region 115p (a hole storage layer) may be provided in proximity to an interface between the n-type region 115n and the surface S2.

The conductive plugs 120a1 and 120b2 may function as connectors between the organic photoelectric converter 11G and the semiconductor substrate 11 together with the conductive plugs 120a2 and 120a2 to be described later, and may configure a transmission path of electrons or holes generated in the organic photoelectric converter 11G. In various embodiments, the conductive plug 120a1 may be brought into conduction with, for example, the lower electrode 15a of the organic photoelectric converter 11G, and may be coupled to the green storage layer 110G. The conductive plug 120b1 may be brought into conduction with the upper electrode 18 of the organic photoelectric converter 11G, and may serve as a wiring line for discharge of holes.

Each of the conductive plugs 120a1 and 120b1 may be configured of, for example, a conductive semiconductor layer, and may be embedded in the semiconductor substrate 11. In this case, the conductive plug 120a1 may be of an n type (to serve as an electron transmission path), and the conductive plug 120b1 may be of a p type (to serve as a hole transmission path). Alternatively, each of the conductive plugs 120a1 and 120b1 may be configured of, for example, a conductive film material such as tungsten (W) contained in a through via. In this case, for example, to suppress a short circuit with silicon (S1), it is possible to cover a via side surface with an insulating film of, for example, silicon oxide (Sift) or silicon nitride (SiN).

The multilayer wiring layer 51 may be provided on the surface S2 of the semiconductor substrate 11. In the multilayer wiring layer 51, a plurality of wiring lines 51a may be provided with an interlayer insulating film 52 in between. As described above, in the photoelectric conversion element 10, the multilayer wiring layer 51 is provided on side opposite to the light-reception surface, which makes it possible to achieve a socalled back-side illumination type solid-state imaging device. For example, a supporting substrate 53 made of silicon (S1) may be bonded to the multilayer wiring layer 51.

(1-2. Method of Manufacturing a Photoelectric Conversion Element)

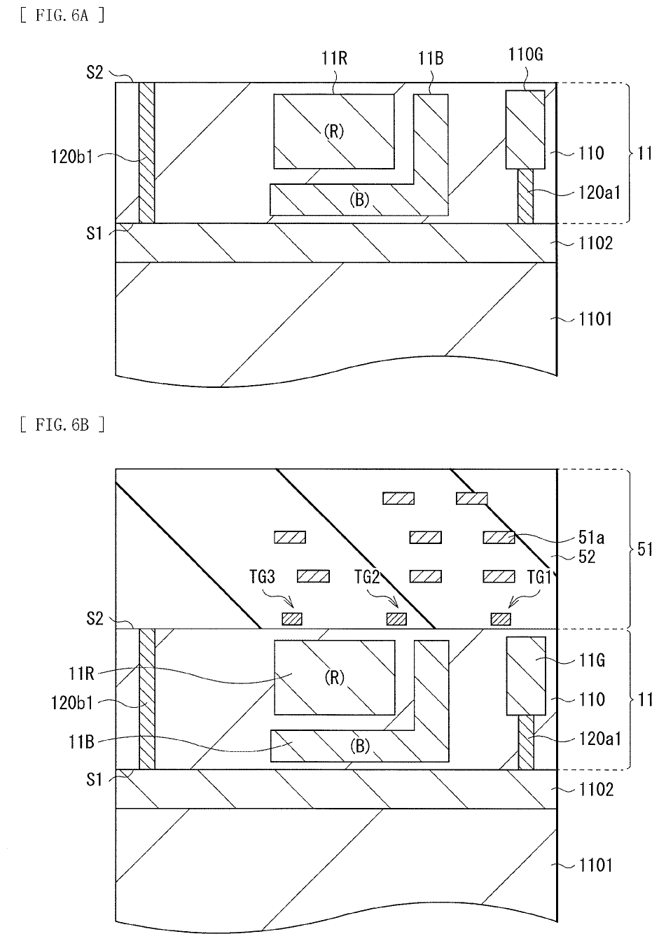

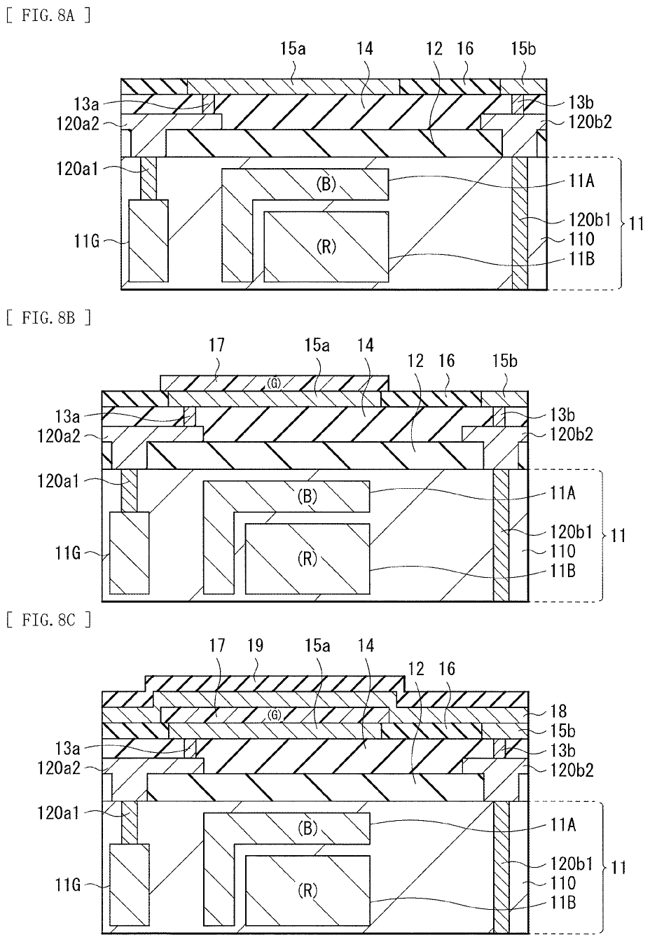

The photoelectric conversion element 10 may be manufactured as follows, for example. FIGS. 6A to 8C illustrate a method of manufacturing the photoelectric conversion element 10 in process order. It is to be noted that FIGS. 8A to 8C illustrate only a main-part configuration of the photoelectric conversion element 10.

First, the semiconductor substrate 11 may be formed. More specifically, a silicon on insulator (SOI) substrate may be prepared. In the SOI substrate, the silicon layer 110 is provided on a silicon base 1101 with a silicon oxide film 1102 in between. It is to be noted that a surface on side on which the silicon oxide film 1102 is located, of the silicon layer 110 may serve as the back surface (the surface S1) of the semiconductor substrate 11. FIGS. 6A and 6B illustrate a state in which a configuration illustrated in FIG. 1 is vertically inverted. Next, the conductive plugs 120a1 and 120b1 may be formed in the silicon layer 110, as illustrated in FIG. 6A. At this occasion, a through bias may be formed in the silicon layer 110, and thereafter, a barrier metal such as silicon nitride described above and tungsten may be contained in the through vias, which makes it possible to form the conductive plugs 120a1 and 120b1. Alternatively, a conductive extrinsic semiconductor layer may be formed by, for example, ion implantation on the silicon layer 110. In this case, the conductive plug 120a1 may be formed as an n-type semiconductor layer, and the conductive plug 120b1 may be formed as a p-type semiconductor layer. Thereafter, the inorganic photoelectric converters 11B and 11R each having, for example, the p-type region and the n-type region as illustrated in FIG. 4A may be formed by ion implantation in regions located at depths different from each other in the silicon layer 110 (to be superimposed on each other). Moreover, in a region adjacent to the conductive plug 120a1, the green storage layer 110G may be formed by ion implantation. Thus, the semiconductor substrate 11 is formed.

Subsequently, the pixel transistors including the transfer transistors Tr1 to Tr3 and peripheral circuits such as a logic circuit may be formed on the surface S2 side of the semiconductor substrate 11, and thereafter, a plurality of layers of wiring lines 51a may be formed on the surface S2 of the semiconductor substrate 11 with the interlayer insulating film 52 in between to form the multilayer wiring layer 51. Next, the supporting substrate 53 made of silicon may be bonded onto the multilayer wiring layer 51, and thereafter, the silicon base 1101 and the silicon oxide film 1102 may be removed from the surface S1 of the semiconductor substrate 11 to expose the surface S1 of the semiconductor substrate 11.

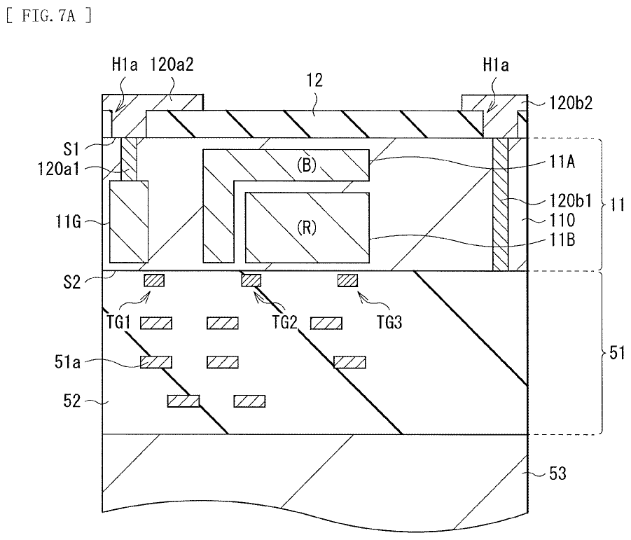

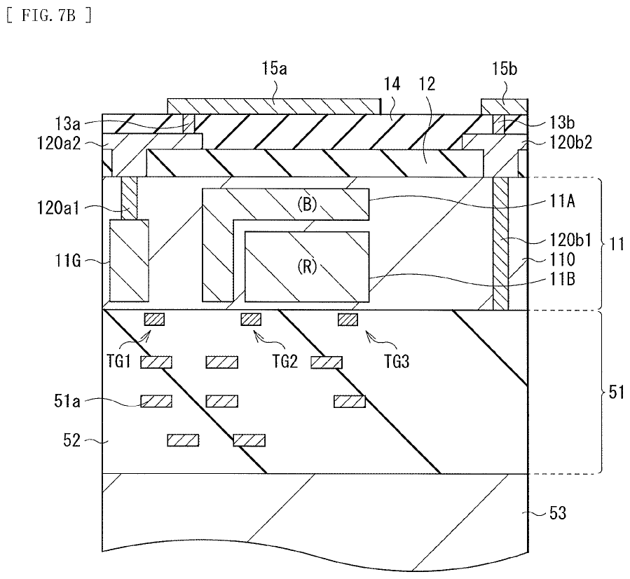

Next, the organic photoelectric converter 11G may be formed on the surface S1 of the semiconductor substrate 11. More specifically, first, as illustrated in FIG. 7A, the interlayer insulating film 12 configured of the foregoing laminated film of the hafnium oxide film and the silicon oxide film may be formed on the surface S1 of the semiconductor substrate 11. For example, after the hafnium oxide film may be formed by an ALD (atomic layer deposition) method, the silicon oxide film may be formed by, for example, a plasma CVD (Chemical Vapor Deposition) method. Thereafter, the contact holes H1a and H1b may be formed at positions facing the conductive plugs 120a1 and 120b1 of the interlayer insulating film 12, and the conductive plugs 120a2 and 120b2 made of the foregoing material may be formed so as to be contained in the contact holes H1a and H1b, respectively. At this occasion, the conductive plugs 120a2 and 120b2 may be formed to protrude to a region to be light-blocked (to cover the region to be light-blocked). Alternatively, a light-blocking layer may be separately formed in a region isolated from the conductive plugs 120a2 and 120b2.

Subsequently, the interlayer insulating film 14 made of the foregoing material may be formed by, for example, a plasma CVD method, as illustrated in FIG. 7B. It is to be noted that after film formation, a front surface of the interlayer insulating film 14 may be planarized by, for example, a CMP (Chemical Mechanical Polishing) method. Next, contact holes may be formed at positions facing the conductive plugs 120a2 and 120b2 of the interlayer insulating film 14, and the contact holes may be filled with the foregoing material to form the wiring layers 13a and 13b. It is to be noted that, thereafter, a surplus wiring layer material (such as tungsten) on the interlayer insulating film 14 may be removed by, for example, a CMP method. Next, the lower electrode 15a may be formed on the interlayer insulating film 14. More specifically, first, the foregoing transparent conductive film may be formed on the entire surface of the interlayer insulating film 14 by, for example, a sputtering method. Thereafter, a selective portion may be removed with use of a photolithography method (through performing light exposure, development, post-baking, etc. on a photoresist film), for example, with use of dry etching or wet etching to form the lower electrode 15a. At this occasion, the lower electrode 15a may be formed in a region facing the wiring layer 13a. Moreover, in processing of the transparent conductive film, the transparent conductive film may remain also in a region facing the wiring layer 13b to form the wiring layer 15b configuring a portion of a hole transmission path together with the lower electrode 15a.

Subsequently, the insulating film 16 may be formed. At this occasion, first, the insulating film 16 made of the foregoing material may be formed by, for example, a plasma CVD method on the entire surface of the semiconductor substrate 11 to cover the interlayer insulating film 14, the lower electrode 15a, and the wiring layer 15b. Thereafter, the formed insulating film 16 may be polished by, for example, a CMP method to expose the lower electrode 15a and the wiring layer 15b from the insulating film 16 and to reduce (or eliminate) a difference in level between the lower electrode 15a and the insulating film 16, as illustrated in FIG. 8A.

Next, the organic photoelectric conversion layer 17 may be formed on the lower electrode 15a, as illustrated in FIG. 8B. At this occasion, pattern formation of three kinds of organic semiconductor materials including the foregoing materials may be performed by, for example, a vacuum deposition method. It is to be noted that in a case where another organic layer (such as an electron blocking layer) is formed above or below the organic photoelectric conversion layer 17 as described above, the organic layer may be formed continuously in a vacuum process (in-situ vacuum process). Moreover, the method of forming the organic photoelectric conversion layer 17 is not limited to a technique using the foregoing vacuum deposition method, and any other technique, for example, a print technology may be used.

Subsequently, the upper electrode 18 and the protective layer 19 may be formed, as illustrated in FIG. 8C. First, the upper electrode 18 configured of the foregoing transparent conductive film may be formed on an entire surface of the semiconductor substrate 11 by, for example, a vacuum deposition method or a sputtering method to cover a top surface and a side surface of the organic photoelectric conversion layer 17. It is to be noted that characteristics of the organic photoelectric conversion layer 17 easily vary by an influence of water, oxygen, hydrogen, etc.; therefore, the upper electrode 18 may be formed by an in-situ vacuum process together with the organic photoelectric conversion layer 17. Thereafter (before pattering the upper electrode 18), the protective layer 19 made of the foregoing material may be formed by, for example, a plasma CVD method to cover a top surface of the upper electrode 18. Subsequently, after the protective layer 19 is formed on the upper electrode 18, the upper electrode 18 may be processed.

Thereafter, selective portions of the upper electrode 18 and the protective layer 19 may be collectively removed by etching using a photolithography method. Subsequently, the contact hole H may be formed in the protective layer 19 by, for example, etching using a photolithography method. At this occasion, the contact hole H may be formed in a region not facing the organic photoelectric conversion layer 17. Even after formation of the contact hole H, a photoresist may be removed, and cleaning using a chemical solution may be performed by a method similar to the foregoing method; therefore, the upper electrode 18 may be exposed from the protective layer 19 in a region facing the contact hole H. Accordingly, in view of generation of a pin hole, the contact hole H may be provided in a region other than a region where the organic photoelectric conversion layer 17 is formed. Subsequently, the contact metal layer 20 made of the foregoing material may be formed with use of, for example, a sputtering method. At this occasion, the contact metal layer 20 may be formed on the protective layer 19 to be contained in the contact hole H and extend to a top surface of the wiring layer 15b. Lastly, the planarization layer 21 may be formed on the entire surface of the semiconductor substrate 11, and thereafter, the on-chip lens 22 may be formed on the planarization layer 21. Thus, the photoelectric conversion element 10 illustrated in FIG. 1 is completed.

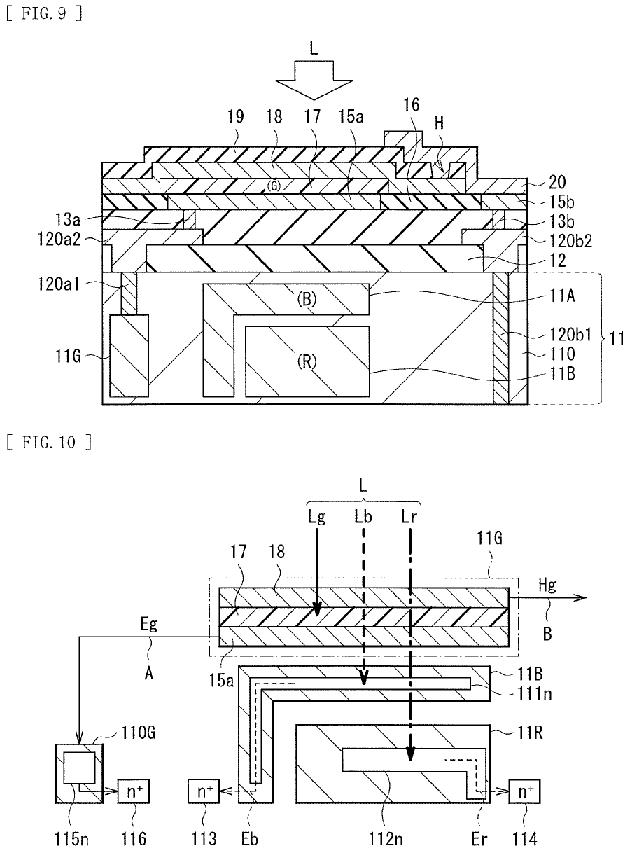

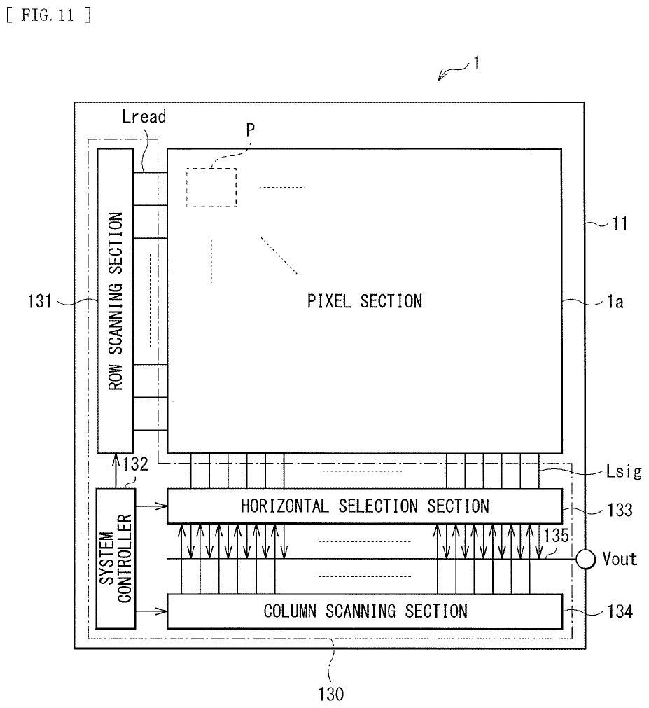

In the foregoing photoelectric conversion element 10, for example, as the unit pixel P of the solid-state imaging device 1, signal electric charges may be obtained as follows. As illustrated in FIG. 9, light L may enter the photoelectric conversion element 10 through the on-chip lens 22 (not illustrated in FIG. 9), and thereafter, the light L may pass through the organic photoelectric converter 11G and the inorganic photoelectric converters 11B and 11R in this order. Each of green light, blue light, and red light of the light L may be subjected to photoelectric conversion in the course of passing. FIG. 10 schematically illustrates a flow of obtaining signal electric charges (electrons) on the basis of incident light. Hereinafter, description is given of a specific signal obtaining operation in each photoelectric converter.

(Obtaining of Green Signal by Organic Photoelectric Converter 11G)

First, green light Lg of the light L having entered the photoelectric conversion element 10 may be selectively detected (absorbed) by the organic photoelectric converter 11G to be subjected to photoelectric conversion. Electrons Eg of thusgenerated electron-hole pairs may be extracted from the lower electrode 15a, and thereafter, the electrons Eg may be stored in the green electric storage layer 110G through a transmission path A (the wiring layer 13a and the conductive plugs 120a1 and 120a2). The stored electrons Eg may be transferred to the FD 116 in a reading operation. It is to be noted that holes Hg may be discharged from the upper electrode 18 through a transmission path B (the contact metal layer 20, the wiring layers 13b and 15b, and the conductive plugs 120b1 and 120b2).

More specifically, the signal electric charges may be stored as follows. In various embodiments, a predetermined negative potential VL (<0 V) and a potential VU (<VL) lower than the potential VL may be applied to the lower electrode 15a and the upper electrode 19, respectively. It is to be noted that the potential VL may be applied to the lower electrode 15a from, for example, the wiring line 51a in the multilayer wiring layer 51 through the transmission path A. The potential VL may be applied to the upper electrode 18 from, for example, the wiring line 51a in the multilayer wiring layer 51 through the transmission path B. Thus, in an electric charge storing state (an OFF state of the unillustrated reset transistor and the transfer transistor Tr1), electrons of the electron-hole pairs generated in the organic photoelectric conversion layer 17 may be guided to the lower electrode 15a having a relatively high potential (holes may be guided to the upper electrode 18). Thus, the electrons Eg may be extracted from the lower electrode 15a to be stored in the green electric storage layer 110G (more specifically, the n-type region 115n) through the transmission path A. Moreover, storage of the electrons Eg may change the potential VL of the lower electrode 15a brought into conduction with the green storage layer 110G. A change amount of the potential VL may correspond to a signal potential (herein, a potential of a green signal).

In a reading operation, the transfer transistor Tr1 may be turned to an ON state, and the electrons Eg stored in the green electric storage layer 110G may be transferred to the FD 116. Accordingly, a green signal based on a light reception amount of the green light Lg may be read to the vertical signal line Lsig to be described later through an unillustrated other pixel transistor. Thereafter, the unillustrated reset transistor the transfer transistor Tr1 may be turned to an ON state, and the FD 116 as the n-type region and a storage region (the n-type region 115n) of the green electric storage layer 110G may be reset to, for example, a power source voltage VDD.

(Obtaining of Blue Signal and Red Signal by Inorganic Photoelectric Converters 11B and 11R)

Next, blue light and red light of light having passed through the organic photoelectric converter 11G may be absorbed in order by the inorganic photoelectric converter 11B and the inorganic photoelectric converter 11R, respectively, to be subjected to photoelectric conversion. In the inorganic photoelectric converter 11B, electrons Eb corresponding to the blue light having entered the inorganic photoelectric converter 11B may be stored in the n-type region (the n-type photoelectric conversion layer 111n), and the stored electrons Eb may be transferred to the FD 113 in the reading operation. It is to be noted that holes may be stored in an unillustrated p-type region. Likewise, in the inorganic photoelectric converter 11R, electrons Er corresponding to the red light having entered the inorganic photoelectric converter 11R may be stored in the n-type region (the n-type photoelectric conversion layer 112n), and the stored electrons Er may be transferred to the FD 114 in the reading operation. It is to be noted that holes may be stored in an unillustrated p-type region.

In the electric charge storing state, the negative potential VL may be applied to the lower electrode 15a of the organic photoelectric converter 11G, as described above, which tends to increase a hole concentration in the p-type region (the p-type region 111p in FIG. 3) as a hole storage layer of the inorganic photoelectric converter 11B. This makes it possible to suppress generation of a dark current at an interface between the p-type region 111p and the interlayer insulating film 12.

In the reading operation, as with the foregoing organic photoelectric converter 11G, the transfer transistors Tr2 and Tr3 may be turned to an ON state, and the electrons Eb stored in the n-type photoelectric conversion layer 111n and the electrons Er stored in the n-type photoelectric conversion layer 112n may be transferred to the FDs 113 and 114, respectively. Accordingly, a blue signal based on a light reception amount of the blue light Lb and a red signal based on a light reception amount of the red light Lr may be read to the vertical signal line Lsig to be described later through an unillustrated other pixel transistor. Thereafter, the unillustrated reset transistor and the transfer transistors Tr2 and Tr3 may be turned to the ON state, and the FDs 113 and 114 as the n-type regions may be reset to, for example, the power source voltage VDD.

As described above, the organic photoelectric converter 11G and the inorganic photoelectric converters 11B and 11R are stacked along the vertical direction, which makes it possible to separately detect red light, green light, and blue light without providing a color filter, thereby obtaining signal electric charges of respective colors. This makes it possible to suppress light loss (a decline in sensitivity) resulting from color light absorption by the color filter and generation of false color associated with pixel interpolation processing.

(1-3. Workings and Effects)

As described above, in recent years, in solid-state imaging devices such as CCD image sensors and CMOS image sensors, high color reproducibility, a high frame rate, and high sensitivity have been in demand. In order to achieve high color reproducibility, the high frame rate, and high sensitivity, a favorable spectroscopic shape, high responsivity, and high external quantum efficiency (EQE) are in demand. In a solid-state imaging device in which a photoelectric converter made of an organic material (an organic photoelectric converter) and a photoelectric converter made of an inorganic material such as S1 (an inorganic photoelectric converter) are stacked, the organic photoelectric converter extracts a signal of one color, and the inorganic photoelectric converter extracts signals of two colors, a bulk-hetero structure is used for the organic photoelectric converter. The bulk-hetero structure makes it possible to increase an electric charge separation interface by co-evaporation of the p-type organic semiconductor material and the n-type organic semiconductor material, thereby improving conversion efficiency. Hence, in a typical solid-state imaging device, improvements in the spectroscopic shape, responsivity and EQE of the organic photoelectric converter are achieved with use of two kinds of materials. An organic photoelectric converter made of two kinds of materials (binary system), for example, fullerenes and quinacridones or subphthalocyanines, or quinacridones and subphthalocyanines may be used.

However, in general, a material having a sharp spectroscopic shape in a solid-state film tends not to have a high electric charge transporting property. In order to develop a high electric charge transporting property with use of a molecular material, it may be necessary for respective orbitals configured of molecules to have an overlap in a solid state. In a case where interaction between the orbitals is developed, a shape of an absorption spectrum in the solid state is broadened. For example, diindenoperylenes have high hole mobility of about 10⁻² cm²/Vs maximum in a solid-state film thereof. For example, a solid-state film of diindenoperylenes formed at a substrate temperature rising to 90° C. has high hole mobility, which results from change in crystallinity and orientation of diindenoperylenes. In a case where the solid-state film is formed at a substrate temperature of 90° C., a solid-state film that allows a current to easily flow toward a direction where π-stacking as one kind of intermolecular interaction is formed is formed. Thus, the material having strong interaction between molecules in a solid-state film easily develops higher electric charge mobility.

In contrast, it is known that diindenoperylenes have a sharp absorption spectrum in a case where diindenoperylenes are dissolved in an organic solvent such as dichloromethane, but exhibits a broad absorption spectrum in the solid-state film thereof. It is understood that in a solution, diindenoperylenes are diluted by dichloromethane, and are therefore in a single molecule state, whereas intermolecular interaction is developed in the solid-state film. It can be seen that it is difficult to form a solid-state film having a sharp spectroscopic shape and high electric charge transporting property in principle.

Moreover, in the organic photoelectric converter having a binary bulk-hetero structure, electric charges (holes and electrons) generated at a P/N interface in the solid-state film are transported. The holes are transported by the p-type organic semiconductor material, and the electrons are transported by the n-type organic semiconductor material. Accordingly, in order to achieve high responsivity, it may be necessary for both the p-type organic semiconductor material and the n-type organic semiconductor material to have a high electric charge transporting property. Hence, in order to achieve both a favorable spectroscopic shape and high responsivity, it may be necessary for one of the p-type organic semiconductor material and the n-type organic semiconductor material to have both sharp spectroscopic characteristics and high electric charge mobility. However, it is difficult to prepare a material having a sharp spectroscopic shape and a high electric charge transporting property due to the foregoing reason, and it is difficult to achieve a favorable spectroscopic shape, high responsivity, and high EQE with use of two kinds of materials.

In contrast, the organic photoelectric conversion layer is formed with use of three kinds of organic semiconductor materials (ternary system) having mother skeletons different from one another, which makes it possible to achieve a sharp spectroscopic shape, high responsivity, and high EQE. This makes it possible to entrust, to another material, one of the sharp spectroscopic shape and high electric charge mobility, which are expected of one or both of the p-type semiconductor and the n-type semiconductor in the binary system, thereby achieving the favorable spectroscopic shape, high responsivity, and high EQE. In the organic photoelectric conversion layer made of the three kinds of organic semiconductor materials, excitons generated through absorption of light by a light-absorption material (for example, the second organic semiconductor material in the present embodiment) are separated at an interface between two organic semiconductor materials selected from the three kinds of organic semiconductor materials.

In the foregoing ternary-system photoelectric conversion element and a solid-state imaging device including the ternary-system photoelectric conversion element as an imaging element, in order to obtain a finer image, it may be desirable to suppress generation of a dark current. It is to be noted that even in the binary-system photoelectric conversion element, it may be desirable to suppress generation of a dark current.

In contrast, in the photoelectric conversion element according to various embodiments, the organic photoelectric conversion layer 17 is formed with use of the first organic semiconductor material, the second organic semiconductor material, and the third organic semiconductor material that have mother skeletons different from one another. In this case, the first organic semiconductor material is one of fullerene and fullerene derivatives. The third organic semiconductor material has a HOMO level that is shallower than the HOMO level of the first organic semiconductor material and the HOMO level of the second organic semiconductor material and allows a difference in HOMO level between the third organic semiconductor material and the first organic semiconductor material to be less than 0.9 eV. This makes it possible to suppress generation of a dark current between the first organic semiconductor material and the third organic semiconductor material and between the second organic semiconductor material and the third organic semiconductor material in the organic photoelectric conversion layer 17.

As described above, in various embodiments, the organic photoelectric conversion layer 17 is formed with use of three kinds of organic semiconductor materials, e.g., the first organic semiconductor material, the second organic semiconductor material, and the third organic semiconductor material mentioned above, and one of fullerene and fullerene derivatives is used as the first organic semiconductor material. The third organic semiconductor material used herein is an organic semiconductor material having a HOMO level that is shallower than the HOMO level of the first organic semiconductor material and the HOMO level of the second organic semiconductor material and allows a difference in HOMO level between the third organic semiconductor material and the first organic semiconductor material to be less than 0.9 eV. This makes it possible to suppress generation of a dark current between the first organic semiconductor material and the third organic semiconductor material and between the second organic semiconductor material and the third organic semiconductor material in the organic photoelectric conversion layer 17, thereby improving dark-current characteristics.

### 2. Application Examples

### Application Example 1

FIG. 11 illustrates an entire configuration of a solid-state imaging device (the solid-state imaging device 1) using the photoelectric conversion element 10 described in the foregoing embodiment as the unit pixel P. The solid-state imaging device 1 may be a CMOS image sensor, and may include a pixel section 1a as an imaging region and a peripheral circuit section 130 in a peripheral region of the pixel section 1a on the semiconductor substrate 11. The peripheral circuit section 130 may include, for example, a row scanning section 131, a horizontal selection section 133, a column scanning section 134, and a system controller 132.

The pixel section 1a may include, for example, a plurality of unit pixels P (each corresponding to the photoelectric conversion element 10) that are two-dimensionally arranged in rows and columns. The unit pixels P may be wired with pixel driving lines Lread (specifically, row selection lines and reset control lines) for respective pixel rows, and may be wired with vertical signal lines Lsig for respective pixel columns. The pixel driving lines Lread may transmit drive signals for signal reading from the pixels. The pixel driving lines Lread may have one end coupled to a corresponding one of output terminals, corresponding to the respective rows, of the row scanning section 131.

The row scanning section 131 may include, for example, a shift register and an address decoder, and may be, for example, a pixel driver that drives the unit pixels P of the pixel section 1a on a row basis. Signals may be outputted from the unit pixels P of a pixel row selected and scanned by the row scanning section 131, and the signals thus outputted may be supplied to the horizontal selection section 133 through the respective vertical signal lines Lsig. The horizontal selection section 133 may include, for example, an amplifier and horizontal selection switches that are provided for each of the vertical signal lines Lsig.

The column scanning section 134 may include, for example, a shift register and an address decoder, and may drive the horizontal selection switches of the horizontal selection section 133 in order while sequentially performing scanning of those horizontal selection switches. Such selection and scanning performed by the column scanning section 134 may allow the signals of the pixels P transmitted through the respective vertical signal lines Lsig to be sequentially outputted to a horizontal signal line 135. The thus-outputted signals may be transmitted to outside of the semiconductor substrate 11 through the horizontal signal line 135.

A circuit portion configured of the row scanning section 131, the horizontal selection section 133, the column scanning section 134, and the horizontal signal line 135 may be provided directly on the semiconductor substrate 11, or may be disposed in an external control IC. Alternatively, the circuit portion may be provided in any other substrate coupled by means of a cable or any other coupler.

The system controller 132 may receive, for example, a clock supplied from the outside of the semiconductor substrate 11, data on instructions of operation modes, and may output data such as internal information of the solid-state imaging device 1. Furthermore, the system controller 132 may include a timing generator that generates various timing signals, and may perform drive control of peripheral circuits such as the row scanning section 131, the horizontal selection section 133, and the column scanning section 134 on a basis of the various timing signals generated by the timing generator.

### Application Example 2

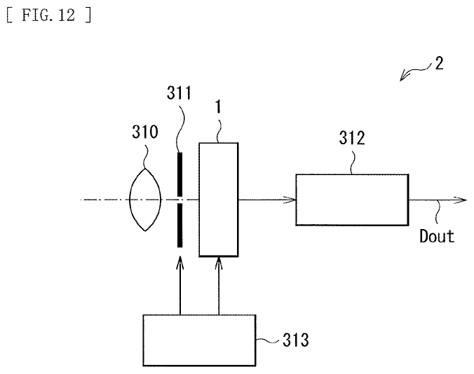

The foregoing solid-state imaging device 1 is applicable to various kinds of electronic apparatuses having imaging functions. Non-limiting examples of the electronic apparatuses may include camera systems such as digital still cameras and video cameras, and mobile phones having imaging functions. FIG. 12 illustrates, for purpose of an example, a schematic configuration of an electronic apparatus 2 (e.g., a camera). The electronic apparatus 2 may be, for example, a video camera that allows for shooting of a still image, a moving image, or both. The electronic apparatus 2 may include the solid-state imaging device 1, an optical system (e.g., an optical lens) 310, a shutter unit 311, a driver 313, and a signal processor 312. The driver 313 may drive the solid-state imaging device 1 and the shutter unit 311.

The optical system 310 may guide image light (e.g., incident light) from an object toward the pixel section 1a of the solid-state imaging device 1. The optical system 310 may include a plurality of optical lenses. The shutter unit 311 may control a period in which the solid-state imaging device 1 is irradiated with the light and a period in which the light is blocked. The driver 313 may control a transfer operation of the solid-state imaging device 1 and a shutter operation of the shutter unit 311. The signal processor 312 may perform various signal processes on signals outputted from the solid-state imaging device 1. A picture signal Dout having been subjected to the signal processes may be stored in a storage medium such as a memory, or may be outputted to a unit such as a monitor.

The foregoing solid-state imaging device 1 is also applicable to the following electronic apparatuses, including a capsule type endoscope 10100 and a mobile body of a vehicle.

### Application Example 3

<Application Example to In-vivo Information Acquisition System>

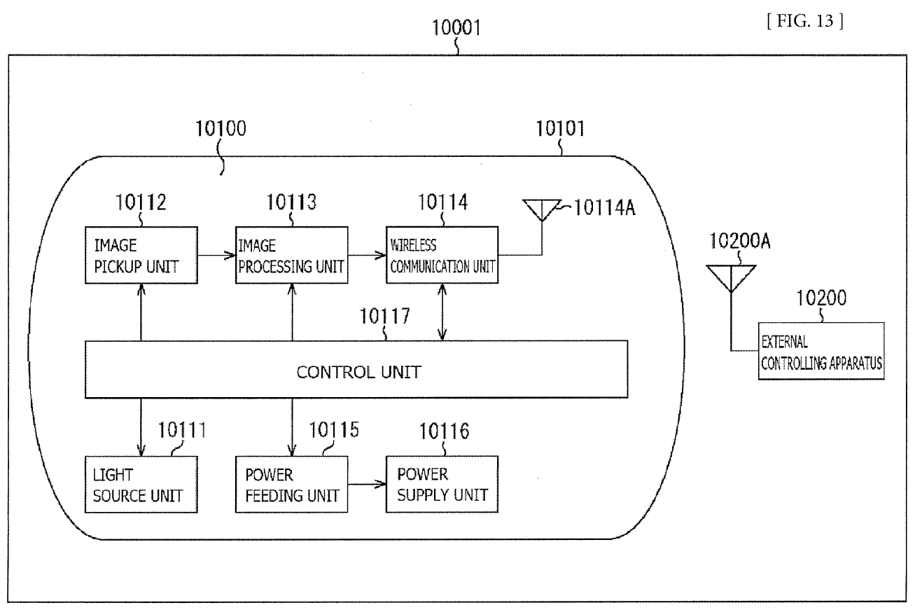

FIG. 13 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image of a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 13, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked-up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

Note that the description has been given above of one example of the in-vivo information acquisition system, to which the technology according to the embodiment of the present disclosure can be applied. The technology according to the embodiment of the present disclosure is applicable to, for example, the image pickup unit 10112 of the configurations described above. This makes it possible to acquire a fine operative image, thereby improving accuracy of an inspection.

### Application Example 4

<Application Example to Mobile Body>

The technology according to any of the foregoing embodiment, modification examples, and the application examples of the present disclosure is applicable to various products. For example, the technology according to any of the foregoing embodiment, the modification examples, and the application examples of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, and a robot.

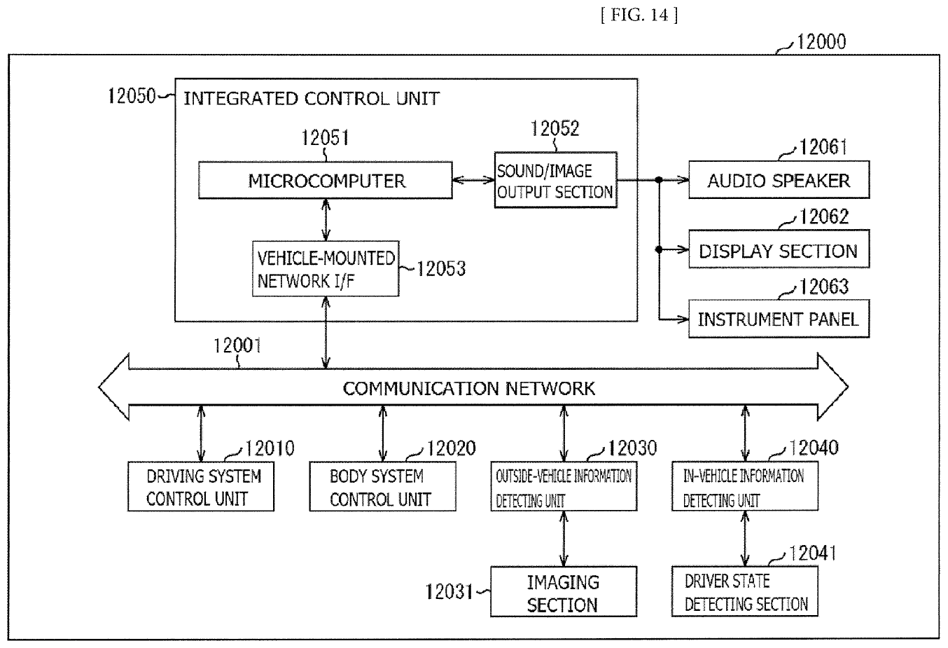

FIG. 14 is a block diagram depicting an example of a schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 14, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received-light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 14, an audio speaker 12061, a display section 12062, and an instrument panel 12063 are illustrated as the output device. The display section 12062 may, for example, include at least one of an on-board display and a head-up (heads-up) display (HUD).

FIG. 15 is a diagram depicting an example of the installation position of the imaging section 12031.

In FIG. 15, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 15 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

### 3. Examples

Next, examples of the present disclosure are described in detail below. In an experiment 1, calculation of the energy levels of the first organic semiconductor material, the second organic semiconductor material, and the third organic semiconductor material and evaluation of spectroscopic characteristics of the first organic semiconductor material, the second organic semiconductor material, and the third organic semiconductor material were performed. In an experiment 2, the photoelectric conversion element of the present disclosure was fabricated, and electrical characteristics of the photoelectric conversion element were evaluated. In an experiment 3, diffraction peak positions, crystal particle diameters, and crystallinity of the first organic semiconductor material, the second organic semiconductor material, and the third organic semiconductor material in the organic photoelectric conversion layer of the present disclosure were evaluated by an X-ray diffraction method.

### Experiment 1: Calculation of Energy Level and Evaluation of Spectroscopic Characteristics

First, samples of the first organic semiconductor material, the second organic semiconductor material, and the third organic semiconductor material were fabricated with use of the following method, and spectroscopic characteristics of the samples were evaluated.

A glass substrate was cleaned by UV/ozone treatment. Fullerene C60 (the formula (1-1)) was evaporated on the glass substrate by a resistance heating method in a vacuum of 1×10⁻⁵ Pa or less with use of an organic evaporation apparatus while rotating a substrate holder. Evaporation speed was 0.1 nm/sec, and the evaporated fullerene C60 was a sample used for evaluation of spectroscopic characteristics. In addition, in place of using fullerene C60 (the formula (1-1)), samples used for evaluation of spectroscopic characteristic using the organic semiconductor materials represented by the formulas (3-1) to (3-15), the formulas (4-1) to (4-6), the formula (5-1), and the formula (6-1) were fabricated, and spectroscopic characteristics of the respective samples were evaluated. It is to be noted that a thickness of a single-layer film including one of the organic semiconductor materials was 50 nm.

Transmittance and reflectivity for each wavelength in a wavelength region from 300 nm to 800 nm were measured with use of an ultraviolet-visible spectrophotometer to determine absorptivity (%) of light absorbed by each of the single-layer films as the spectroscopic characteristics. A linear absorption coefficient α (cm 1) for each wavelength in each of the single-layer films was evaluated by the Lambert-Beer law using the light absorptivity and the thickness of the single-layer film as parameters. A maximal absorption wavelength in a visible light region, a linear absorption coefficient in the maximal absorption wavelength, that is, a maximal linear absorption coefficient, and an absorption end of a spectrum, that is, a light absorption end were calculated from wavelength dependence of the linear absorption coefficient.

Next, the HOMO levels and the LUMO levels of the first organic semiconductor material, the second organic semiconductor material, and the third organic semiconductor material were calculated.

The HOMO level of each of the organic semiconductor materials was calculated with use of the following method. First, a sample used for HOMO level measurement was fabricated with use of a method similar to the foregoing method of fabricating the sample for evaluation of spectroscopic characteristics. It is to be noted that a thickness of a single-layer film including one of the organic semiconductor materials was 20 nm. Subsequently, ultraviolet light of 21.23 eV was applied to the obtained sample used for HOMO level measurement to obtain a kinetic energy distribution of electrons emitted from a surface of the sample, and an energy width of a spectrum of the kinetic energy distribution was subtracted from an energy value of the applied ultraviolet light to obtain the HOMO level of the organic semiconductor material. The organic semiconductor materials used here were fullerene C60 (the formula (1-1)) as the first organic semiconductor, the subphthalocyanine derivatives represented by the formulas (3-1) to (3-15) as the second organic semiconductor material, and the compounds represented by the formulas (4-1) to (4-6) and the formula (5-1) and quinacridone (QD) represented by the formula (6-1) as the third organic semiconductor material.

The LUMO level of each of the organic semiconductor materials was calculated as a value obtained by adding, to the HOMO level, an energy value of the light absorption end obtained by the evaluation of the spectroscopic characteristics.

TABLE 4

| First Organic | | |
|---|---|---|
| Semiconductor | HOMO Level | LUMO Level |
| Material | (eV) | (eV) |
| Formula (1-1) | −6.33 | −4.50 |

TABLE 5

| | | | Maximal | Maximal Linear |
|---|---|---|---|---|
| Second Organic | HOMO | LUMO | Absorption | Absorption |
| Semiconductor | Level | Level | Wavelength | Coefficient |
| Material | (eV) | (eV) | (nm) | (cm⁻¹) |
| Formula (3-1) | −6.06 | −3.98 | 560 | >200000 |
| Formula (3-2) | −6.21 | −4.13 | 562 | |
| Formula (3-3) | −6.23 | −4.15 | 562 | |
| Formula (3-4) | −6.32 | −4.24 | 563 | |
| Formula (3-5) | −6.32 | −4.24 | 562 | |
| Formula (3-6) | −6.32 | −4.24 | 566 | |
| Formula (3-7) | −6.33 | −4.25 | 565 | |
| Formula (3-8) | −6.38 | −4.30 | 563 | |
| Formula (3-9) | −6.39 | −4.31 | 563 | |
| Formula (3-10) | −6.39 | −4.31 | 563 | |
| Formula (3-11) | −6.43 | −4.35 | 563 | |
| Formula (3-12) | −6.50 | −4.42 | 563 | |
| Formula (3-13) | −6.50 | −4.42 | 562 | |
| Formula (3-14) | −6.58 | −4.50 | 562 | |
| Formula (3-15) | −6.66 | −4.58 | 562 | |

TABLE 6

| Third Organic | | | |
|---|---|---|---|
| Semiconductor | HOMO Level | LUMO Level | Light Absorption |
| Material | (eV) | (eV) | End (nm) |
| Formula (4-1) | −5.20 | −2.61 | 480 |
| Formula (4-2) | −5.34 | −2.71 | 473 |
| Formula (5-1) | −5.51 | −2.87 | 470 |
| Formula (4-3) | −5.64 | −2.91 | 455 |
| Formula (4-4) | −5.78 | −2.79 | 415 |
| Formula (4-5) | −5.83 | −2.91 | 425 |
| Formula (4-6) | −6.11 | −3.34 | 448 |
| Formula (6-1) | −5.58 | −3.55 | 610 |

Table 4 illustrates the HOMO level and the LUMO level of fullerene C60 (the formula (1-1)) used as the first organic semiconductor material. Table 5 provides a summary of the HOMO levels and the LUMO levels of the organic semiconductor materials represented by the formulas (3-1) to (3-15) used as the second organic semiconductor material, and the maximal absorption wavelengths in the visible light region and the maximal linear absorption coefficients of the single-layer films including these organic semiconductor materials. Table 6 provides the HOMO levels and the LUMO levels of the compounds represented by the formulas (4-1) to (4-6) and the formula (5-1) and QD represented by the formula (6-1) used as the third organic semiconductor material, and the light absorption ends of the single-layer films including these organic semiconductor materials.

The subphthalocyanine derivatives represented by the formulas (3-1) to (3-15) are dyes that selectively absorbs green light. These subphthalocyanine derivatives had a maximal absorption wavelength in a region from 500 nm to 600 nm, a higher maximal linear absorption coefficient than 200000 cm 1, and a higher maximal linear absorption coefficient in the visible light region than those of fullerene C60 (the formula (1-1)) and the compounds represented by the formulas (4-1) to (4-6) and the formulas (5-1), etc., as illustrated in Table 5. Accordingly, it was found that using the subphthalocyanine derivatives as the second organic semiconductor material made it possible to fabricate a photoelectric conversion element that selectively absorbs light in a predetermined wavelength region.

Moreover, as can be seen from Table 6, the compounds represented by the formulas (4-1) to (4-6) and the formula (5-1) had a light absorption end in a wavelength region of 480 nm or less without having absorption in a wavelength region of 500 nm or more. In other words, it was found that the compounds represented by the formulas (4-1) to (4-6) and the formula (5-1) had high light transmittance of blue light. Consequently, it was found that using any of the foregoing organic semiconductor materials as the third organic semiconductor material prevented the third organic semiconductor material from interfering with separation of R, G, and B in the photoelectric conversion element of the present disclosure.

### Experiment 2: Evaluation of Electrical Characteristics

Samples used for evaluation of electrical characteristics were fabricated, and external quantum efficiency (EQE), dark-current characteristics, and responsivity of the samples were evaluated.

First, as a sample 1 (an experimental example 1), an organic photoelectric conversion layer was formed by the following method. A glass substrate provided with an ITO electrode having a film thickness of 50 nm was cleaned by UV/ozone treatment, and thereafter, C60 (the formula (1-1)) as the first organic semiconductor material, the subphthalocyanine derivative represented by the formula (3-1) as the second organic semiconductor material, and the compound (BP-rBDT) represented by the formula (4-3) as third organic semiconductor material were evaporated simultaneously on the glass substrate by a resistance heating method in a vacuum of 1×10⁻⁵ Pa or less with use of an organic evaporation apparatus while rotating a substrate holder. The first organic semiconductor material, the second organic semiconductor material, and the third organic semiconductor material were evaporated at evaporation speed of 0.025 nm/sec, 0.050 nm/sec, and 0.050 nm/sec, respectively to form a film having a total thickness of 200 nm. Thus, the organic photoelectric conversion layer having a composition ratio of 20 vol % (the first organic semiconductor material): 40 vol % (the second organic semiconductor material): 40 vol % (the third organic semiconductor material) was obtained. Thereafter, B4PyMPM represented by the following formula (10) was evaporated at evaporation speed of 0.5 angstroms/sec to form a film having a thickness of 5 nm as a hole blocking layer. Subsequently, an AlSiCu film having a thickness of 100 nm was formed as an upper electrode on the hole blocking layer by an evaporation method. Thus, a photoelectric conversion element having a 1 mm-by-1 mm photoelectric conversion region was fabricated.

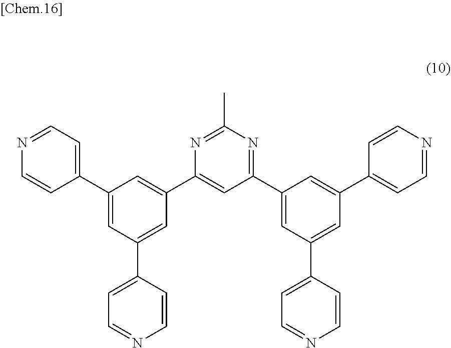 [SMILES: Cc1nc(-c2cc(-c3ccncc3)cc(-c3ccncc3)c2)cc(-c2cc(-c3ccncc3)cc(-c3ccncc3)c2)n1]

In addition, as experimental examples 2 to 15, samples 2 to 15 were fabricated by a method similar to the method of fabricating the sample 1, except that the subphthalocyanine derivatives represented by the formulas (3-2) to (3-15) were used as the second organic semiconductor material in place of the subphthalocyanine derivative represented by the formula (3-1). Moreover, as experimental examples 16 to 22, samples 16 to 22 were fabricated by a method similar to the method of fabricating the sample 1, except that the subphthalocyanine derivative represented by the formula (3-2) was used as the second organic semiconductor material and the compounds represented by the formulas (4-1), (4-2), (5-1), (4-4) to (4-6), and (6-1) were used as the third organic semiconductor material.

(Method of Evaluating EQE and Dark-current Characteristics)

Evaluation of EQE and the dark-current characteristics were performed with use of a semiconductor parameter analyzer. More specifically, a current value (a bright current value) in a case where an amount of light to be applied from a light source to the photoelectric conversion element through a filter was 1.62 μW/cm² and a bias voltage to be applied between electrodes was −2.6 V and a current value (a dark current value) in a case where the amount of light was 0 μW/cm² were measured, and the EQE and the dark-current characteristics were calculated from these values.

(Method of Evaluating Responsivity)

Responsivity was evaluated on the basis of speed of falling, after stopping application of light, a bright current value observed during application of light with use of a semiconductor parameter analyzer. Specifically, an amount of light to be applied from a light source to the photoelectric conversion element through a filter was 1.62 μW/cm², and a bias voltage to be applied between electrodes was −2.6 V. A stationary current was observed in this state, and thereafter, application of light was stopped, and how the current was attenuated was observed. Subsequently, a dark current value was subtracted from an obtained current-time curve. A current-time curve to be thereby obtained was used, and time necessary for a current value after stopping application of light to attenuate to 3% of an observed current value in a stationary state was an indication of responsivity.

TABLE 7

| | | | | | | | | | Difference in | |
|---|---|---|---|---|---|---|---|---|---|---|
| | | | | | | | | | LUMO Level | |
| | | | | | | | | | between Second | |
| | | | | | | | | | Organic | Crystallinity |
| | | | | | | | | | Semiconductor | of Third |
| | Organic Photoelectric Conversion Layer | | | | | | | | Material and | Organic |
| | First Organic | Second Organic | Third Organic | | Dark-current | | LUMO Level | | First Organic | Semi- |
| | Semiconductor | Semiconductor | Semiconductor | | Character- | | (eV) | | Semiconductor | conductor |
| | Material | Material | Material | EQE | istics | Responsivity | First | Second | Material (eV) | Material |
| Experimental | Formula (1-1) | Formula (3-1) | Formula (4-3) | 0.9 | 0.2 | 0.12 | −4.50 | −3.98 | 0.52 | 1.4 |
| Example 1 | | | | | | | | | | |
| Experimental | Formula (1-1) | Formula (3-2) | Formula (4-3) | 1.0 | 0.07 | 0.13 | −4.50 | −4.13 | 0.37 | 1.3 |
| Example 2 | | | | | | | | | | |
| Experimental | Formula (1-1) | Formula (3-3) | Formula (4-3) | 1.0 | 0.2 | 0.2 | −4.50 | −4.15 | 0.35 | 1.5 |
| Example 3 | | | | | | | | | | |
| Experimental | Formula (1-1) | Formula (3-4) | Formula (4-3) | 1.0 | 0.2 | 0.2 | −4.50 | −4.24 | 0.26 | 1.4 |
| Example 4 | | | | | | | | | | |
| Experimental | Formula (1-1) | Formula (3-5) | Formula (4-3) | 1.0 | 0.07 | 0.11 | −4.50 | −4.24 | 0.26 | 1.4 |
| Example 5 | | | | | | | | | | |
| Experimental | Formula (1-1) | Formula (3-6) | Formula (4-3) | 1.0 | 0.3 | 0.13 | −4.50 | −4.24 | 0.26 | 1.2 |
| Example 6 | | | | | | | | | | |
| Experimental | Formula (1-1) | Formula (3-7) | Formula (4-3) | 0.9 | 0.13 | 0.06 | −4.50 | −4.25 | 0.25 | 1.3 |
| Example 7 | | | | | | | | | | |
| Experimental | Formula (1-1) | Formula (3-8) | Formula (4-3) | 1.0 | 0.5 | 0.3 | −4.50 | −4.30 | 0.20 | 1.3 |
| Example 8 | | | | | | | | | | |
| Experimental | Formula (1-1) | Formula (3-9) | Formula (4-3) | 1.0 | 0.3 | 0.2 | −4.50 | −4.31 | 0.19 | 1.2 |
| Example 9 | | | | | | | | | | |
| Experimental | Formula (1-1) | Formula (3-10) | Formula (4-3) | 1.0 | 0.3 | 0.11 | −4.50 | −4.31 | 0.19 | 1.3 |
| Example 10 | | | | | | | | | | |
| Experimental | Formula (1-1) | Formula (3-11) | Formula (4-3) | 1.0 | 0.7 | 0.12 | −4.50 | −4.35 | 0.15 | 1.2 |
| Example 11 | | | | | | | | | | |
| Experimental | Formula (1-1) | Formula (3-12) | Formula (4-3) | 1.0 | 0.0 | 0.2 | −4.50 | −4.42 | 0.08 | 1.2 |
| Example 12 | | | | | | | | | | |
| Experimental | Formula (1-1) | Formula (3-13) | Formula (4-3) | 1.0 | 0.7 | 0.2 | −4.50 | −4.42 | 0.08 | 1.2 |
| Example 13 | | | | | | | | | | |
| Experimental | Formula (1-1) | Formula (3-14) | Formula (4-3) | 1.0 | 0.7 | 0.3 | −4.50 | −4.50 | 0.00 | 1.0 |
| Example 14 | | | | | | | | | | |
| Experimental | Formula (1-1) | Formula (3-15) | Formula (4-3) | 1.0 | 1.0 | 1.0 | −4.50 | −4.58 | −0.08 | 1.0 |
| Example 15 | | | | | | | | | | |

TABLE 8

| | | | | | | | | | Difference in | | | |
|---|---|---|---|---|---|---|---|---|---|---|---|---|
| | | | | | | | | | HOMO Level | | | |
| | | | | | | | | | between Third | | | |
| | Organic Photoelectric Conversion Layer | | | | | | | | Organic | | | |
| | First | Second | Third | | | | | | Semiconductor | | | |
| | Organic | Organic | Organic | | Dark- | | HOMO | | Material and | | | |
| | Semi- | Semi- | Semi- | | current | | Level | | First Organic | | | |
| | conductor | conductor | conductor | | Character- | | (eV) | | Semiconductor | LUMO Leve (eV) | | |
| | Material | Material | Material | EQE | istics | Responsivity | First | Third | Material (eV) | First | Second | Third |
| Experimental | Formula | Formula | Formula | 1.0 | 1.0 | 1.0 | −6.33 | −5.20 | 1.13 | −4.50 | −4.13 | −2.61 |
| Example 16 | (1-1) | (3-2) | (4-1) | | | | | | | | | |
| Experimental | Formula | Formula | Formula | 1.1 | 0.5 | 2.0 | −6.33 | −5.34 | 0.99 | −4.50 | −4.13 | −2.71 |
| Example 17 | (1-1) | (3-2) | (4-2) | | | | | | | | | |
| Experimental | Formula | Formula | Formula | 1.0 | 0.10 | 0.06 | −6.33 | −5.51 | 0.82 | −4.50 | −4.13 | −2.87 |
| Example 18 | (1-1) | (3-2) | (5-1) | | | | | | | | | |
| Experimental | Formula | Formula | Formula | 1.0 | 0.07 | 0.2 | −6.33 | −5.64 | 0.69 | −4.50 | −4.13 | −2.91 |
| Example 2 | (1-1) | (3-2) | (4-3) | | | | | | | | | |
| Experimental | Formula | Formula | Formula | 0.9 | 0.01 | 0.06 | −6.33 | −5.78 | 0.55 | −4.50 | −4.13 | −2.79 |
| Example 19 | (1-1) | (3-2) | (4-4) | | | | | | | | | |
| Experimental | Formula | Formula | Formula | 1.1 | 0.01 | 0.06 | −6.33 | −5.83 | 0.50 | −4.50 | −4.13 | −2.91 |
| Example 20 | (1-1) | (3-2) | (4-5) | | | | | | | | | |
| Experimental | Formula | Formula | Formula | 0.0 | 0.02 | N.A. | −6.33 | −6.11 | 0.22 | −4.50 | −4.13 | −3.34 |
| Example 21 | (1-1) | (3-2) | (4-6) | | | | | | | | | |
| Experimental | Formula | Formula | Formula | 1.0 | 0.3 | 7.0 | −6.33 | −5.58 | 0.75 | −4.50 | −4.13 | −3.55 |
| Example 22 | (1-1) | (3-2) | (6-1) | | | | | | | | | |

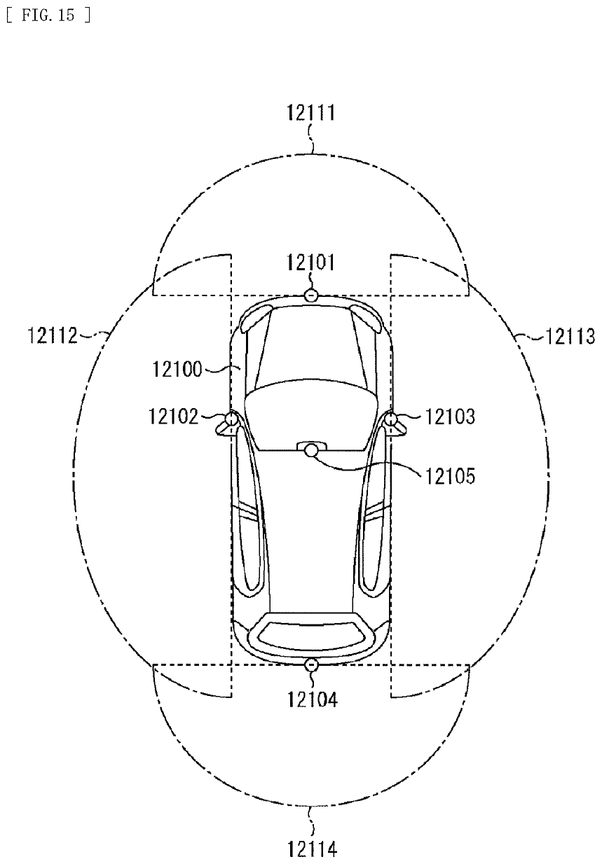

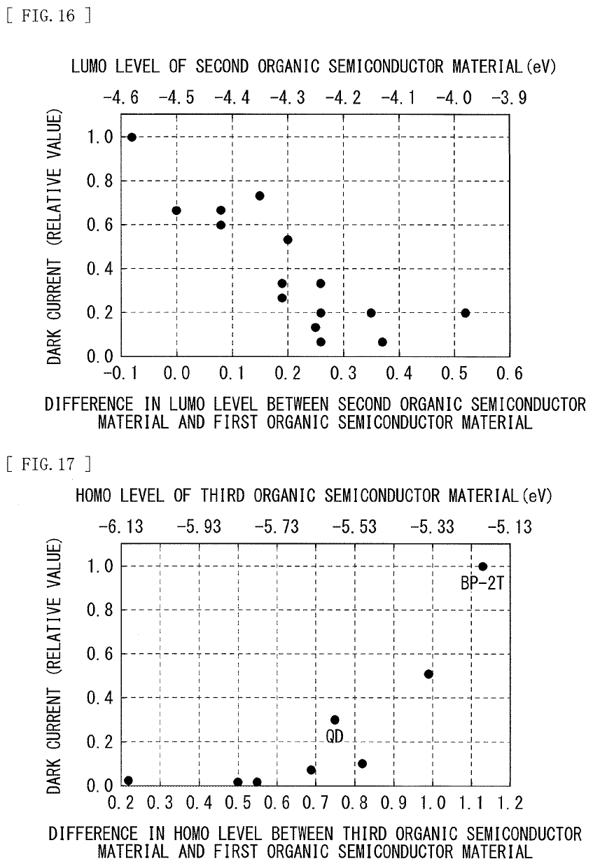

Table 7 provides a summary of the configuration of the organic photoelectric conversion layer, EQE, dark-current characteristics, responsivity, LUMO levels of the first organic semiconductor material and the second organic semiconductor material and a difference therebetween, and crystallinity of the third organic semiconductor material in the organic photoelectric conversion layer in the experimental examples 1 to 15. It is to be noted that the crystallinity of the third organic semiconductor material in the organic photoelectric conversion layer is described in detail later in the experiment 3. Table 8 provides a summary of the configuration of the organic photoelectric conversion layer, EQE, dark-current characteristics, responsivity, HOMO levels of the first organic semiconductor material and the third organic semiconductor material and a difference therebetween, and LUMO levels of the first organic semiconductor material, the second organic semiconductor material, and the third organic semiconductor material in the experimental examples 2 and 16 to 22. FIG. 16 illustrates a relationship between a dark current and both a difference in LUMO level between the second organic semiconductor material and the first organic semiconductor material and the LUMO level of the second organic semiconductor material. FIG. 17 illustrates a relationship between a dark current and both a difference in HOMO level between the third organic semiconductor material and the first organic semiconductor material and the LUMO level of the third organic semiconductor material.

It is to be noted that each of numerical values of the EQE, the dark-current characteristics, and the responsivity illustrated in Table 7 is a relative value in a case where each of the values of the experimental example 15 is a reference, i.e., 1.0. Each of numerical values of the EQE, the dark-current characteristics, and responsivity illustrated in Table 8 is a relative value in a case where each of the values of the experimental example 16 is a reference, i.e., 1.0. Moreover, the HOMO level of the third organic semiconductor material (the formula (4-3)) used in the experimental examples 1 to 15 was −5.64 eV.

As can be seen from Tables 7 and FIG. 16, as compared with the organic semiconductor material (the formula (3-15); the experimental example 15) having a deeper LUMO level than −4.50 eV, using the organic semiconductor material (the formulas (3-1) to (3-14); the experimental examples 1 to 14) having a LUMO level of −4.50 eV or more made it possible to achieve favorable dark-current characteristics. Moreover, as can be seen from Table 7 and FIG. 16, favorable dark current characteristics were achieved with a difference of 0.0 eV in LUMO level between the first organic semiconductor material and the second organic semiconductor material as a boundary. It is considered that the reason for this is that generation of a dark current from the HOMO of the third organic semiconductor material to the LUMO of the second organic semiconductor material was suppressed. In other words, it was found that it was preferable to use, as the second organic semiconductor material, an organic semiconductor material having a shallower LUMO level than the LUMO level of the first organic semiconductor material.

As can be seen from Table 8 and FIG. 17, a difference of less than 1 eV in HOMO level between the first organic semiconductor material and the third organic semiconductor material made it possible to achieve favorable dark-current characteristics. Moreover, as can be seen from Table 8 and FIG. 17, more favorable dark-current characteristics were achieved with a difference of 0.9 eV in HOMO Level between the first organic semiconductor material and the third organic semiconductor material as a boundary. It is considered that the reason for this is that generation of a dark current from the HOMO of the third organic semiconductor material to the LUMO of the first organic semiconductor material was suppressed. In other words, it was found that it was preferable to use, as the third organic semiconductor material, an organic semiconductor material having a HOMO level that allowed a difference in HOMO level between the first organic semiconductor material and the third organic semiconductor material to be less than 0.9 eV.

Further, as can be seen from Table 7 and FIG. 16, more favorable dark-current characteristics were stably achieved with a difference of 0.2 eV in LUMO level between the second organic semiconductor material and the first organic semiconductor material as a boundary. For example, in a case where the experimental example 15 is compared with the experimental example 7, such an effect was 10 or more times higher. For this reason, it was found that it was more preferable to use, as the second organic semiconductor material, an organic semiconductor material having a shallower LUMO level by 0.2 eV or more than the LUMO level of the first organic semiconductor material.

Furthermore, in the experimental examples 1 to 13 in which the second organic semiconductor material had a shallower LUMO level than the LUMO level of the first organic semiconductor material, crystallinity of the third organic semiconductor material was improved, as compared with the experimental examples 14 and 15. It is considered that in addition to suppression of generation of a dark current from the HOMO of the third organic semiconductor material to the LUMO of the second organic semiconductor material, an improvement in crystallinity of the third organic semiconductor material causes favorable dark-current characteristics. The crystallinity of the third organic semiconductor material is improved in the organic photoelectric conversion layer in a case where the second organic semiconductor material has a shallower LUMO level than the LUMO level of the first organic semiconductor material. It is considered that this reduced a contact area between the third organic semiconductor material and the first organic semiconductor material, thereby suppressing generation of a dark current. Moreover, it is considered that a contact area between the third organic semiconductor material and the second organic semiconductor material was reduced, thereby suppressing generation of a dark current.

Moreover, as can be seen from Table 7 and FIG. 16, in a case where the second organic semiconductor material had a shallower LUMO level than the LUMO level of the first organic semiconductor material, in addition to favorable dark-current characteristics, high responsivity was achieved. It is considered that the reason for this is that as compared with the experimental examples 14 and 15, in the experimental examples 1 to 13 in which the second organic semiconductor material had a shallower LUMO level than the LUMO level of the first organic semiconductor material, crystallinity of the third organic semiconductor material was improved as described above; therefore, it was possible to perform transport of hole carriers at higher speed.

Further, as can be seen from Table 8 and FIG. 17, more favorable dark-current characteristics were stably achieved with a difference of 0.7 eV in HOMO level between the third organic semiconductor material and the first organic semiconductor material as a boundary. For example, in a case where the experimental example 16 is compared with the experimental example 19, such an effect was 100 or more times higher. For this reason, it was found that it was more preferable to use, as the third organic semiconductor material, an organic semiconductor material having a LUMO level that allowed a difference in HOMO level between the third organic semiconductor material and the first organic semiconductor material to be less than 0.7 eV.

Furthermore, as can be seen from Table 8 and FIG. 17, a difference of 0.5 eV or more in HOMO level between the third organic semiconductor material and the first organic semiconductor material made it possible to achieve favorable EQE. In other words, it was found that using the third organic semiconductor material that allowed a difference in HOMO level between the third organic semiconductor material and the first organic semiconductor material to be 0.5 eV or more and less than 0.7 eV made it possible to achieve both extremely favorable dark current characteristics and favorable EQE.

Moreover, as can be seen from Tables 7 and 8 and FIGS. 16 and 17, in a case where C60 fullerene (the formula (1-1)) having a HOMO level of −6.33 eV and a LUMO level of −4.50 eV was used as the first organic semiconductor material, the LUMO level of the second organic semiconductor material and the HOMO level of the third organic semiconductor material had the following numeral values ranges, thereby achieving favorable dark-current characteristics. For example, it was found that using, as the second organic semiconductor material, an organic semiconductor material having a shallower LUMO level than −4.50 eV made it possible to achieve favorable dark-current characteristics. Further, it was found that using, as the second organic semiconductor material, an organic semiconductor material having a LUMO level of −4.3 eV or more made it possible to achieve more favorable dark-current characteristics. For example, it was found that using, as the third organic semiconductor material, an organic semiconductor material having a deeper HOMO level than −5.4 eV made it possible to achieve favorable dark-current characteristics. Moreover, it was found that using, as the third organic semiconductor material, an organic semiconductor material having a deeper HOMO level than −5.6 eV made it possible to achieve more favorable dark-current characteristics.

Further, the third organic semiconductor material may have a shallower LUMO level than the LUMO level of the second organic semiconductor material. It is considered that such an energy level relationship suppresses generation of electrons in the third organic semiconductor material resulting from excitors separation, which makes it possible to prevent a decline in EQE caused by recombination of electric charges (electrons and holes).

Furthermore, the third organic semiconductor material may preferably have a shallower LUMO level than the LUMO level of the first organic semiconductor material. It is considered that such an energy level relationship makes it possible to suppress generation of a dark current from one or more HOMO levels of the HOMO levels of the first organic semiconductor material, the second organic semiconductor material, and the third organic semiconductor material to the LUMO level of the third organic semiconductor material.

Accordingly, this indicates the third organic semiconductor material may preferably have a shallower LUMO level than the LUMO level of the second organic semiconductor material. Moreover, this indicates that the third organic semiconductor material may preferably have the shallowest LUMO level among the first organic semiconductor material, the second organic semiconductor material, and the third organic semiconductor material.

It is to be noted that the result of this experiment indicates that as the second organic semiconductor material, the subphthalocyanine derivatives represented by the formulas (3-1) to (3-13) out of the formulas (3-1) to (3-23) in Chem. 4 and Chem. 5 mentioned above may be preferably used, or the subphthalocyanine derivatives represented by the formulas (3-1) to (3-8) may be more preferably used.

### Experiment 3: Diffraction Peak Position, Crystal Particle Diameter, and Evaluation of Crystallinity by X-ray Diffraction Method

Samples used for crystallinity evaluation were fabricated, and diffraction peak positions, crystal particle diameters, and crystallinity of the samples were evaluated.

First, as a sample 23 (an experimental example 23), an organic photoelectric conversion layer was formed as follows. A glass substrate provided with an ITO electrode having a thickness of 50 nm was cleaned by UV/ozone treatment, and thereafter, C60 (the formula (1-1)) as the first semiconductor material, the subphthalocyanine derivative represented by the formula (3-2) as the second organic semiconductor material, and the compound (BP-rBDT) represented by the formula 4-3 as the third organic semiconductor material were evaporated simultaneously by a resistance heating method in a vacuum of 1×10⁻⁵ Pa or less with use of an organic evaporation apparatus while rotating a substrate holder. The first organic semiconductor material, the second organic semiconductor material, and the third organic semiconductor material were evaporated at evaporation speed of 0.025 nm/sec, 0.050 nm/sec, and 0.050 nm/sec, respectively to form a film having a total thickness of 200 nm as the sample used for crystallinity evaluation. In addition, samples used for crystallinity evaluation (samples 34 to 29 (experimental examples 24 to 29)) using the organic semiconductor materials represented by the formulas (4-1), (4-2), (5-1), and (4-4) to (4-6) in place of BP-rBDT represented by the formula (4-3) were fabricated.

These samples 23 to 29 were irradiated with X-rays with use of an X-ray diffraction apparatus using CuKα as an X-ray generation source to perform X-ray diffraction measurement in an out-of-plane direction in a range of 20=2° to 35° with use of an oblique incidence method, thereby evaluating peak positions, crystal particle diameters, and crystallinity of these samples. Moreover, samples used for crystallinity evaluation using the subphthalocyanine derivatives represented by the formulas (3-1) and (3-3) to (3-15) in place of the subphthalocyanine derivative represented by the formula (3-2) were fabricated, and crystallinity of these samples was evaluated. It is to be noted that the organic photoelectric conversion layers formed in the experimental examples 23 to 29 respectively had a configuration similar to those of the organic photoelectric conversion layer formed in the experimental examples 16, 17, 18, 2, 19, 20, and 21.

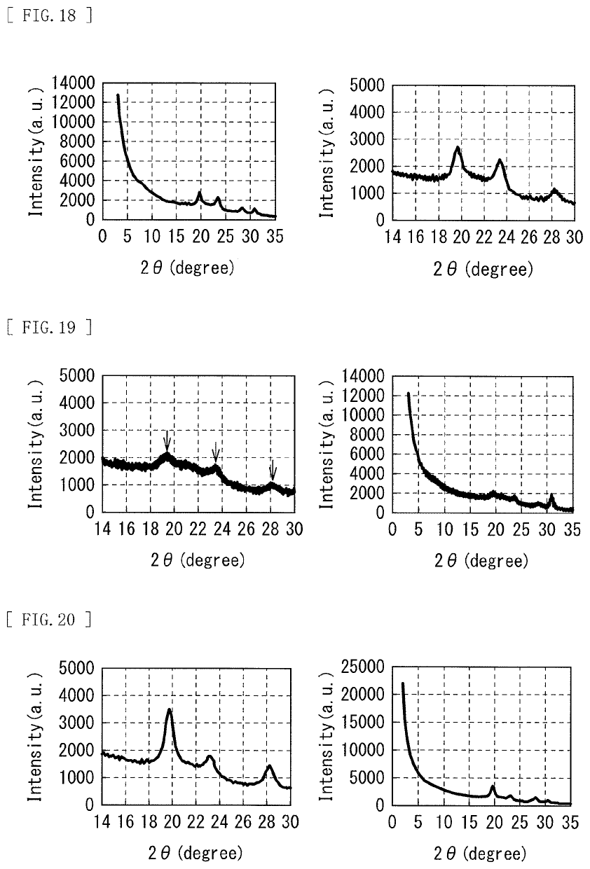

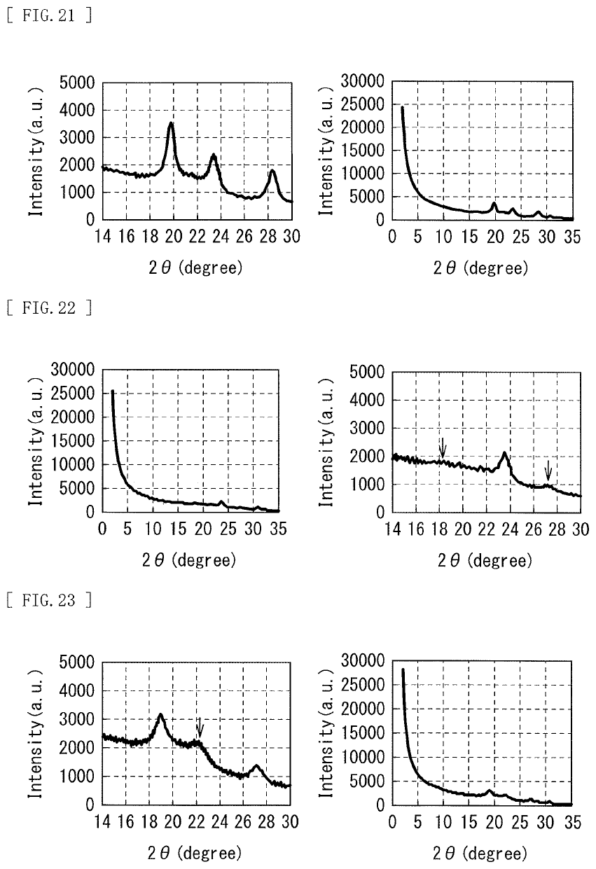

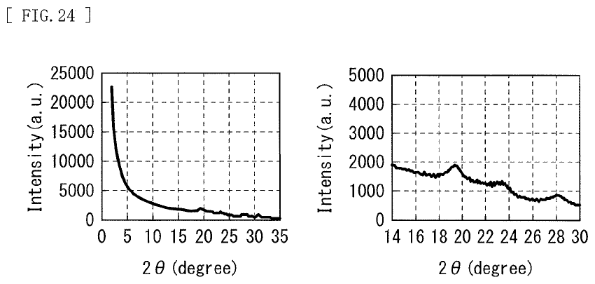

FIGS. 18 to 24 respectively illustrate results of X-ray diffraction measurement of the organic photoelectric conversion layers in the experimental examples 23 to 29. In each of FIGS. 18 to 24, a horizontal axis indicates 20, and X-ray diffraction intensity of each of the samples 23 to 29 used for crystallinity evaluation is plotted on a vertical axis. In each of FIGS. 18 to 24, a characteristic diagram on the left illustrates an entire measurement range (2θ=2° to 35°), and a characteristic diagram on the right illustrates a range of 2θ=14° to 30° in an enlarged manner. In a case where a peak position is less visible, the peak position is indicated by an arrow.

In each of the experimental examples, one or more diffraction peaks were observed in a region of a Bragg angle (2θ) from 18° to 21°, a region of a Bragg angle (2θ) from 22° to 24°, and a region of a Bragg angle (2θ) from 26° to 30° in an X-ray diffraction spectrum. These peaks are referred to as first, second, and third peaks in order. Table 9 provides a summary of the configurations of the organic photoelectric conversion layers, positions of the first, second, and third peaks, and crystal particle diameters in the experimental examples 23 to 29. It is to be noted that one peak always observed at 2θ=30° to 31° is not derived from the organic photoelectric conversion layer but ITO provided in the substrate.

TABLE 9

| | Organic Photoelectric Conversion Layer | | | | | | Crystal |
|---|---|---|---|---|---|---|---|
| | First Organic | Second Organic | Third Organic | | | | Particle |
| | Semiconductor | Semiconductor | Semiconductor | Peak Position (°) | | | Diameter |
| | Material | Material | Material | First | Second | Third | (nm) |
| Experimental | Formula (1-1) | Formula (3-2) | Formula (4-1) | 19.6 | 23.3 | 28.2 | 10.3 |
| Example 23 | | | | | | | |
| Experimental | Formula (1-1) | Formula (3-2) | Formula (4-2) | 19.4 | 23.5 | 28.1 | 7.9 |
| Example 24 | | | | | | | |
| Experimental | Formula (1-1) | Formula (3-2) | Formula (5-1) | 19.7 | 23.2 | 28.2 | 9.2 |
| Example 25 | | | | | | | |
| Experimental | Formula (1-1) | Formula (3-2) | Formula (4-3) | 19.7 | 23.4 | 28.3 | 11.3 |
| Example 26 | | | | | | | |
| Experimental | Formula (1-1) | Formula (3-2) | Formula (4-4) | 19.1 | 23.5 | 27.2 | 9.6 |
| Example 27 | | | | | | | |
| Experimental | Formula (1-1) | Formula (3-2) | Formula (4-5) | 18.8 | 22.2 | 27.1 | 6.1 |
| Example 28 | | | | | | | |
| Experimental | Formula (1-1) | Formula (3-2) | Formula (4-6) | 19.4 | 23.5 | 28.1 | 6.7 |
| Example 29 | | | | | | | |

(Method of Evaluating Peak Position and Crystal Particle Diameter)

The positions of the first, second, and third peaks were determined from a spectrum after background subtraction by fitting each of the peaks with use of the Pearson VII function. The second peak is fitted with use of the Pearson VII function to determine a half width of the second peak, and the half width is substituted into the Scherrer equation to determine the crystal particle diameter. A Scherrer constant K used here was 0.94.

(Method of Evaluating Crystallinity)

An area of the first peak was determined from a spectrum after background subtraction by fitting the first peak with use of the Pearson VII function, and the thusdetermined area was an indication of crystallinity (a degree of crystallization).

In FIGS. 18 to 24, a peak observed at a Bragg angle (2θ) of 18° or more indicates that the third organic semiconductor material in the organic photoelectric conversion layer exhibits crystallinity, and an intermolecular distance may be 4.9 angstroms or less. It is expected that as the intermolecular distance decreases, an overlap between molecular orbitals increases, which makes it possible to perform transport of holes at higher speed.

In FIGS. 18 to 24, three diffraction peaks (first, second, and third peaks) observed in the region of a Bragg angle (2θ) from 18° to 21°, the region of a Bragg angle (2θ) from 22° to 24°, and the region of a Bragg angle (2θ) from 26° to 30° indicate that the third organic semiconductor material in the organic photoelectric conversion layer exhibits crystallinity. In addition, this indicates that the third organic semiconductor material has a packing mode called herringbone structure in the organic photoelectric conversion layer.

For example, it is easily assumed with use of crystal structure data of BP-2T (the formula (4-3)) disclosed in literatures, etc. that strong diffraction peaks are shown at three points of 19.5°, 23.4°, and 28.2° in a case where CuKα is an X-ray generation source. The peak at 19.5° of the three diffraction peaks corresponds to a diffraction peak from plane orientations (110) and (11-2). The peak at 23.4° corresponds to a diffraction peak from a plane orientation (200), and the peak at 28.2° corresponds to a diffraction peak from a plane orientation (12-1). These diffraction peaks are important peaks indicating formation of the herringbone structure. It is to be noted that a space group of BP-2T is P21/c according to the crystal structure data of BP-2T.

Incidentally, it is easily assumed with use of crystal structure data disclosed in literatures, etc. that in BP-4T (in which the number of thiophene rings of BP-2T represented by the formula (4-1) is four), strong diffraction peaks are shown at three points of 19.5°, 23.4°, and 28.2°, which indicate formation of the herringbone structure in a case where CuKα is an X-ray generation source, as with the case of BP-2T. The space group of BP-4T is P21/n. As can be seen from the above, this means that the third organic semiconductor material has three diffraction peaks observed in the region of a Bragg angle (2θ) from 18° to 21°, the region of a Bragg angle (2θ) from 22° to 24°, and the region of a Bragg angle (2θ) from 26° to 30° irrespective of the space group, thereby having a packing mode called the herringbone structure in the organic photoelectric conversion layer.

In this experiment, as can be seen from Table 9 and FIG. 18, in the experimental example 23 using BP-2T (the formula 4-1) as the third organic semiconductor, the first, second, and third diffraction peaks were observed at 19.7°, 23.3°, and 28.2°, respectively, which are substantially the same as positions of the foregoing diffraction peaks in the literatures. In other words, it was found that the third organic semiconductor material used in the experimental example 23 exhibited crystallinity and had the herringbone structure in the organic photoelectric conversion layer.

Even in Table 9 and FIGS. 19 to 24, the first, second, and third peaks were similarly observed. More specifically, it was found that in addition to BP-2T represented by the formula (4-1), the compounds represented by the formulas (4-2), (5-1), and (4-3) to (4-6) also exhibited crystallinity and had the herringbone structure in the organic photoelectric conversion layer.

Influences of crystallinity of the third organic semiconductor material and presence or absence of the herringbone structure exerted on the photoelectric conversion element are confirmed from results of the experimental examples 2 and 22 in the experiment 2 (refer to Table 8). The experimental example 2 using BP-rBDT represented by the formula (4-3) as the third organic semiconductor material had a HOMO level of −5.64 eV and the experimental example 22 using QD represented by the formula (6-1) as the third organic semiconductor material had a HOMO level of −5.58 eV that was close to the HOMO level of the third organic semiconductor material in the experimental example 2. However, the experimental example 2 achieved favorable dark-current characteristics and favorable responsivity. In FIG. 21, one or more diffraction peaks were observed in each of the region of a Bragg angle (2θ) from 18° to 21°, the region of a Bragg angle (2θ) from 22° to 24°, and the region of a Bragg angle (2θ) from 26° to 30°; therefore, it was known that BP-rBDT had crystallinity and had the herringbone structure in the organic photoelectric conversion layer. Although not illustrated here, in QD, no diffraction peak was observed in the region of a Bragg angle (2θ) from 18° to 21°, the region of a Bragg angle (2θ) from 22° to 24°, and the region of a Bragg angle (2θ) from 26° to 30° in an X-ray diffraction spectrum; therefore, it is assumed that QD does not exhibit crystallinity and does not have the herringbone structure in the organic photoelectric conversion layer. Accordingly, differences in dark-current characteristics and responsivity between the experimental example 2 and the experimental example 22 are considered as differences depending on presence or absence of crystallinity of the third organic semiconductor material in the organic photoelectric conversion layer and whether the third organic semiconductor material has the herringbone structure in the organic photoelectric conversion layer. In other words, it is assumed that in the experimental example 2, BP-rBDT exhibited crystallinity and had the herringbone structure in the organic photoelectric conversion layer, which reduced a contact area with the first organic semiconductor material, thereby suppressing generation of a dark current. Regarding responsivity, it is assumed that BP-rBDT exhibited crystallinity and had the herringbone structure in the organic photoelectric conversion layer, which made it possible to perform transport of holes at higher speed.

Moreover, as can be seen from results of crystallinity evaluation illustrated in Table 7, using, as the second organic semiconductor material, an organic semiconductor material having a shallower LUMO level than the LUMO level of the first organic semiconductor material improved crystallinity of the third organic semiconductor material in the organic photoelectric conversion layer. It is assumed that interaction among the first organic semiconductor material, the second organic semiconductor material, and the third organic semiconductor material varied depending on the energy level of the second organic semiconductor material, thereby causing a difference in crystallinity of the third organic semiconductor material. It is assumed that this made it possible to achieve more favorable dark-current characteristics and more favorable responsivity.

Moreover, as can be seen from results of evaluation of the crystal particle diameter illustrated in Table 7, it is preferable that the crystal particle diameter of the third organic semiconductor material be in a range from 6 nm to 12 nm both inclusive. In other words, it was found that the third organic semiconductor material having a crystal particle diameter of 6 nm to 12 nm both inclusive made it possible to achieve the foregoing favorable dark-current characteristics and the foregoing favorable responsivity.

It is to be noted that in a case where the diffraction peaks indicating that the third organic semiconductor material has the herringbone structure are not observed in the region of a Bragg angle (2θ) from 18° to 21°, the region of a Bragg angle (2θ) from 22° to 24°, and the region of a Bragg angle (2θ) from 26° to 30°, it is possible to observe the diffraction peaks by checking results of crystal structure data of the third organic semiconductor material against an X-ray diffraction spectrum measured with use of the foregoing method, as described above. It is to be noted that a single-layer film including the third organic semiconductor material may be used for X-ray diffraction measurement. Note that, for example, a case where a large number of peaks are detected in each of the regions is considered as a reason why the diffraction peaks are not observed.

Although the description has been given by referring to the embodiment, the modification examples, and the application examples, the contents of the present disclosure are not limited to the embodiment, the modification examples, and the application examples, and may be modified in a variety of ways. For example, the foregoing embodiment has exemplified, as the photoelectric conversion element (the solid-state imagine device), a configuration in which the organic photoelectric converter 11G detecting green light and the inorganic photoelectric converters 11B and 11R respectively detecting blue light and red light are stacked; however, the contents of the present disclosure is not limited thereto. More specifically, the organic photoelectric converter may detect red light or blue light, and the inorganic photoelectric converter may detect green light.

Moreover, the number of organic photoelectric converters, the number of inorganic photoelectric converters, a ratio between the organic photoelectric converters and the inorganic photoelectric converters are not limited, and two or more organic photoelectric converters may be provided, or color signals of a plurality of colors may be obtained by only the organic photoelectric converter. Further, the content of the present disclosure is not limited to a configuration in which organic photoelectric converters and inorganic photoelectric converters are stacked along the vertical direction, and organic photoelectric converters and inorganic photoelectric converters may be disposed side by side along a substrate surface.

Furthermore, in the foregoing embodiment, the configuration of the back-side illumination type solid-state imaging device has been exemplified; however, the contents of the present disclosure are applicable to a front-side illumination type solid-state imaging device. Further, it may not be necessary for the solid-state imaging device (the photoelectric conversion element) of an example embodiment of the present disclosure to include all components described in the foregoing embodiment, and the solid-state imaging device of an example embodiment of the present disclosure may include any other layer.

Note that the effects described in the present specification are illustrative and non-limiting. The technology may have effects other than those described in the present specification.

The present disclosure may have the following configurations.

(1)

A photoelectric conversion element, including:

a first electrode and a second electrode facing each other; and

a photoelectric conversion layer disposed between the first electrode and the second electrode, and including a first organic semiconductor material, a second organic semiconductor material, and a third organic semiconductor material that have mother skeletons different from one another,

the first organic semiconductor material being one of fullerenes and fullerene derivatives, and

the third organic semiconductor material having a highest occupied molecular orbital level that is shallower than a highest occupied molecular orbital level of the first organic semiconductor material and a highest occupied molecular orbital level of the second organic semiconductor material and allows a difference in highest occupied molecular orbital level between the third organic semiconductor material and the first organic semiconductor material to be less than 0.9 eV.

(2)

The photoelectric conversion element according to (1), in which a lowest unoccupied molecular orbital level of the second organic semiconductor material is shallower than a lowest unoccupied molecular orbital level of the first organic semiconductor material.

(3)

The photoelectric conversion element according to (1) or (2), in which a lowest unoccupied molecular orbital level of the second organic semiconductor material is shallower by 0.2 eV or more than a lowest unoccupied molecular orbital level of the first organic semiconductor material.

(4)

The photoelectric conversion element according to any of (1) to (3), in which the difference in highest occupied molecular orbital level between the third organic semiconductor material and the first organic semiconductor material is less than 0.7 eV.

(5)

The photoelectric conversion element according to any of (1) to (4), in which the difference in highest occupied molecular orbital level between the third organic semiconductor material and the first organic semiconductor material is 0.5 eV or more and less than 0.7 eV.

(6)

The photoelectric conversion element according to any of (1) to (5), in which the third organic semiconductor material has a shallower lowest unoccupied molecular orbital level than the lowest unoccupied molecular orbital level of the first organic semiconductor material.

(7)

The photoelectric conversion element according to any of (1) to (6), in which the third organic semiconductor material has crystallinity.

(8)

The photoelectric conversion element according to any of (1) to (7), in which a particle diameter of a crystal component of the third organic semiconductor material is in a range from 6 nm to 12 nm both inclusive.

(9)

The photoelectric conversion element according to any of (1) to (8), in which the third organic semiconductor material has one or more diffraction peaks in a region of a Bragg angle 2θ±0.2° of 18° or more in an X-ray diffraction spectrum.

(10)

The photoelectric conversion element according to any of (1) to (9), in which the third organic semiconductor material has one or more diffraction peaks in each of a region of a Bragg angle 2θ±0.2° ranging from 18° to 21° both inclusive, a region of a Bragg angle 2θ±0.2° ranging from 22° to 24° both inclusive, and a Bragg angle 2θ±0.2° ranging from 26° to 30° both inclusive in an X-ray diffraction spectrum.

(11)

The photoelectric conversion element according to any of (1) to (10), in which the fullerenes and the fullerene derivatives are represented by one of the following formulas (1) and (2):

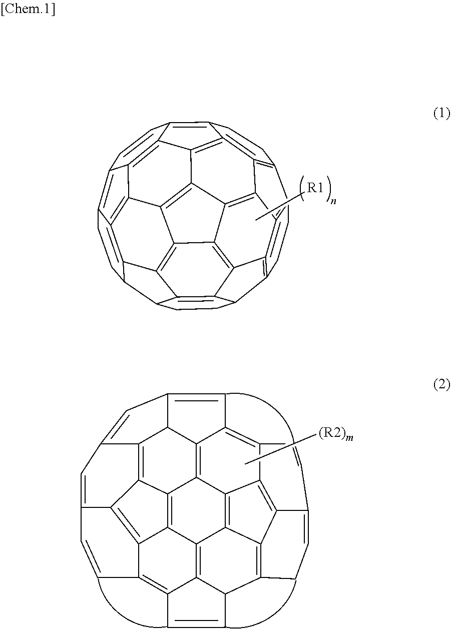

where each of R1 and R2 is independently one of a hydrogen atom, a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfanyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, and derivatives thereof, and each of “n” and “m” is 0 or an integer of 1 or more.

(12)

The photoelectric conversion element according to any of (1) to (11), in which the lowest unoccupied molecular orbital level of the second organic semiconductor material is shallower than −4.5 eV.

(13)

The photoelectric conversion element according to any of (1) to (12), in which the lowest unoccupied molecular orbital level of the second organic semiconductor material is −4.3 eV or more.

(14)

The photoelectric conversion element according to any of (1) to (13), in which the highest occupied molecular orbital level of the third organic semiconductor material is deeper than −5.4 eV.

(15)

The photoelectric conversion element according to any of (1) to (14), in which the highest occupied molecular orbital level of the third organic semiconductor material is deeper than −5.6 eV.

(16)

The photoelectric conversion element according to any of (1) to (15), in which the second organic semiconductor material is subphthalocyanine or a subphthalocyanine derivative represented by the following formula (3):

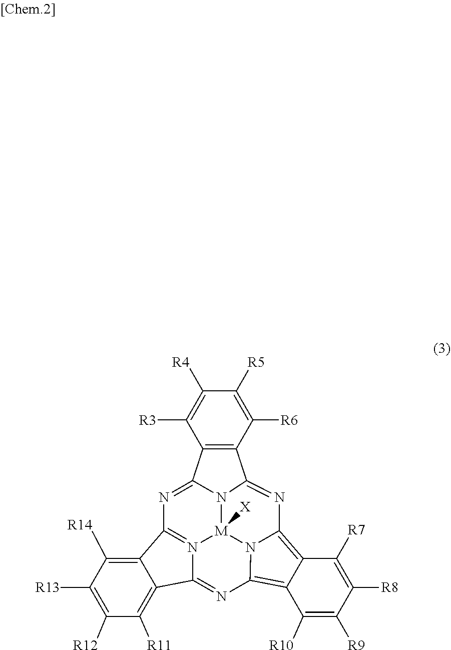

where each of R3 to R14 is independently selected from a group configured of a hydrogen atom, a halogen atom, a straight-chain, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, a phenyl group, a carboxy group, a carboxyamide group, a carboalkoxy group, an acyl group, a sulfonyl group, a cyano group, and a nitro group, any adjacent ones of R3 to R14 are optionally part of a condensed aliphatic ring or a condensed aromatic ring, the condensed aliphatic ring or the condensed aromatic ring optionally includes one or more atoms other than carbon, M is one of boron and a divalent or trivalent metal, and X is an anionic group.

(17)

The photoelectric conversion element according to any of (1) to (16), in which the third organic semiconductor material is a compound represented by one of the following formula (4) and the following formula (5):

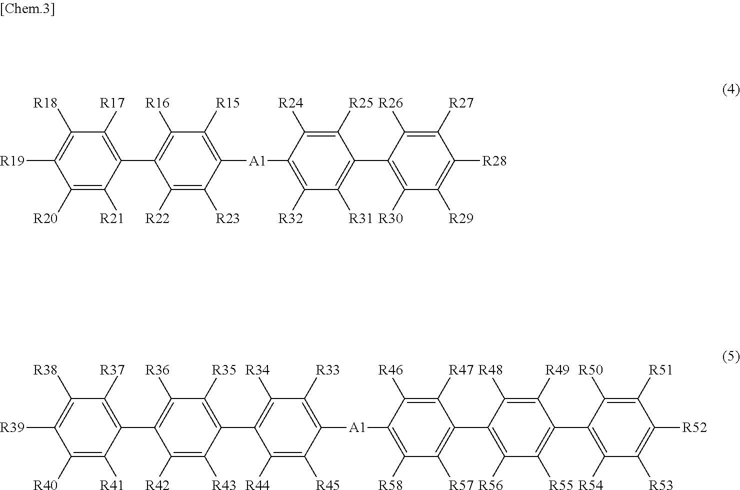

where each of A1 and A2 is one of a conjugated aromatic ring, a condensed aromatic ring, a condensed aromatic ring including a hetero element, oligothiophene, and thiophene, each of which is optionally substituted by one of a halogen atom, a straight-chain, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, a carboxy group, a carboxyamide group, a carboalkoxy group, an acyl group, a sulfonyl group, a cyano group, and a nitro group, each of R15 to R58 is independently selected from a group configured of a hydrogen atom, a halogen atom, a straight-chain, branched, or cyclic alkyl group, thioalkyl group, an aryl group, a thioaryl group, an arylsulfonyl group, an alkylsulfonyl group, an amino group, an alkylamino group, an arylamino group, a hydroxy group, an alkoxy group, an acylamino group, an acyloxy group, a phenyl group, a carboxy group, a carboxyamide group, a carboalkoxy group, an acyl group, a sulfonyl group, a cyano group, and a nitro group, and any adjacent ones of R15 to R23, any adjacent ones of R24 to R32, any adjacent ones of R33 to R45, and any adjacent ones of R46 to R58 are optionally bound to one another to form a condensed aromatic ring.

(18)

The photoelectric conversion element according to any of (1) to (17), in which the third organic semiconductor material does not have absorption in a wavelength region of 500 nm or more.

(19)

The photoelectric conversion element according to any of (1) to (18), in which the second organic semiconductor material has a maximal absorption wavelength in a wavelength region from 500 nm to 600 nm both inclusive.

(20)

A solid-state imaging device provided with pixels each including one or more organic photoelectric converters, each of the organic photoelectric converters including:

a first electrode and a second electrode facing each other; and

a photoelectric conversion layer disposed between the first electrode and the second electrode, and including a first organic semiconductor material, a second organic semiconductor material, and a third organic semiconductor material that have mother skeletons different from one another,

the first organic semiconductor material being one of fullerenes and fullerene derivatives, and

the third organic semiconductor material having a highest occupied molecular orbital level that is shallower than a highest occupied molecular orbital level of the first organic semiconductor material and a highest occupied molecular orbital level of the second organic semiconductor material and allows a difference in highest occupied molecular orbital level between the third organic semiconductor material and the first organic semiconductor material to be less than 0.9 eV.

(A1)

An imaging device, including: a first electrode; a second electrode; a photoelectric conversion layer disposed between the first electrode and the second electrode and including a first organic semiconductor material, a second organic semiconductor material, and a third organic semiconductor material, where the second organic semiconductor material includes a subphthalocyanine material, and where the second organic semiconductor material has a highest occupied molecular orbital level ranging from −6 eV to −6.7 eV.

(A2)

The imaging device according to (A1), where a lowest unoccupied molecular orbital level of the second organic semiconductor material is less than a lowest unoccupied molecular orbital level of the first organic semiconductor material.

(A3)

The imaging device according to any of (A1) to (A2), where the second organic semiconductor material has the highest occupied molecular orbital level ranging from −6 eV to −6.5 eV.

(A4)

The imaging device according to any of (A1) to (A3), where the second organic semiconductor material has the highest occupied molecular orbital level ranging from −6 eV to −6.3 eV.

(A5)

The imaging device according to any of (A1) to (A4), where the second organic semiconductor material as a single layer film has a higher linear absorption coefficient of a maximal absorption wavelength in a visible light region than the first organic semiconductor material as a single layer film and the third organic semiconductor material as a single layer film.

(A6)

The imaging device according to any of (A1) to (A5), where each of the first organic semiconductor material, the second organic semiconductor material, and the third organic semiconductor material is independently only one kind of organic semiconductor material.

(A7)

The imaging device according to any of (A1) to (A6), where the third organic semiconductor material has a value equal to or higher than the highest occupied molecular orbital level of the second organic semiconductor material.

(A8)

The imaging device according to any of (A1) to (A7), where the subphthalocyanine material is represented by the following formula (6) or a derivative thereof

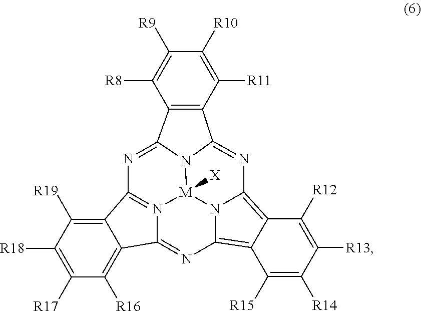

where each of R8 to R19 is independently selected from a group configured of a hydrogen atom, a halogen atom, a straight-chain, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, a phenyl group, a carboxy group, a carboxyamide group, a carboalkoxy group, an acyl group, a sulfonyl group, a cyano group, and a nitro group; M is one of boron and a divalent or trivalent metal; and X is an anionic group.

(A9)

The imaging device according to any of (A1) to (A8), where adjacent ones of R8 to R19 are part of a condensed aliphatic ring or a condensed aromatic ring.

(A10)

The imaging device according to any of (A1) to (A9), where the condensed aliphatic ring or the condensed aromatic ring includes one or more atoms other than carbon.

(A11)

The imaging device according to any of (A1) to (A10), where the derivative of the subphthalocyanine material is selected from the group consisting of

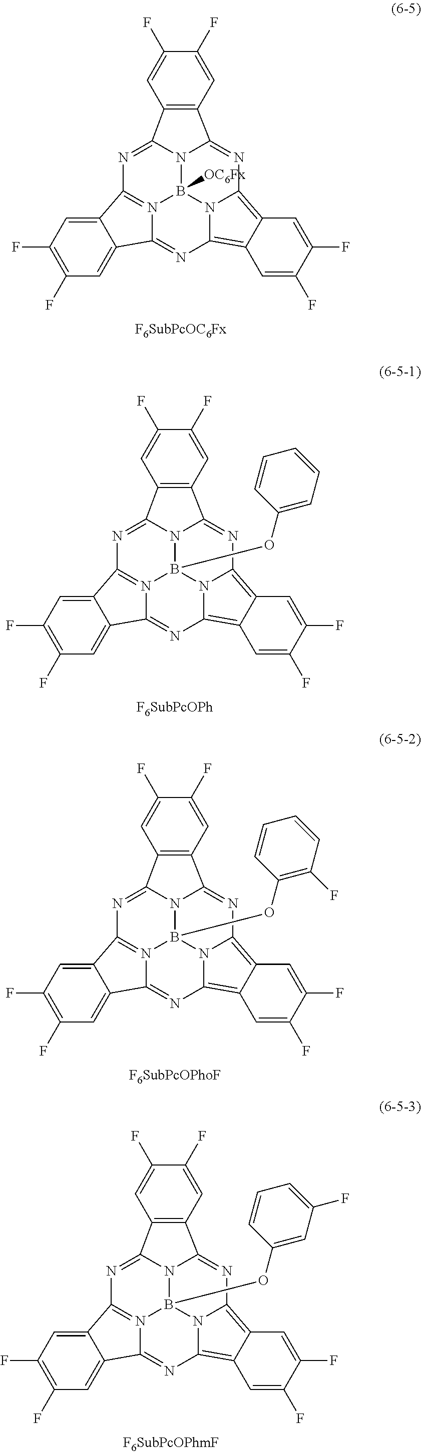

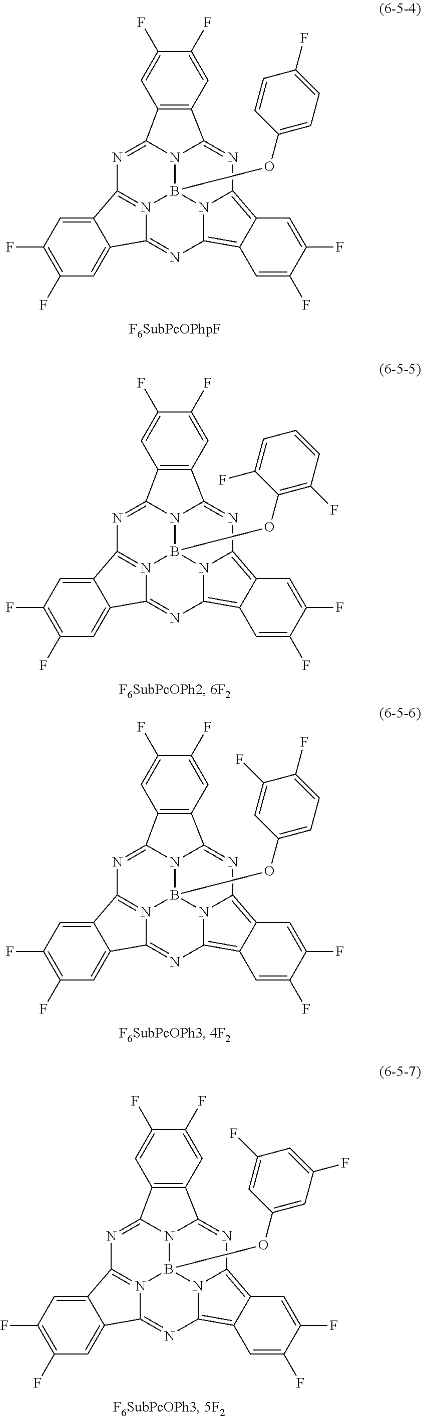

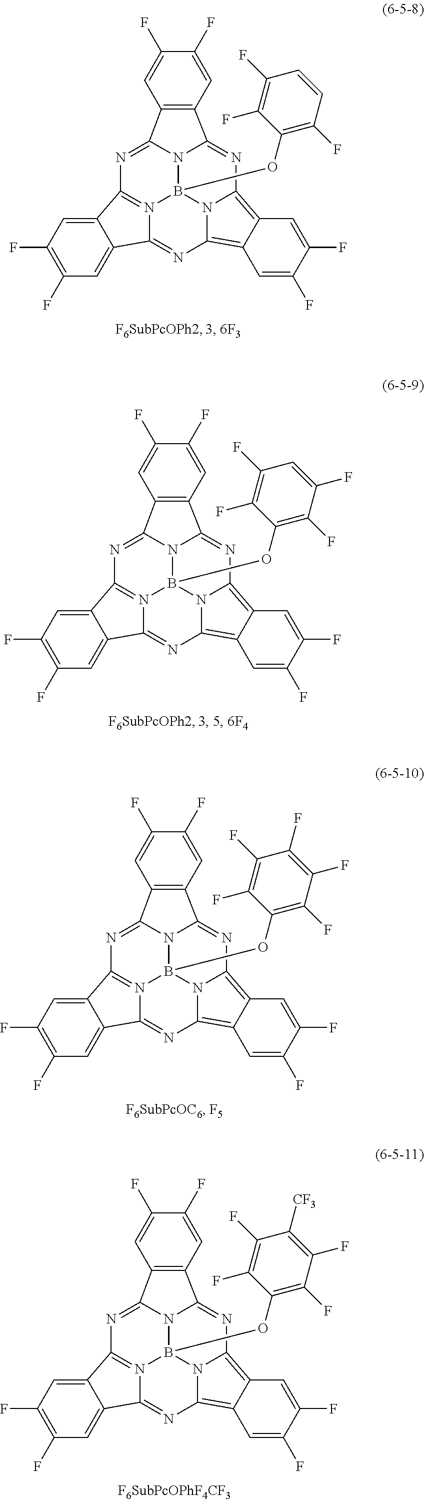

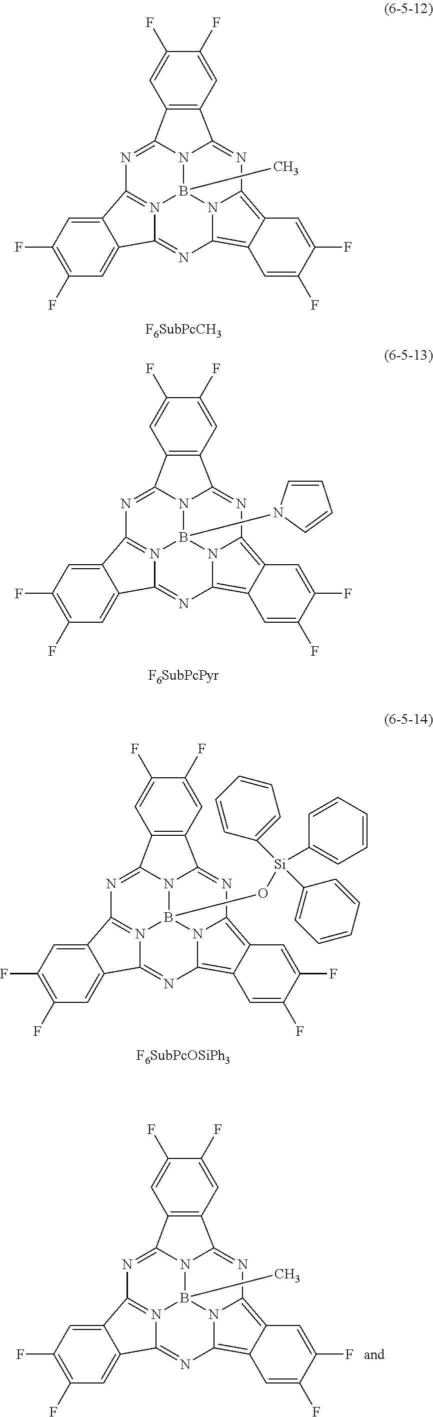

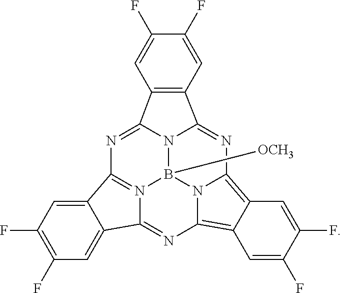

(A12)

The imaging device according to any of (A1) to (A11), where the third organic semiconductor material as a single layer film has a higher hole mobility than a hole mobility of the second organic semiconductor material as a single layer film.

(A13)

The imaging device according to any of (A1) to (A12), where the third organic semiconductor material is selected from the group consisting of: quinacridone represented by the following formula (3) or a derivative thereof, triallylamine represented by the following formula (4) or a derivative thereof, and benzothienobenzothiophene represented by a formula (5) or a derivative thereof

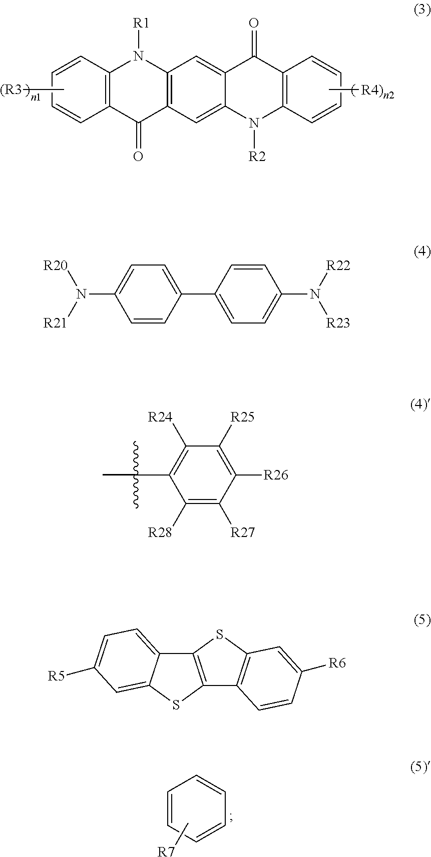

quinacridone represented by the following formula (3) or a derivative thereof, triallylamine represented by the following formula (4) or a derivative thereof, and benzothienobenzothiophene represented by a formula (5) or a derivative thereof

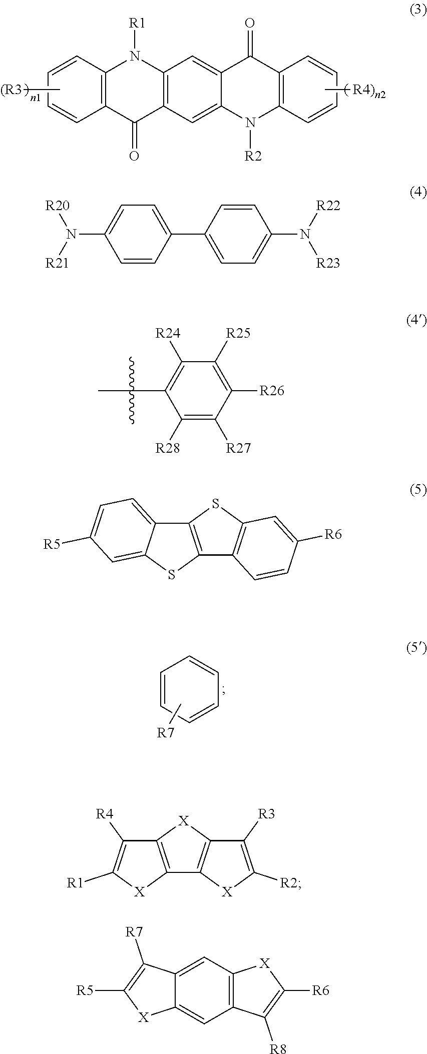

(A14)

An electronic apparatus, including: a lens; signal processing circuitry; and an imaging device, including: a first electrode; a second electrode; a photoelectric conversion layer disposed between the first electrode and the second electrode and including a first organic semiconductor material, a second organic semiconductor material, and a third organic semiconductor material, where the second organic semiconductor material includes a subphthalocyanine material, and where the second organic semiconductor material has a highest occupied molecular orbital level ranging from −6 eV to −6.7 eV.

It should be understood by those skilled in the art that various modifications, combinations, sub-combinations and alterations may occur depending on design requirements and other factors insofar as they are within the scope of the appended claims or the equivalents thereof.

What is claimed is:

1-14. (canceled)

15. A photoelectric conversion element, including:
a first electrode and a second electrode facing each other; and
a photoelectric conversion layer disposed between the first electrode and the second electrode, and including a first organic semiconductor material, a second organic semiconductor material, and a third organic semiconductor material that have mother skeletons different from one another;
wherein the first organic semiconductor material being one of fullerenes and fullerene derivatives, and
wherein the third organic semiconductor material has a highest occupied molecular orbital level that is shallower than a highest occupied molecular orbital level of the first organic semiconductor material and a highest occupied molecular orbital level of the second organic semiconductor material and allows a difference in highest occupied molecular orbital level between the third organic semiconductor material and the first organic semiconductor material to be less than 0.9 eV.

16. The photoelectric conversion element according to claim 15, in which a lowest unoccupied molecular orbital level of the second organic semiconductor material is shallower than a lowest unoccupied molecular orbital level of the first organic semiconductor material.

17. The photoelectric conversion element according to claim 15, in which a lowest, unoccupied molecular orbital level of the second organic semiconductor material is shallower by 0.2 eV or more than a lowest unoccupied molecular orbital level of the first organic semiconductor material.

18. The photoelectric conversion element according to claim 15, wherein the difference in highest occupied molecular orbital level between the third organic semiconductor material and the first organic semiconductor material is less than 0.7 eV.

19. The photoelectric conversion element according to claim 15, wherein the difference in highest occupied molecular orbital level between the third organic semiconductor material and the first organic semiconductor material is 0.5 eV or more and less than 0.7 eV.

20. The photoelectric conversion element according to claim 15, wherein the third organic semiconductor material has a shallower lowest unoccupied molecular orbital level than a lowest unoccupied molecular orbital level of the first organic semiconductor material.

21. The photoelectric conversion element according to claim 15, wherein the third organic semiconductor material has crystallinity.

22. The photoelectric conversion element according to claim 15, wherein a particle diameter of a crystal component of the third organic semiconductor material is in a range from 6 nm to 12 nm both inclusive.

23. The photoelectric conversion element according to claim 15, wherein the third organic semiconductor material has one or more diffraction peaks in a region of a Bragg angle 2θ±0.2° of 18° or more in an X-ray diffraction spectrum.

24. The photoelectric conversion element according to claim 15, wherein the third organic semiconductor material has one or more diffraction peaks in each of a region of a Bragg angle 2θ±0.2° ranging from 18° to 21° both inclusive, a region of a Bragg angle 2θ±0.2° ranging from 22° to 24° both inclusive, and a Bragg angle 2θ±0.2° ranging from 26° to 30° both inclusive in an X-ray diffraction spectrum.

25. The photoelectric conversion element according to claim 15, wherein the fullerenes and the fullerene derivatives are represented by one of the following formulas (1) and (2): 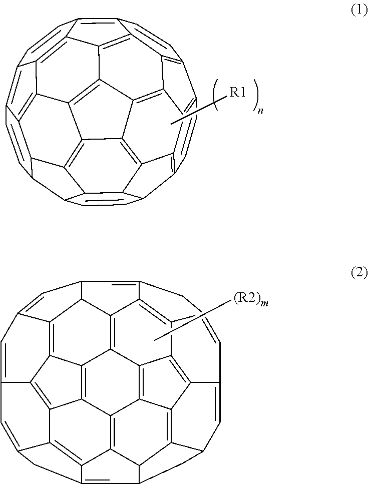
where each of R1 and R2 is independently one of a hydrogen atom, a halogen atom, a straight-chain, branched, or cyclic alkyl group, a phenyl group, a group having a straight-chain or condensed ling aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, and derivatives thereof, and each of “n” and “m” is 0 or an integer of 1 or more.

26. The photoelectric conversion element according to claim 15, wherein a lowest unoccupied molecular orbital level of the second organic semiconductor material is shallower than −4.5 eV.

27. The photoelectric conversion element according to claim 15, wherein a lowest unoccupied molecular orbital level of the second organic semiconductor material is −4.3 eV or more.

28. The photoelectric conversion element according to claim 15, wherein the highest occupied molecular orbital level of the third organic semiconductor material is deeper than −5.4 eV.

29. The photoelectric conversion element according to claim 15, wherein the highest occupied molecular orbital level of the third organic semiconductor material is deeper than −5.6 eV.

30. The photoelectric conversion element according to claim 15, wherein the second organic semiconductor material is subphthalocyanine or a subphthalocyanine derivative represented by the following formula (3): 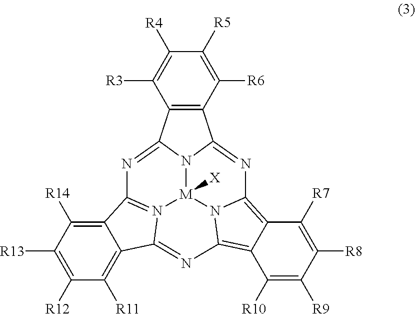
where each of R3 to R14 is independently selected from a group configured of a hydrogen atom, a halogen atom, a straight-chain, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, a phenyl group, a carboxy group, a carboxyamide group, a carboalkoxy group, an acyl group, a sulfonyl group, a cyano group, and a nitro group, any adjacent ones of R3 to R14 are optionally part of a condensed aliphatic ring or a condensed aromatic ring, the condensed aliphatic ring or the condensed aromatic ring optionally, includes one or more atoms other than carbon, M is one of boron and a divalent or trivalent metal, and X is an anionic group.

31. The photoelectric conversion element according to claim 15, wherein the third organic semiconductor material is a compound represented by one of the following formula (4) and the following formula (5): 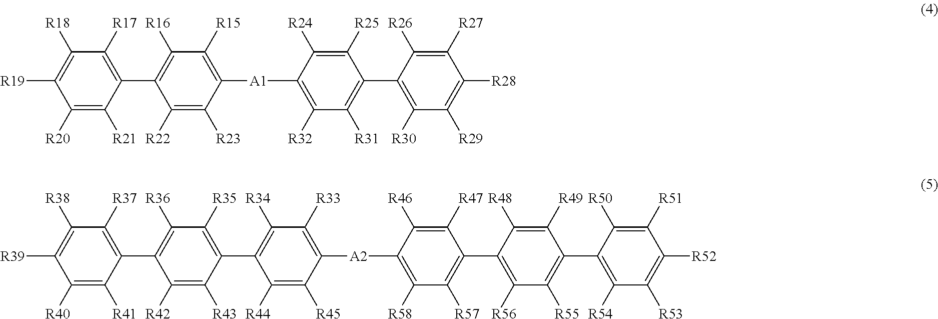
where each of A1 and A2 is one of a conjugated aromatic ring, a condensed aromatic ring, a condensed aromatic ring including a hetero element, oligothiophene, and thiophene, each of which is optionally substituted by one of a halogen atom, a straight-chain, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, a carboxy group, a carboxyamide group, a carboalkoxy group, an acyl group, a sulfonyl group, a cyano group, and a nitro group, each of R15 to R58 is independently selected from a group configured of a hydrogen atom, a halogen atom, a straight-chain, branched, or cyclic alkyl group, thioalkyl group, an aryl group, a thioaryl group, an arylsulfonyl group, an alkyl sulfonyl group, an amino group, an alkylamino group, an arylamino group, a hydroxy group, an alkoxy group, an acylamino group, an acyloxy group, a phenyl group, a carboxy group, a carboxyamide group, a carboalkoxy group, an acyl group, a sulfonyl group, a cyano group, and a nitro group; and any adjacent ones of R15 to R23, any adjacent ones of R24 to R32, any adjacent ones of R33 to R45, and any adjacent ones of R46 to R58 are optionally bound to one another to form a condensed aromatic ring.

32. The photoelectric conversion element according claim 15, wherein the third organic semiconductor material does not have absorption in a wavelength region of 500 nm or more.

33. The photoelectric conversion element according to claim 15, wherein the second organic semiconductor material has a maximal absorption wavelength in a wavelength region from 500 nm to 600 nm both inclusive.

34. A solid-state imaging device provided with pixels each including one or more organic photoelectric converters, each of the organic photoelectric converters including:
a first electrode and a second electrode facing each other; and
a photoelectric conversion layer disposed between the first electrode and the second electrode, and including a first organic semiconductor material, a second organic semiconductor material, and a third organic semiconductor material that have mother skeletons different from one another,
the first organic semiconductor material being one of fullerenes and fullerene derivatives, and
the third organic semiconductor material having a highest occupied molecular orbital level that is shallower than a highest occupied molecular orbital level of the first organic semiconductor material and a highest occupied molecular orbital level of the second organic semiconductor material and allows a difference in highest occupied molecular orbital level between the third organic semiconductor material and the first organic semiconductor material to be less than 0.9 eV.
